(19) United States
(12) Patent Application Publication
(10) Pub. No.: US 2025/0101047 A1
(43) Pub. Date: Mar. 27, 2025

(54) BORON-NITROGEN COMPOUNDS AND ORGANIC ELECTRONIC DEVICES INCLUDING THE SAME

(71) Applicants: SHENZHEN CHINA STAR OPTOELECTRONICS SEMICONDUCTOR DISPLAY TECHNOLOGY CO., LTD., Shenzhen (CN); GUANGZHOU CHINARAY OPTOELECTRONIC MATERIALS LTD., Guangzhou (CN)

(72) Inventors: Zeming XIA, Shenzhen (CN); Zeguan XIAO, Shenzhen (CN); Ruifeng HE, Shenzhen (CN); Jingyao SONG, Shenzhen (CN)

(21) Appl. No.: 18/383,597

(22) Filed: Oct. 25, 2023

(30) Foreign Application Priority Data
Sep. 15, 2023 (CN) 202311201822.1

(51) Int. Cl. C07F 5/02; C07F 7/08; H10K 85/40; H10K 85/60

(52) U.S. Cl. CPC C07F 5/027; C07F 7/0803; H10K 85/40; H10K 85/622; H10K 85/631; H10K 85/6572; H10K 85/6576; H10K 85/658

(57) ABSTRACT

The present disclosure provides a boron-nitrogen compound and an organic electronic device including the same. The organic compound has a structure represented by the following formula (1) or formula (2).

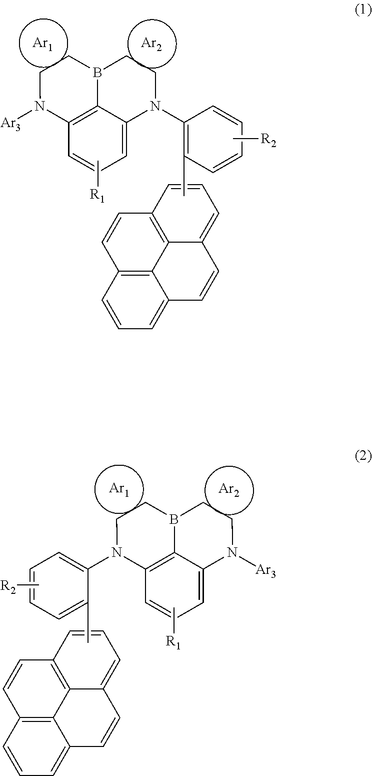

### CROSS-REFERENCE TO RELATED APPLICATION

The present disclosure claims priority to and the benefit of Chinese Patent Application No. 202311201822.1, filed on Sep. 15, 2023, the present disclosure of which is incorporated herein by reference in its entirety.

### TECHNICAL FIELD

The present disclosure relates to the field of electroluminescent materials, in particular, to boron-nitrogen compounds and organic electronic devices including the same.

### BACKGROUND

Organic semiconductor materials have great potential in the application of optoelectronic devices, especially organic light-emitting diode (OLED) devices, due to their advantages of diversity in synthesis, relatively low manufacturing cost, and excellent optical and electrical properties.

In order to improve luminous efficiency of the OLED devices, various luminescent material systems based on fluorescence and phosphorescence have been developed. OLED devices using fluorescent materials have the characteristic of high reliability, but due to the branch ratio of the singlet excited state and triplet excited state of excitons being 1:3, the internal electroluminescent quantum efficiency of the OLED devices is limited to 25% under electrical excitation. On the contrary, OLED devices using phosphorescent materials have achieved almost 100% of internal electroluminescent quantum efficiency. However, luminous efficiency of phosphorescent OLED devices rapidly decreases with the increase of current or brightness, resulting in a roll-off effect, which is particularly unfavorable for high brightness application.

Thermal activation delayed fluorescence (TADF) materials have been further developed and used as light-emitting materials, especially blue light-emitting materials, which can achieve the luminous efficiency comparable to the phosphorescent OLED devices. However, compared to the phosphorescent materials, there is still certain disparity in luminous efficiency, life, and cost of existing blue light-emitting TADF materials. Therefore, there is an urgent need to develop TADF materials with high luminous efficiency, long life, and low manufacturing cost.

### SUMMARY

Embodiments of the present disclosure provide an organic compound having a structure represented by formula (1) or formula (2):

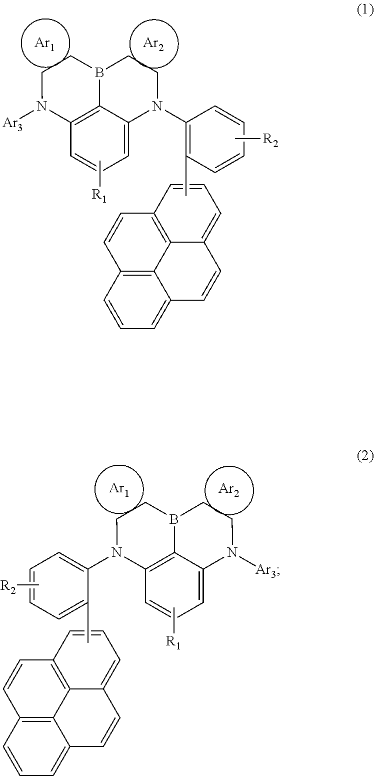

Ar₁ is independently selected from any one of structures represented by formula (X-1) to formula (X-3):

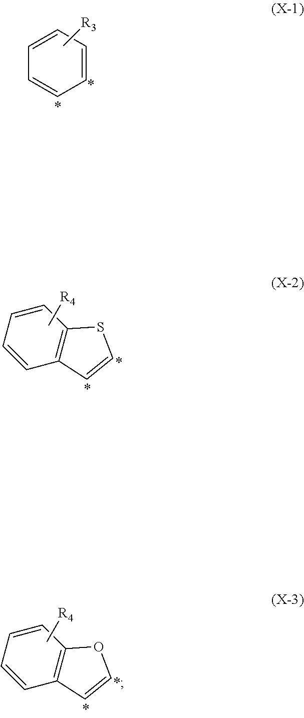

Ar₂ is independently selected from any one of structures represented by formula (A-1) to formula (A-7):

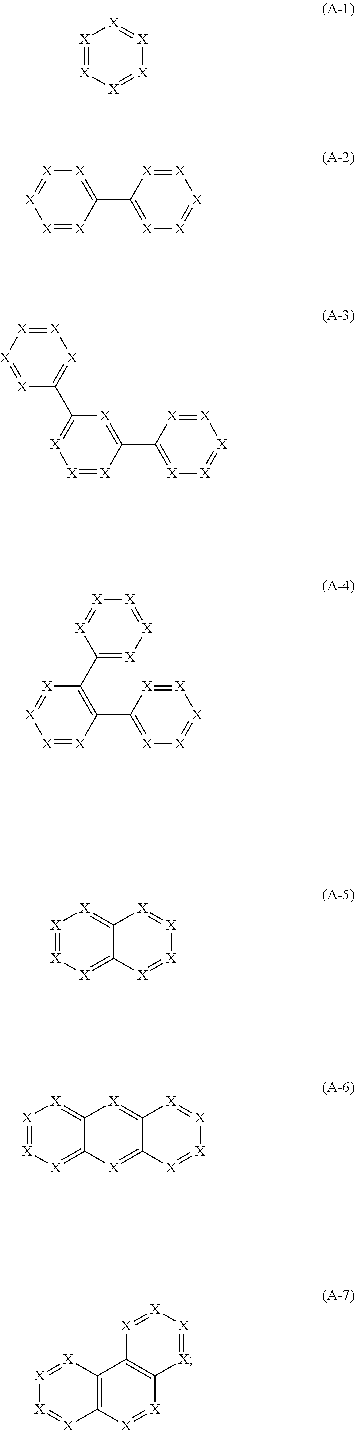

and
Arₙ is independently selected from any one of the following structures:

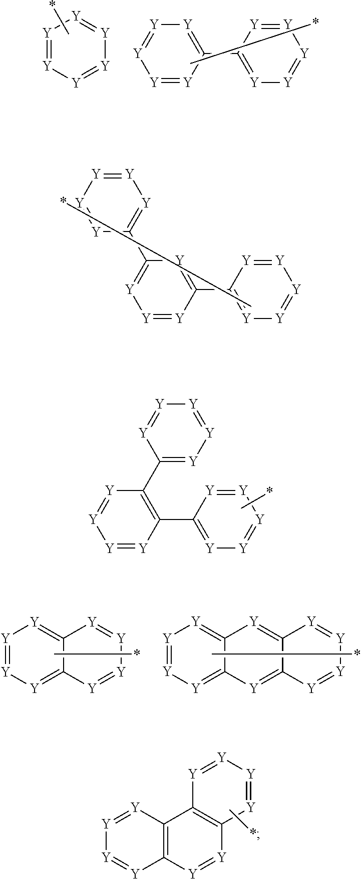

X and Y are each independently selected from CR₅;
R₁-R₅ are each independently selected from H, D, a C₁-C₂₀ linear alkyl group, a C₃-C₂₀ branched alkyl group, a C₃-C₂₀ cyclic alkyl group, a substituted or unsubstituted aromatic group containing 5 to 30 ring atoms, a substituted or unsubstituted heteroaromatic group containing 5 to 30 ring atoms, or combinations thereof at each occurrence; and
* indicates a linking site.

Accordingly, embodiments of the present disclosure further provide an organic electronic device that includes a first electrode, a second electrode, and one or more organic functional layers disposed between the first electrode and the second electrode, and at least one of the one or more organic functional layers includes the above-mentioned boron-nitrogen compound.

### BRIEF DESCRIPTION OF THE DRAWINGS

In order to illustrate technical solutions in embodiments of the present disclosure more clearly, the following briefly introduces drawings needed to be used in description of the embodiments. Apparently, the drawings in the following description are only some embodiments of the present disclosure. For those skilled in the art, other drawings can be obtained from these drawings without paying creative effort.

FIG. 1 is a schematic structural diagram of an organic electronic device according to one or more embodiments of the present disclosure.

### DETAILED DESCRIPTION

In combination with drawings in embodiments of the present disclosure, technical solutions in the embodiments of the present disclosure will be described clearly and completely. Apparently, the described embodiments are only part of the embodiments of the present disclosure, not all of them. Based on the embodiments of the present disclosure, all other embodiments obtained by those skilled in the art without creative effort belong to the scope of the present disclosure. In addition, it should be understood that, specific embodiments described herein are only used to explain and interpret the present disclosure and are not used to limit the present disclosure. In the present disclosure, location terms used, such as “up” and “down”, generally refer to up and down in actual using or working state of devices, in particular drawing directions in the drawings, unless otherwise described. Moreover, in the description of the present disclosure, the term “include” refers to “include but not limited to”, the term “multiple” refers to “two or more”, and the term “and/or” includes any and all combinations of one or more related listed items. Various embodiments of the present disclosure may exist in the form of a scope. It should be understood that the description in the form of the scope is only for convenience and conciseness, and should not be understood as a rigid limitation on the scope of the present disclosure. Therefore, it should be considered that the description of the scope has specifically disclosed all possible sub-ranges and a single value within this range. For example, it should be considered that the description ranging from 1 to 6 has specifically disclosed sub-ranges, such as 1 to 3, 1 to 4, 1 to 5, 2 to 4, 2 to 6, 3 to 6, and the like, and disclosed a single number within the range as described above, such as 1, 2, 3, 4, 5, and 6, regardless of the scope used for what reason. In addition, whenever a numerical range is indicated in this context, it refers to any referenced numbers (fractions or integers) within the range.

The present disclosure provides a boron-nitrogen compound, and an organic electronic device containing the boron-nitrogen compound. In order to make the purpose, technical solutions, and effects of the present disclosure clearer and explicit, the following is a further detailed description of the present disclosure. It should be understood that specific embodiments described here are only used to explain the present disclosure and are not intended to limit it.

In the present disclosure, a cyclic alkyl group and a cycloalkyl group have the same meaning and may be interchanged.

In the present disclosure, “substituted” means that one or more hydrogen atoms in one substituted group are substituted by a substituent group.

In the present disclosure, a same substituent group at different substituent site may be independently selected from the same group or different groups. For example, if a formula includes multiple R¹ groups, each of the R¹ groups may be independently selected from the same group or different groups. For example, in formula

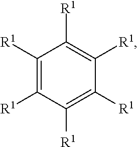

six R¹ groups of a benzene ring may be same or different.

In the present disclosure, “substituted or unsubstituted” means that a defined group may be substituted or not be substituted. When the defined group is substituted, it can be understood that the defined group may be substituted by at least one substituent R. The substituent R is selected from, but not limited to, deuterium (D), a cyano group, an isocyano group, a nitro group, a halogen group, a C₁-C₃₀ alkyl group, a heterocyclic group containing 3-20 ring atoms, an aromatic group containing 5-20 ring atoms, a heteroaromatic group containing 5-20 ring atoms, —NR′R″, a silyl group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, or a trifluoromethyl group. The above-mentioned groups may further be substituted by acceptable substituent groups in the art. Understandably, R′ and R″ in the —NR′R″ are each independently selected from, but not limited to, hydrogen (H), D, a cyano group, an isocyano group, a nitro group, a halogen group, a C₁-C₁₀ alkyl group, a heterocyclic group containing 3-20 ring atoms, an aromatic group containing 6-20 ring atoms, or a heteroaromatic group containing 5-20 ring atoms. In some embodiments, R′ and R″ are each independently selected from, but not limited to, D, a cyano group, an isocyano group, a nitro group, a halogen group, a C₁-C₁₀ alkyl group, a heterocyclic group containing 3-10 ring atoms, an aromatic group containing 6-20 ring atoms, a heteroaromatic group containing 5-20 ring atoms, a silyl group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, or a trifluoromethyl group, and the above-mentioned groups may further be substituted by acceptable substituent groups in the art. In the present disclosure, unless otherwise specified, “halogen” may be F, Cl, Br, or I.

It should be noted that, unless otherwise specified, a ring atom of the present disclosure refers to a carbon atom.

In the present disclosure, “number of ring atoms” refers to a number of atoms constituting a ring of a structural compound obtained by atomic bonding, for example, a monocyclic compound, a fused ring compound, a cross-linked compound, a carbon ring compound, or a heterocyclic compound. In a ring substituted by a substituent group, the atoms contained in the substituent group are not included in the atoms forming the ring. The same applies to “number of ring atoms” described below unless otherwise specified. For example, a number of ring atoms in a benzene ring is 6, a number of ring atoms in a naphthalene ring is 10, and a number of ring atoms in a thiophene group is 5.

In the present disclosure, “an alkyl group” refers to a linear alkyl group, a branched alkyl group, and/or a cyclic alkyl group. Examples of the alkyl group include, but not limited to, methyl, ethyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butyl hexyl, cyclohexyl, 4-methylcyclohexyl 4-tert-butylcyclohexyl, n-heptyl, 1-methylheptyl, 2,2-dimethylheptyl, 2-ethylheptyl, 2-butyl heptyl, n-octyl, tertoctyl, 2-ethyloctyl, 2-butyl octyl, 2-hexyloctyl, 3,7-dimethyloctyl, cyclooctyl, n-nonyl, n-decyl, adamantine, 2-ethyldecyl, 2-butyl decyl, 2-hexyldecyl, 2-octyldecyl, n-undecyl, n-dodecyl, 2-ethyldodecyl 2-butyl dodecyl, 2-hexyl dodecyl, 2-octyl dodecyl, n-tridecyl, n-tetradecyl, n-pentadecyl, n-hexadecyl, 2-ethyl hexadecyl, 2-butyl hexadecyl, 2-hexyl hexadecyl, 2-octyl hexadecyl, n-heptadecyl, n-octadecyl, n-octadecyl, n-eicosyl, 2-ethyl eicosyl, 2-butyl eicosyl, 2-hexyl eicosyl, 2-octyl twenty one alkyl, twenty two alkyl, twenty three alkyl, twenty four alkyl, twenty five alkyl, twenty six alkyl, twenty seven alkyl, twenty eight alkyl, twenty nine alkyl, thirty alkyl, adamantane, and the like.

In the present disclosure, “an alkoxyl group” refers to a group having a structure of “—O-alkyl”, that is, the alkyl group as defined above is connected to other groups through an oxygen atom. Suitable examples of phrases containing the above-mentioned term include, but not limited to, a methoxyl group (—O—CH₃ or —OMe), an ethoxyl group (—O—CH₂CH₃ or -OEt), and a tert-butoxy group (—O—C(CH₃)₃ or -OtBu).

In the present disclosure, “an aryl group or an aromatic group” refers to an aromatic hydrocarbon group derived from a basis of an aromatic ring compound removing H, which may be a monocyclic aryl group, a fused ring aryl group, or a polycyclic aryl group. For a polycyclic ring type, at least one ring is an aromatic ring system. For example, “a substituted or unsubstituted aryl group containing 5 to 30 ring atoms” refers to an aryl group containing 5 to 30 ring atoms, and the aryl group is optionally further substituted. Suitable examples include, but not limited to, a phenyl group, a biphenyl group, a triphenyl group, a naphthyl group, an anthracyl group, a phenanthryl group, a fluoranthenyl group, a triphenylene group, a pyrenyl group, a perylene group, a tetraphenyl group, a fluorenyl group, a dinaphthalene intercalated phenyl group, an acenaphthenyl group, and derivatives thereof. Understandably, aryl groups may be disconnected by short non-aromatic units (for example, <10% of non-hydrogenium atoms, such as C, N, or O). In particular, an acenaphthene group, a fluorene group, a 9,9-diarylfluorene group, a triarylamine group, and a diaryl ether system may be included in an aryl group.

It can be understood that, unless otherwise specified, the heteroatom in the present disclosure refers to a non-carbon atom.

In the present disclosure, “a heteroaryl group or a heteroaromatic group” refers to a basis of an aryl group with at least one carbon atom substituted by a non-carbon atom, and the non-carbon atom may be N, O, S, or the like. For example, “a substituted or unsubstituted heteroaryl group containing 5 to 30 ring atoms” refers to a heteroaryl group containing 5 to 30 ring atoms, and the heteroaryl group is optionally further substituted. Suitable examples include, but not limited to, a furan group, a benzofuran group, a thiophene group, a benzothiophene group, a pyrrole group, a pyrazole group, a triazole group, an imidazole group, an oxazole group, an oxadiazole group, a thiazole group, a tetrazole group, an indole group, a carbazole group, a pyrrolimidazole group, a diketopyrrolopyrrole group, a thiophenopyrrole group, a thienothiophene group, a furanopyrrole group, a furanofuran group, a thiophenofuran group, a benzisoxazole group, a benzisothiazole group, a benzimidazole group, a pyridine group, a pyrazine group, a pyridazine group, a pyrimidine group, a triazine group, a quinoline group, an isoquinoline group, an ortho diazonaphthalene group, a quinoxaline group, a pheridine group, a perimidine group, a quinazoline group, a quinazolone group, a dibenzothiophene group, a dibenzofuran group, and derivatives thereof.

In the present disclosure, “an amino group” refers to a derivative of the amine, has a feature of a group represented by formula —N(X)₂. X is independently selected from H, a substituted or unsubstituted alkyl group, a substituted or unsubstituted cycloalkyl group, a substituted or unsubstituted heterocyclic group, or the like. Examples of amino groups include, but not limited to, —NH₂, —N(alkyl)₂, —NH(alkyl), —N(cycloalkyl)₂, —NH(cycloalkyl), —N(heterocyclic)₂, —NH(heterocyclic), —N(aryl)₂, —NH(aryl), —N(alkyl)(aryl), —N(alkyl)(heterocyclic), —N(cycloalkyl)(heterocyclic), —N(aryl)(heteroaryl), —N(alkyl)(heteroaryl), and the like.

In the present disclosure, “*” connected to a single bond or located at a site of a group indicates a linking site or a fusing site.

In the present disclosure, a single bond connected to a substituent group and penetrated a corresponding ring indicates that the substituent group may be connected to any site of the ring. For example,

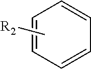

means that R₂ may be connected to any substituent site of the benzene ring, and

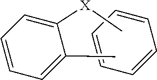

means that

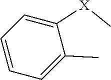

may be connected to any substituent site of

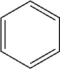

to form multiple rings.

In the present disclosure, abbreviations of substituent groups are as follows: normal (n), secondary (sec), iso (i), tertiary (tert), ortho (o), meta (m), para (p), methyl (Me), ethyl (Et), propyl (Pr), butyl (Bu), n-amyl (Am), hexyl (Hx), cyclohexyl (Cy), and tert-butyl (t-Bu).

The present disclosure provides a boron-nitrogen compound having a structure represented by the following formula (1) or formula (2):

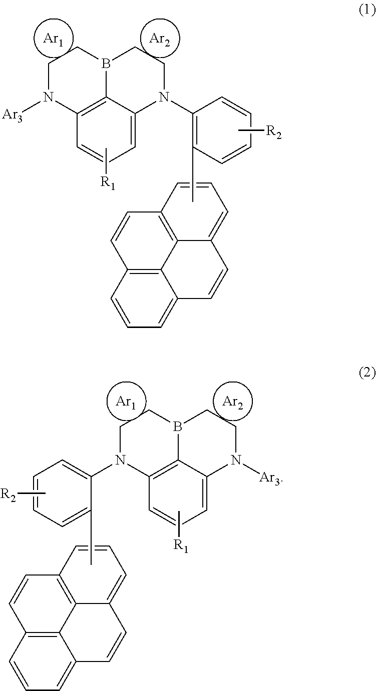

In the formula (1) or the formula (2),

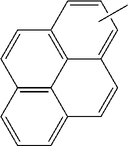

refers to a pyrenyl group.

In the formula (1) or the formula (2), Ar₁ is independently selected from any one of structures represented by the following formula (X-1) to formula (X-3):

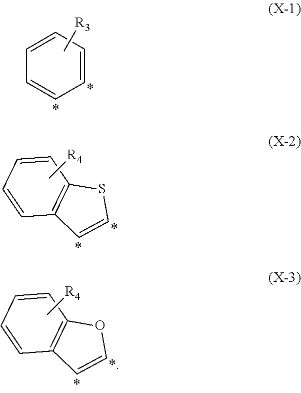

In the formula (1) or the formula (2), Ar₂ is independently selected from any one of structures represented by the following formula (A-1) to formula (A-7):

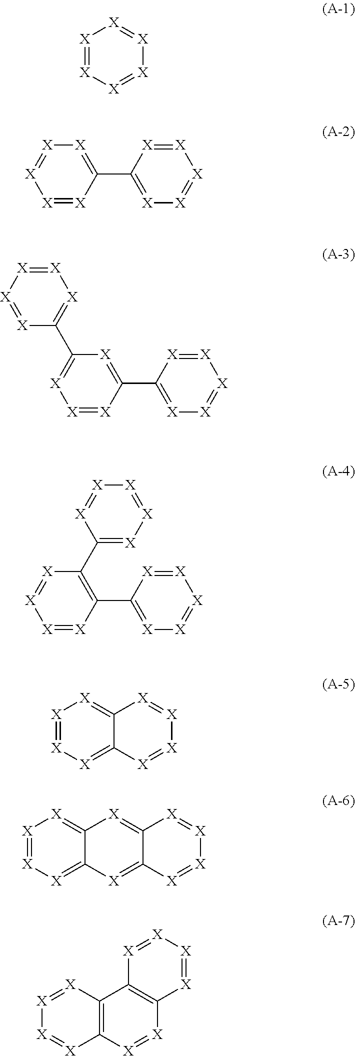

In the formula (1) or the formula (2), Arₙ is independently selected from any one of the following structures:

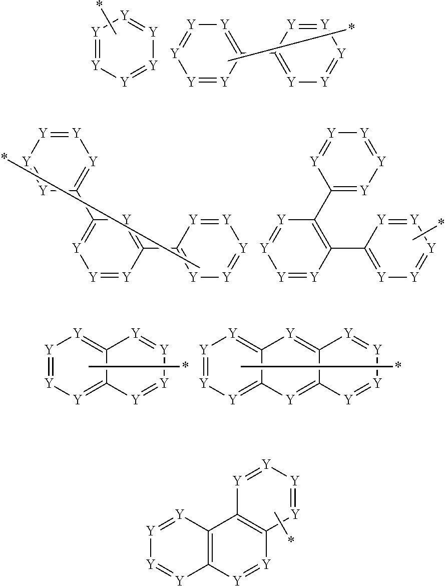

In some embodiments, X and Y are each independently selected from CR₅. R₁-R₅ are each independently selected from H, D, a C₁-C₂₀ linear alkyl group, a C₃-C₂₀ branched alkyl group, a C₃-C₂₀ cyclic alkyl group, a substituted or unsubstituted aromatic group containing 5 to 30 ring atoms, a substituted or unsubstituted heteroaromatic group containing 5 to 30 ring atoms, or combinations thereof at each occurrence.

The present disclosure improves the property of the boron-nitrogen compound by introducing a pyrene group that enhances the overall conjugation of the boron-nitrogen compound. When the boron-nitrogen compound is used as a blue light-emitting material in organic electronic devices, luminous efficiency and life of the organic electronic devices can be improved.

In some embodiments, R₁ is independently selected from any one of structures represented by the following formula (E-1) to formula (E-9):

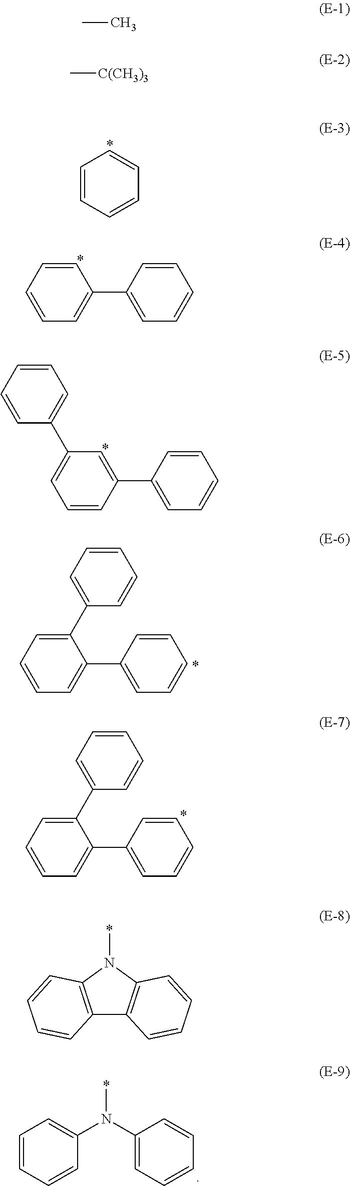

In some embodiments, R₁ is independently selected from any one of structures represented by formula (E-2), formula (E-3), formula (E-4), formula (E-8), and formula (E-9).

In some embodiments, R₂ is independently selected from H, a C₁-C₁₀ linear alkyl group, or a C₃-C₁₀ branched alkyl group.

In some embodiments, R₂ is independently selected from H, a C₁-C₅ linear alkyl group, or a C₃-C₅ branched alkyl group. For example, R₂ may be selected from H, a methyl group, an ethyl group, a tert-butyl group, or an amyl group. Preferably, R₂ may be selected from H or a tert-butyl group.

In some embodiments, Ar₁ is independently selected from any one of structures represented by the following formula (Y-1) to formula (Y-3):

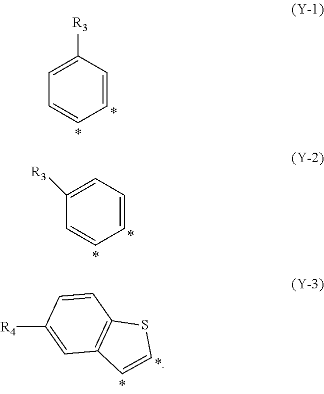

In the formula (Y-1) to the formula (Y-3), R₃ and R₄ are each independently selected from H, a C₁-C₁₀ linear alkyl group, a C₃-C₁₀ branched alkyl group, a substituted or unsubstituted aromatic group containing 5 to 20 ring atoms, or a substituted or unsubstituted heteroaromatic group containing 5 to 20 ring atoms. In some embodiments, R₃ is independently selected from H, a C₁-C₅ linear alkyl group, a C₃-C₅ branched alkyl group, a substituted or unsubstituted aromatic group containing 6 to 20 ring atoms, or a substituted or unsubstituted heteroaromatic group containing 5 to 15 ring atoms.

In some embodiments, R₃ is independently selected from a C₃-C₅ branched alkyl group or any one of structures represented by the following formula (B-1) to formula (B-5):

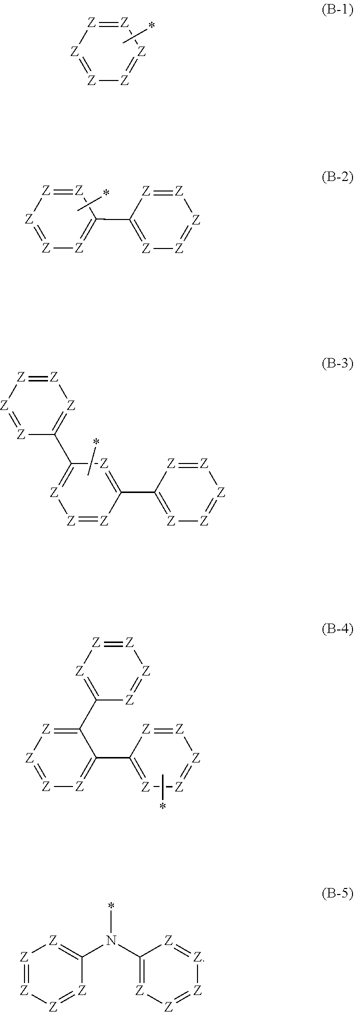

In the formula (B-1) to formula (B-5), Z is independently selected from CR₆, and R₆ is independently selected from H, a C₁-C₅ linear alkyl group, or a C₃-C₅ branched alkyl group.

In some embodiments, at least one R₆ in any one of the formula (B-1) to formula (B-5) is not H, and R₆ is independently selected from H or a C₃-C₅ branched alkyl group. For example, R₆ may be selected from H, a methyl group, an ethyl group, a tert-butyl group, or an amyl group.

In some embodiments, R₃ is independently selected from any one of structures represented by formula (C-1) to formula (C-6):

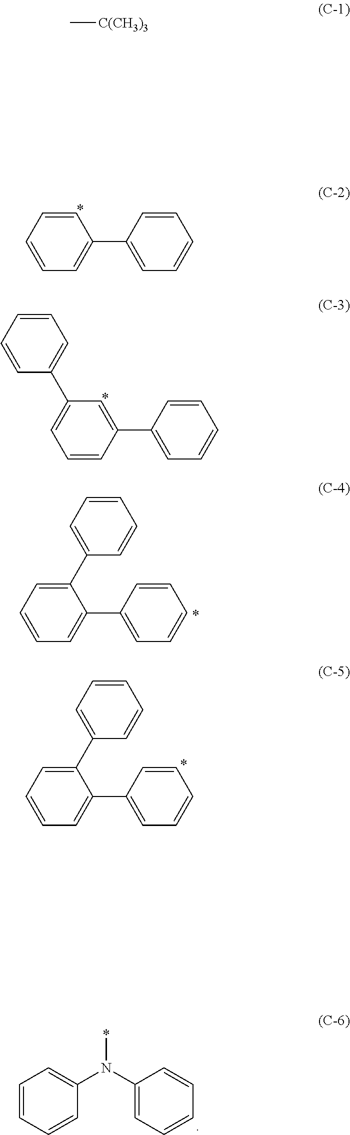

In some embodiments, R₄ is selected from a C₁-C₅ linear alkyl group, a C₃-C₅ branched alkyl group, or a substituted or unsubstituted aromatic group containing 6 to 20 ring atoms.

In some embodiments, R₄ is selected from a C₃-C₅ branched alkyl group, or a substituted or unsubstituted aromatic group containing 6 to 15 ring atoms.

In some embodiments, R₄ is selected from a tert-butyl group or a phenyl group.

In some embodiments, at least one R₅ in any one of formula (A-1) to formula (A-7) is not H.

In some embodiments, Ar₂ is independently selected from any one of structures represented by the following formula (D-1) to formula (D-4):

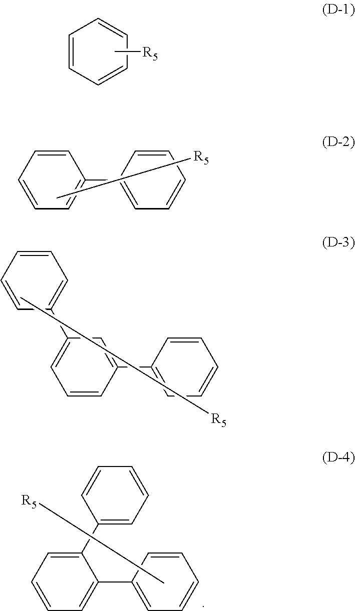

In some embodiments, Ar₃ is independently selected from any one of the following structures:

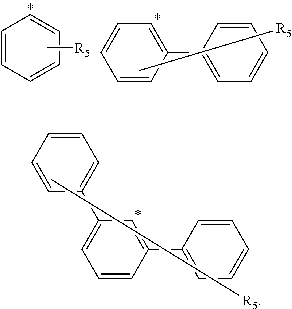

In some embodiments, R₅ is independently selected from H, a C₁-C₁₀ linear alkyl group, or a C₃-C₁₀ branched alkyl group. Preferably, R₅ is independently selected from H, a C₁-C₅ linear alkyl group, or a C₃-C₅ branched alkyl group. For example, R₅ may be selected from H, a methyl group, an ethyl group, a tert-butyl group, or an amyl group.

In some embodiments, the boron-nitrogen compound has a structure represented by the following formula (2-1) or formula (2-5):

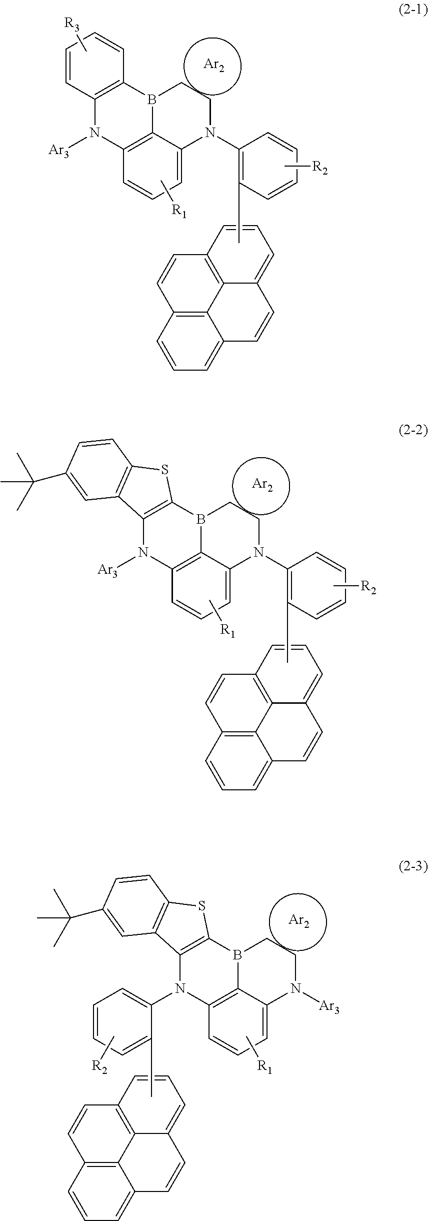

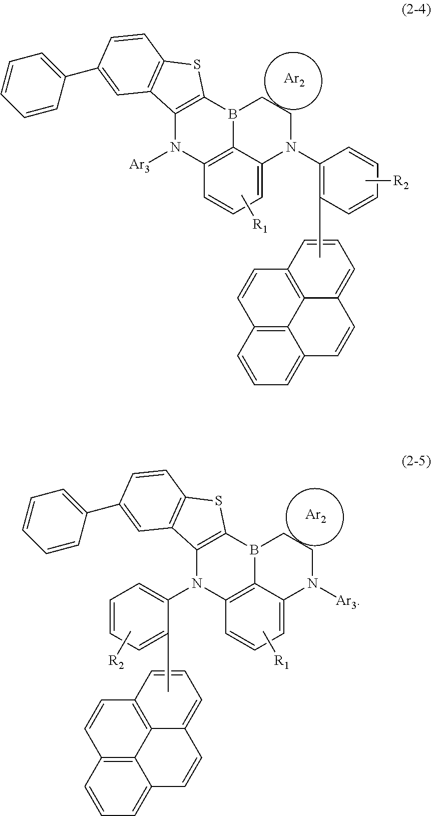

In some embodiments, the boron-nitrogen compound has a structure represented by the following formula (3-1) or formula (3-7):

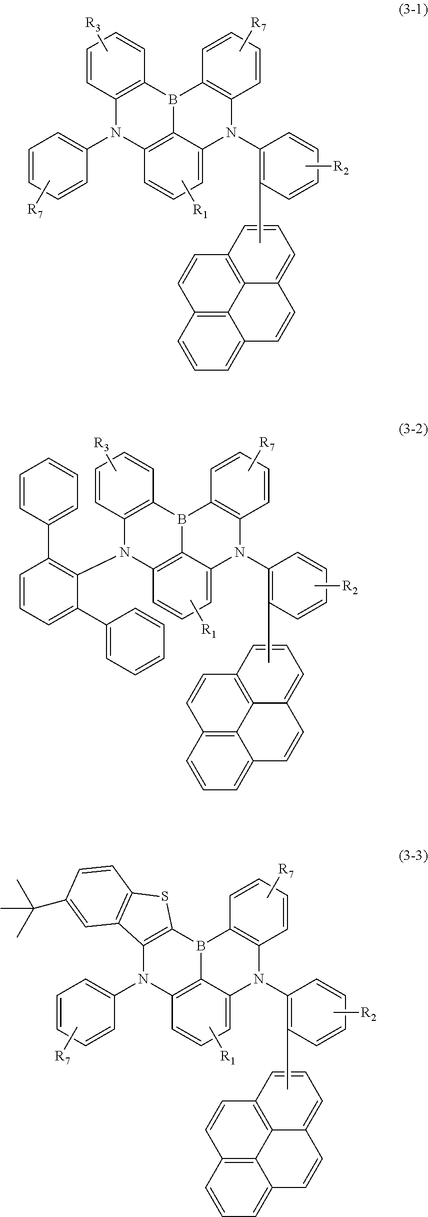

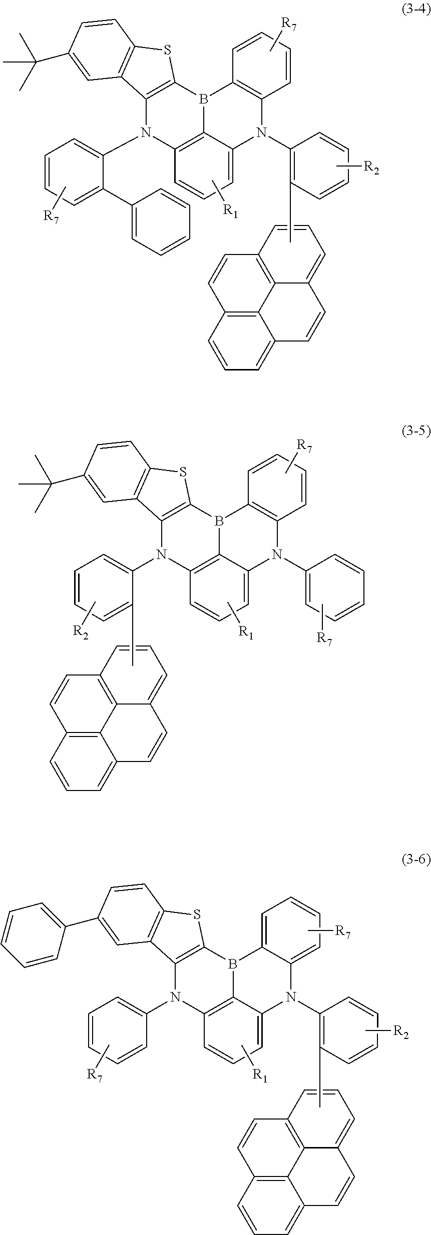

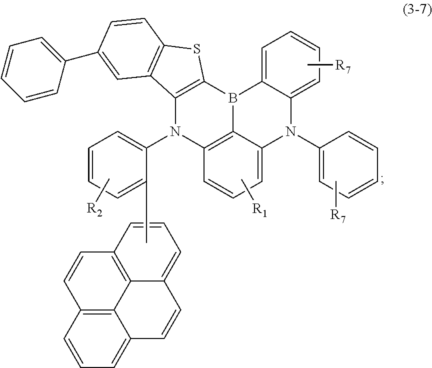

In the formula (3-1) or formula (3-7), R₇ is independently selected from H, a C₁-C₁₀ linear alkyl group, a C₃-C₁₀ branched alkyl group, a substituted or unsubstituted aromatic group containing 5 to 20 ring atoms, or a substituted or unsubstituted heteroaromatic group containing 5 to 20 ring atoms.

In some embodiments, R₇ is independently selected from any one of the following structures:

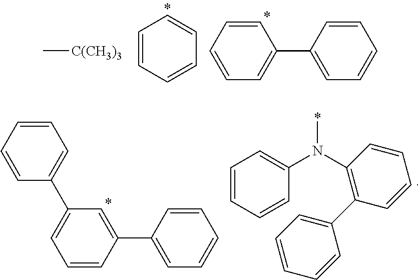

In some embodiments, the boron-nitrogen compound is selected from any one of the following structures:

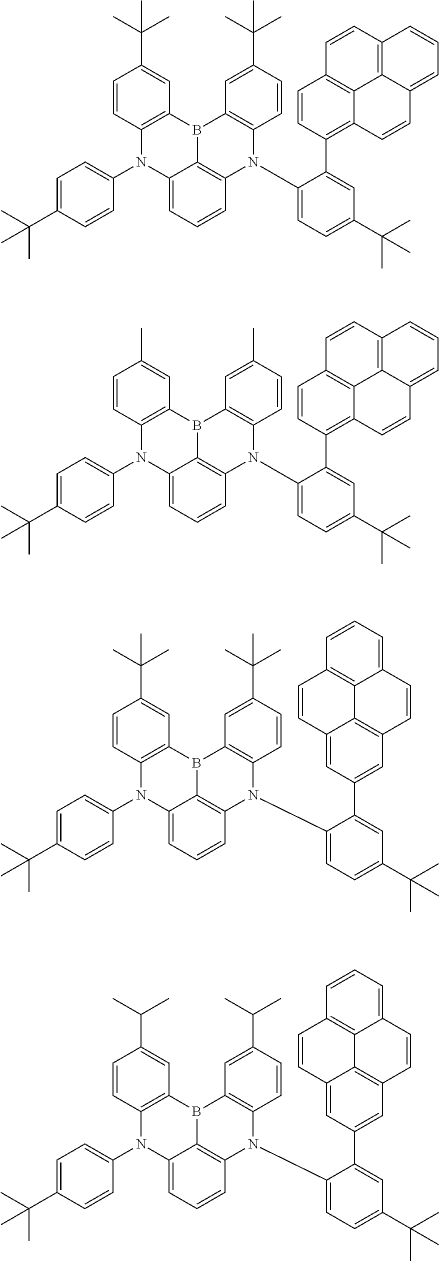

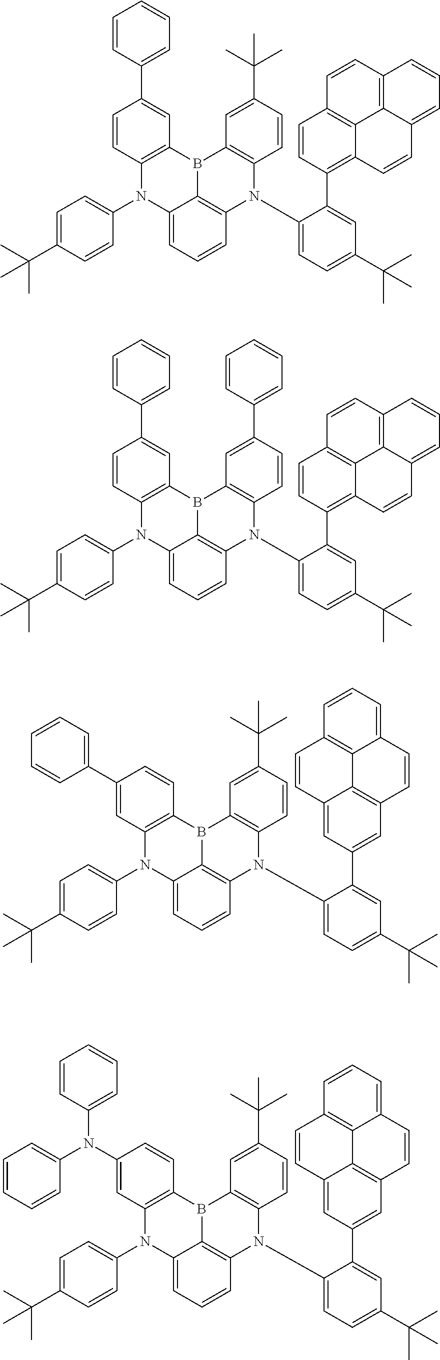

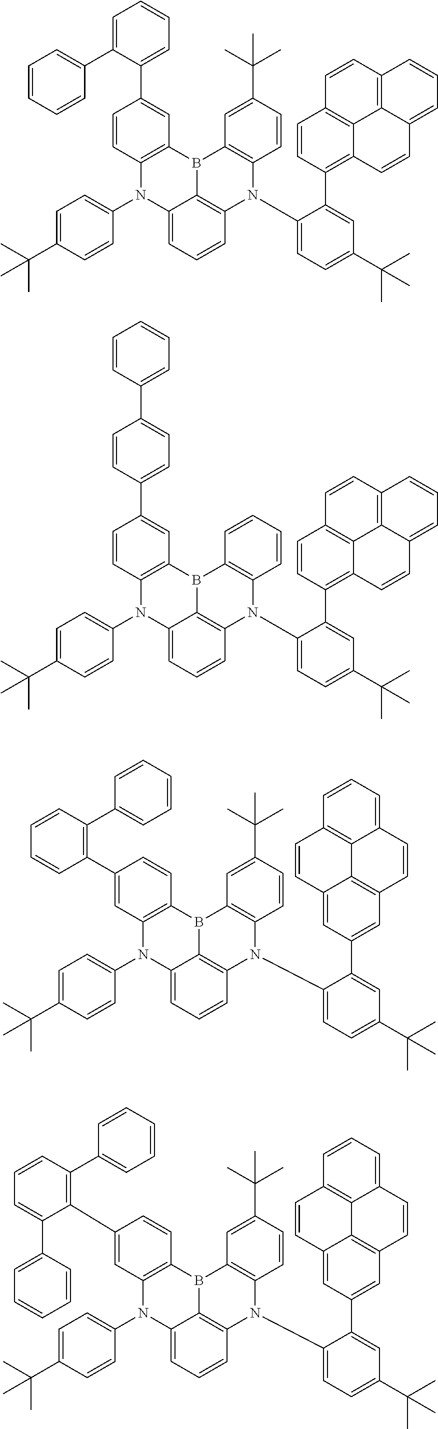

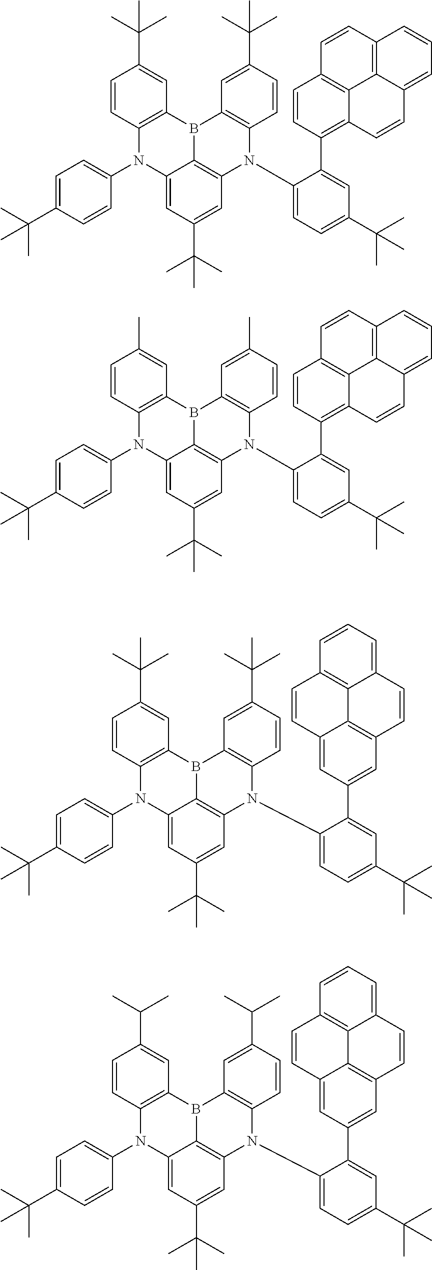

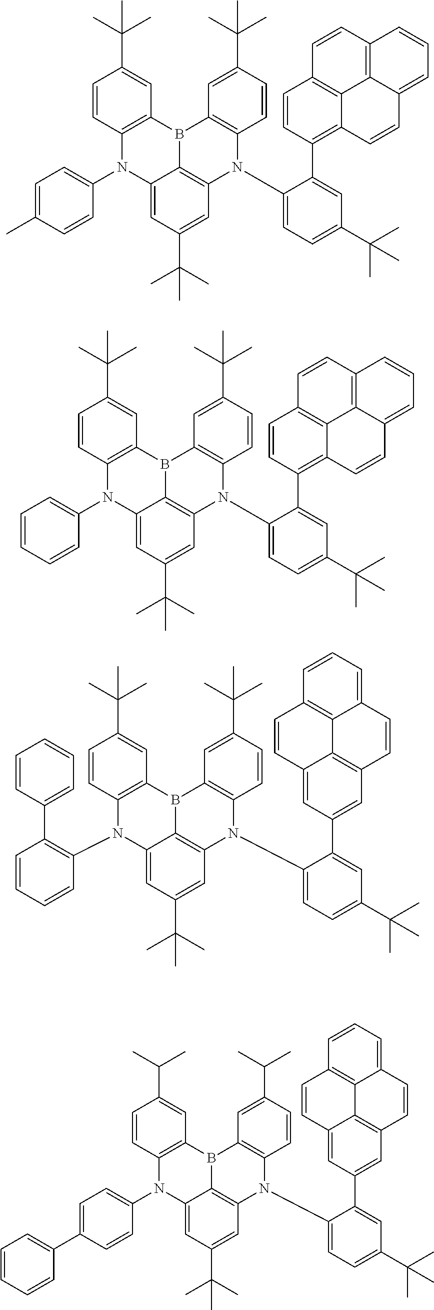 [SMILES: Cc1ccc(N2c3ccc(C(C)(C)C)cc3B3c4cc(C(C)(C)C)ccc4N(c4ccc(C(C)(C)C)cc4-c4ccc5ccc6cccc7ccc4c5c67)c4cc(C(C)(C)C)cc2c43)cc1 ; CC(C)(C)c1ccc2c(c1)B1c3cc(C(C)(C)C)ccc3N(c3ccc(C(C)(C)C)cc3-c3ccc4ccc5cccc6ccc3c4c56)c3cc(C(C)(C)C)cc(c31)N2c1ccccc1 ; CC(C)(C)c1ccc2c(c1)B1c3cc(C(C)(C)C)ccc3N(c3ccc(C(C)(C)C)cc3-c3cc4ccc5cccc6ccc(c3)c4c56)c3cc(C(C)(C)C)cc(c31)N2c1ccccc1-c1ccccc1 ; CC(C)c1ccc2c(c1)B1c3cc(C(C)C)ccc3N(c3ccc(C(C)(C)C)cc3-c3cc4ccc5cccc6ccc(c3)c4c56)c3cc(C(C)(C)C)cc(c31)N2c1ccc(-c2ccccc2)cc1]

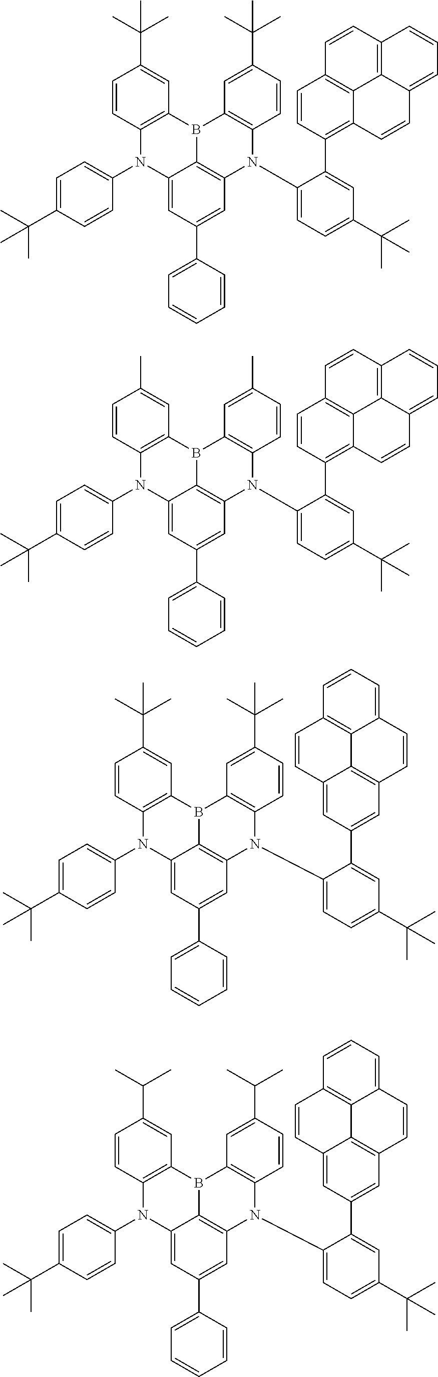

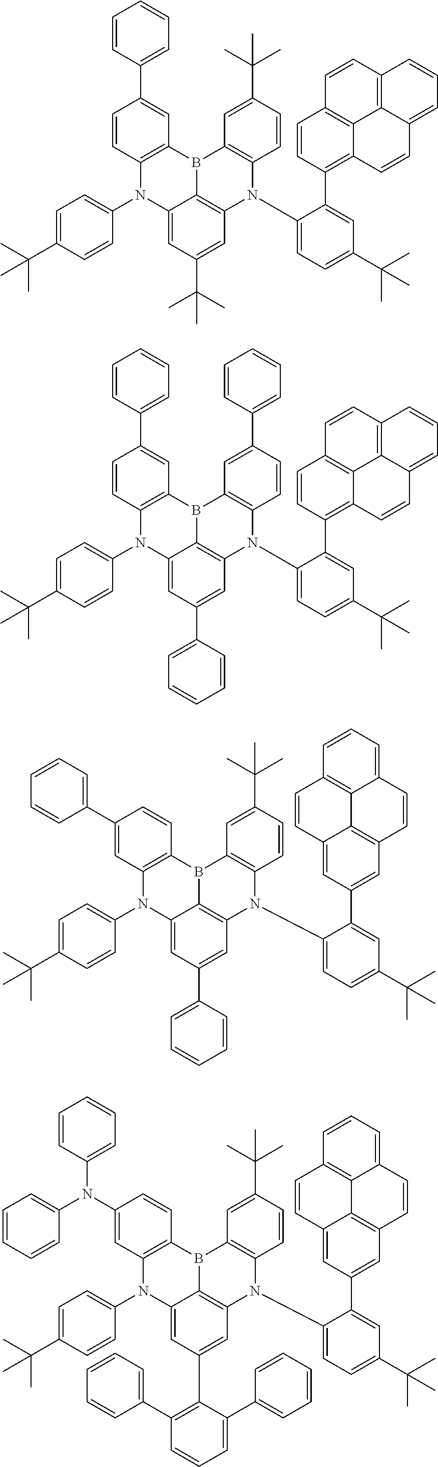

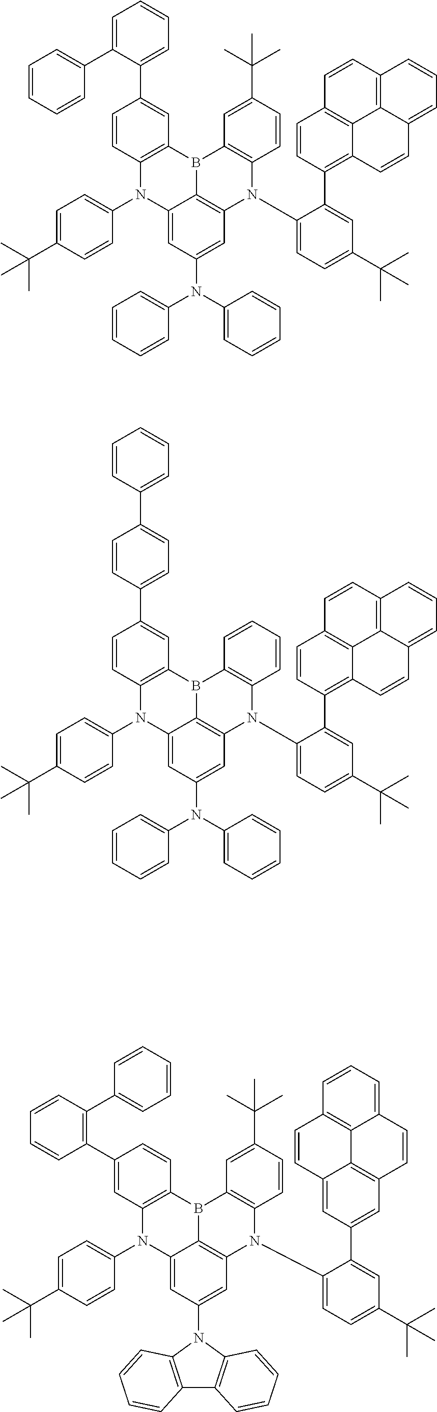 [SMILES: CC(C)(C)c1ccc(N2c3ccc(-c4ccccc4-c4ccccc4)cc3B3c4cc(C(C)(C)C)ccc4N(c4ccc(C(C)(C)C)cc4-c4ccc5ccc6cccc7ccc4c5c67)c4cc(N(c5ccccc5)c5ccccc5)cc2c43)cc1 ; CC(C)(C)c1ccc(N2c3ccc(-c4ccc(-c5ccccc5)cc4)cc3B3c4ccccc4N(c4ccc(C(C)(C)C)cc4-c4ccc5ccc6cccc7ccc4c5c67)c4cc(N(c5ccccc5)c5ccccc5)cc2c43)cc1 ; CC(C)(C)c1ccc(N2c3cc(-c4ccccc4-c4ccccc4)ccc3B3c4cc(C(C)(C)C)ccc4N(c4ccc(C(C)(C)C)cc4-c4cc5ccc6cccc7ccc(c4)c5c67)c4cc(-n5c6ccccc6c6ccccc65)cc2c43)cc1]

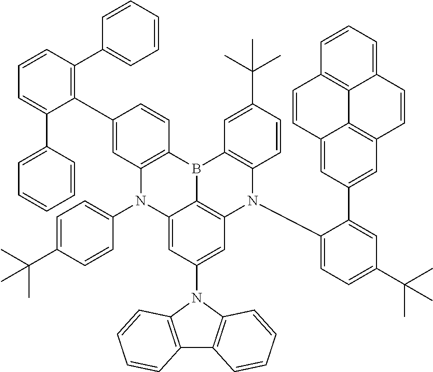 [SMILES: CC(C)(C)c1ccc(N2c3cc(-c4c(-c5ccccc5)cccc4-c4ccccc4)ccc3B3c4cc(C(C)(C)C)ccc4N(c4ccc(C(C)(C)C)cc4-c4cc5ccc6cccc7ccc(c4)c5c67)c4cc(-n5c6ccccc6c6ccccc65)cc2c43)cc1]

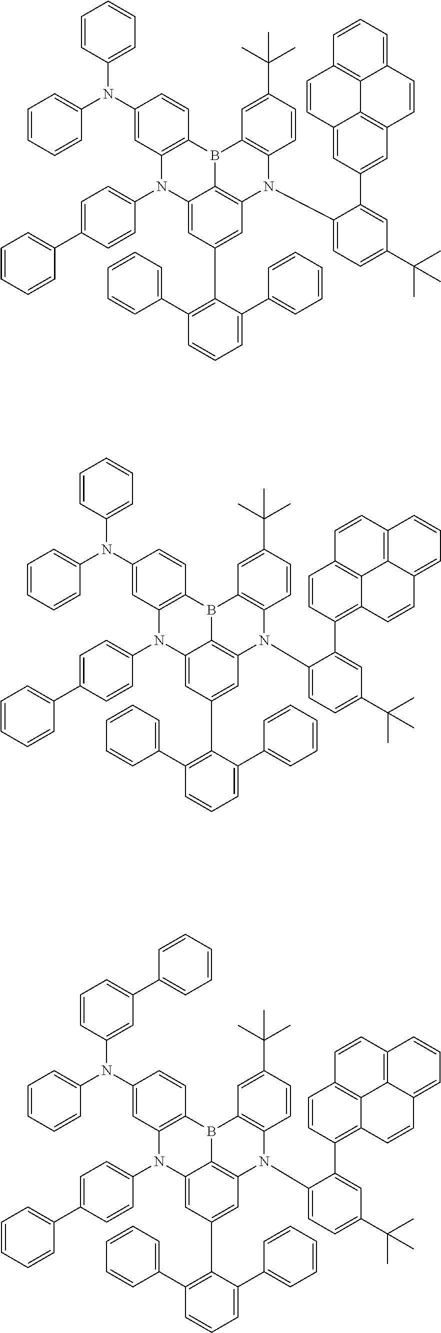 [SMILES: CC(C)(C)c1ccc2c(c1)B1c3ccc(N(c4ccccc4)c4ccccc4)cc3N(c3ccc(-c4ccccc4)cc3)c3cc(-c4c(-c5ccccc5)cccc4-c4ccccc4)cc(c31)N2c1ccc(C(C)(C)C)cc1-c1cc2ccc3cccc4ccc(c1)c2c34 ; CC(C)(C)c1ccc2c(c1)B1c3ccc(N(c4ccccc4)c4ccccc4)cc3N(c3ccc(-c4ccccc4)cc3)c3cc(-c4c(-c5ccccc5)cccc4-c4ccccc4)cc(c31)N2c1ccc(C(C)(C)C)cc1-c1ccc2ccc3cccc4ccc1c2c34 ; CC(C)(C)c1ccc2c(c1)B1c3ccc(N(c4ccccc4)c4cccc(-c5ccccc5)c4)cc3N(c3ccc(-c4ccccc4)cc3)c3cc(-c4c(-c5ccccc5)cccc4-c4ccccc4)cc(c31)N2c1ccc(C(C)(C)C)cc1-c1ccc2ccc3cccc4ccc1c2c34]

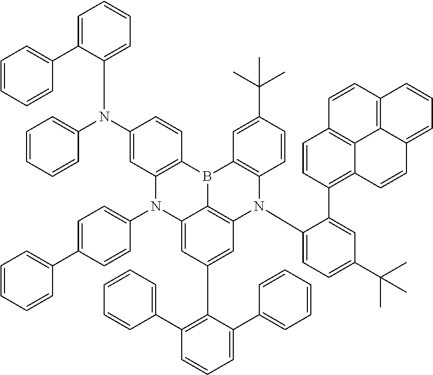 [SMILES: CC(C)(C)c1ccc2c(c1)B1c3ccc(N(c4ccccc4)c4ccccc4-c4ccccc4)cc3N(c3ccc(-c4ccccc4)cc3)c3cc(-c4c(-c5ccccc5)cccc4-c4ccccc4)cc(c31)N2c1ccc(C(C)(C)C)cc1-c1ccc2ccc3cccc4ccc1c2c34]

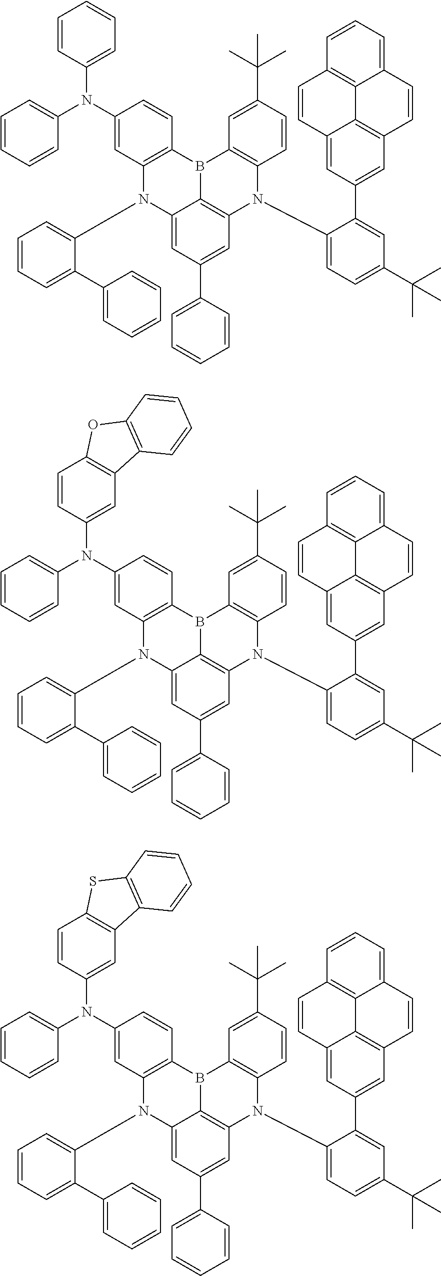

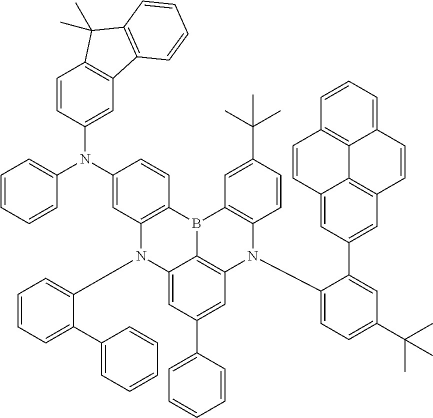 [SMILES: CC(C)(C)c1ccc2c(c1)B1c3ccc(N(c4ccccc4)c4ccc5c(c4)-c4ccccc4C5(C)C)cc3N(c3ccccc3-c3ccccc3)c3cc(-c4ccccc4)cc(c31)N2c1ccc(C(C)(C)C)cc1-c1cc2ccc3cccc4ccc(c1)c2c34]

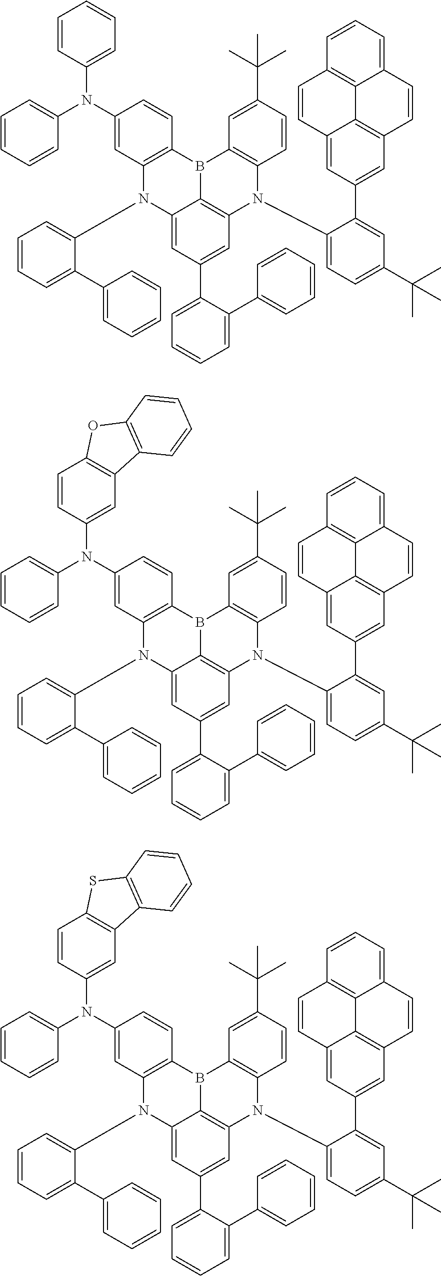

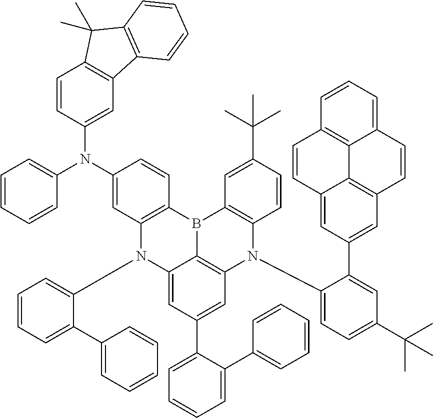 [SMILES: CC(C)(C)c1ccc2c(c1)B1c3ccc(N(c4ccccc4)c4ccc5c(c4)-c4ccccc4C5(C)C)cc3N(c3ccccc3-c3ccccc3)c3cc(-c4ccccc4-c4ccccc4)cc(c31)N2c1ccc(C(C)(C)C)cc1-c1cc2ccc3cccc4ccc(c1)c2c34]

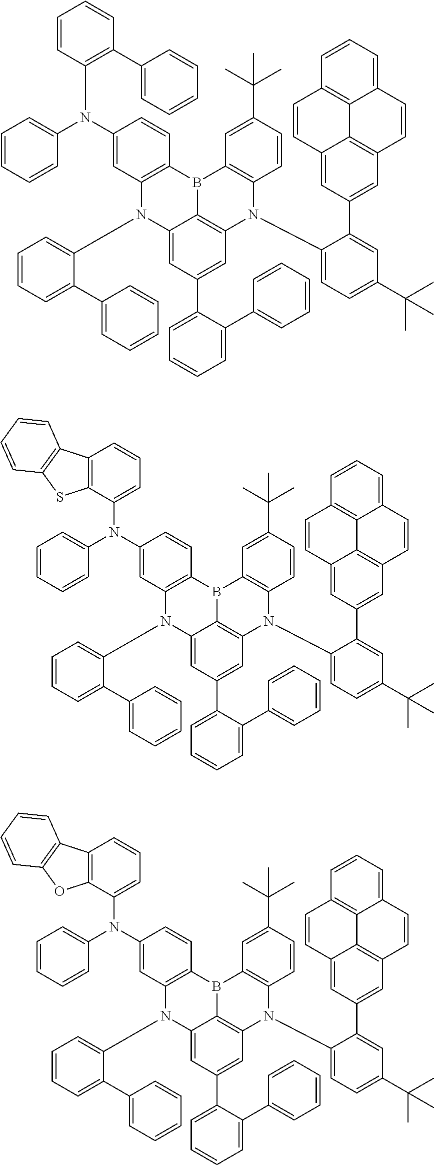 [SMILES: CC(C)(C)c1ccc2c(c1)B1c3ccc(N(c4ccccc4)c4ccccc4-c4ccccc4)cc3N(c3ccccc3-c3ccccc3)c3cc(-c4ccccc4-c4ccccc4)cc(c31)N2c1ccc(C(C)(C)C)cc1-c1cc2ccc3cccc4ccc(c1)c2c34 ; CC(C)(C)c1ccc2c(c1)B1c3ccc(N(c4ccccc4)c4cccc5c4sc4ccccc45)cc3N(c3ccccc3-c3ccccc3)c3cc(-c4ccccc4-c4ccccc4)cc(c31)N2c1ccc(C(C)(C)C)cc1-c1cc2ccc3cccc4ccc(c1)c2c34 ; CC(C)(C)c1ccc2c(c1)B1c3ccc(N(c4ccccc4)c4cccc5c4oc4ccccc45)cc3N(c3ccccc3-c3ccccc3)c3cc(-c4ccccc4-c4ccccc4)cc(c31)N2c1ccc(C(C)(C)C)cc1-c1cc2ccc3cccc4ccc(c1)c2c34]

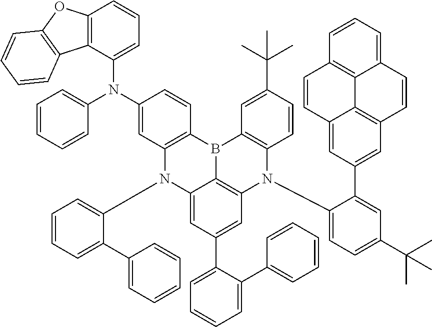 [SMILES: CC(C)(C)c1ccc2c(c1)B1c3ccc(N(c4ccccc4)c4cccc5oc6ccccc6c45)cc3N(c3ccccc3-c3ccccc3)c3cc(-c4ccccc4-c4ccccc4)cc(c31)N2c1ccc(C(C)(C)C)cc1-c1cc2ccc3cccc4ccc(c1)c2c34]

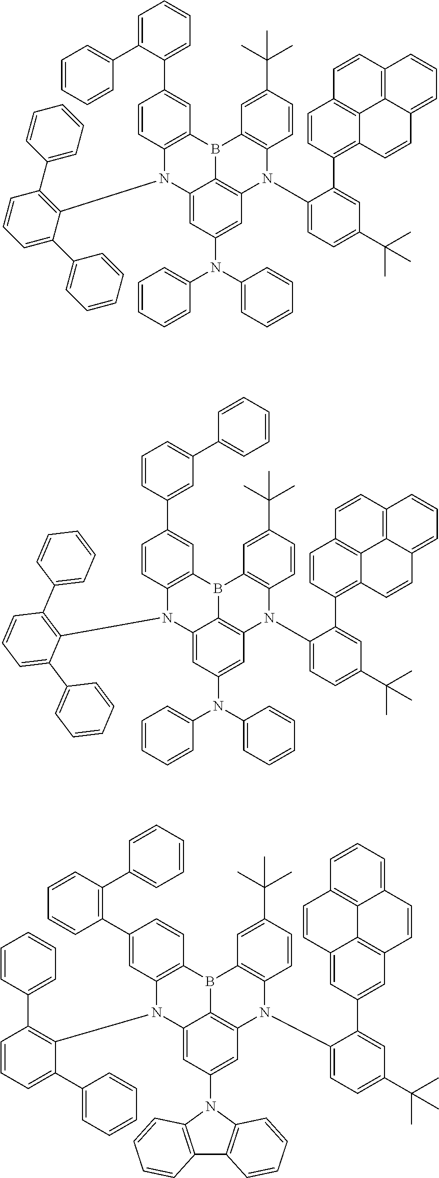 [SMILES: CC(C)(C)c1ccc2c(c1)B1c3cc(-c4ccccc4-c4ccccc4)ccc3N(c3c(-c4ccccc4)cccc3-c3ccccc3)c3cc(N(c4ccccc4)c4ccccc4)cc(c31)N2c1ccc(C(C)(C)C)cc1-c1ccc2ccc3cccc4ccc1c2c34 ; CC(C)(C)c1ccc2c(c1)B1c3cc(-c4cccc(-c5ccccc5)c4)ccc3N(c3c(-c4ccccc4)cccc3-c3ccccc3)c3cc(N(c4ccccc4)c4ccccc4)cc(c31)N2c1ccc(C(C)(C)C)cc1-c1ccc2ccc3cccc4ccc1c2c34 ; CC(C)(C)c1ccc2c(c1)B1c3ccc(-c4ccccc4-c4ccccc4)cc3N(c3c(-c4ccccc4)cccc3-c3ccccc3)c3cc(-n4c5ccccc5c5ccccc54)cc(c31)N2c1ccc(C(C)(C)C)cc1-c1cc2ccc3cccc4ccc(c1)c2c34]

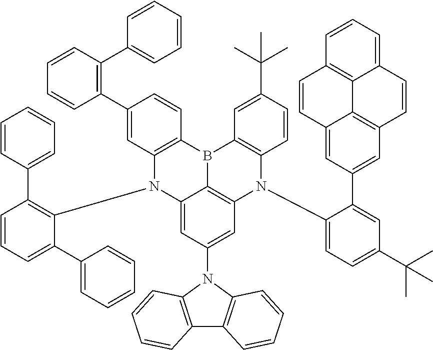 [SMILES: CC(C)(C)c1ccc2c(c1)B1c3ccc(-c4ccccc4-c4ccccc4)cc3N(c3c(-c4ccccc4)cccc3-c3ccccc3)c3cc(-n4c5ccccc5c5ccccc54)cc(c31)N2c1ccc(C(C)(C)C)cc1-c1cc2ccc3cccc4ccc(c1)c2c34]

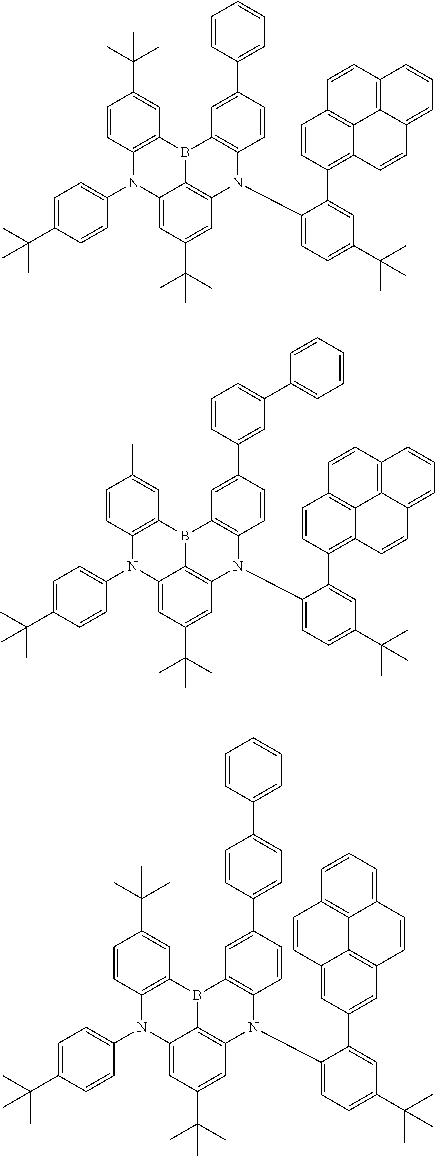 [SMILES: CC(C)(C)c1ccc(N2c3ccc(C(C)(C)C)cc3B3c4cc(-c5ccccc5)ccc4N(c4ccc(C(C)(C)C)cc4-c4ccc5ccc6cccc7ccc4c5c67)c4cc(C(C)(C)C)cc2c43)cc1 ; Cc1ccc2c(c1)B1c3cc(-c4cccc(-c5ccccc5)c4)ccc3N(c3ccc(C(C)(C)C)cc3-c3ccc4ccc5cccc6ccc3c4c56)c3cc(C(C)(C)C)cc(c31)N2c1ccc(C(C)(C)C)cc1 ; CC(C)(C)c1ccc(N2c3ccc(C(C)(C)C)cc3B3c4cc(-c5ccc(-c6ccccc6)cc5)ccc4N(c4ccc(C(C)(C)C)cc4-c4cc5ccc6cccc7ccc(c4)c5c67)c4cc(C(C)(C)C)cc2c43)cc1]

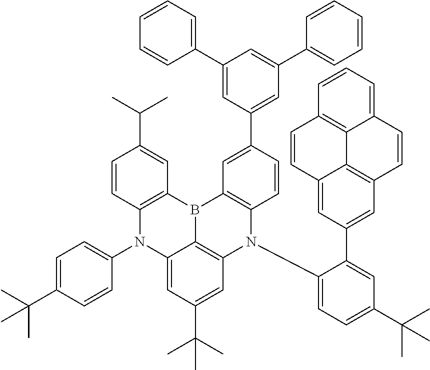 [SMILES: CC(C)c1ccc2c(c1)B1c3cc(-c4cc(-c5ccccc5)cc(-c5ccccc5)c4)ccc3N(c3ccc(C(C)(C)C)cc3-c3cc4ccc5cccc6ccc(c3)c4c56)c3cc(C(C)(C)C)cc(c31)N2c1ccc(C(C)(C)C)cc1]

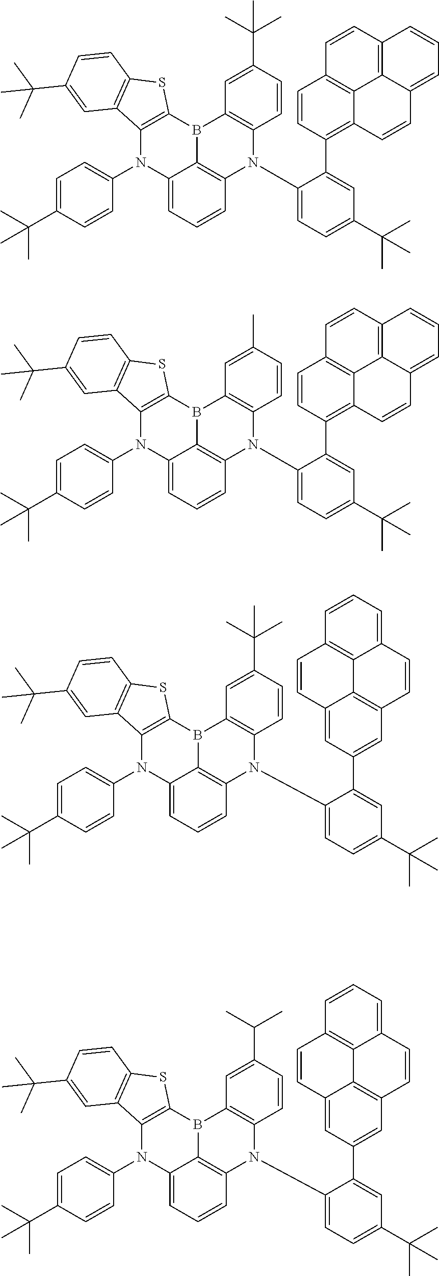

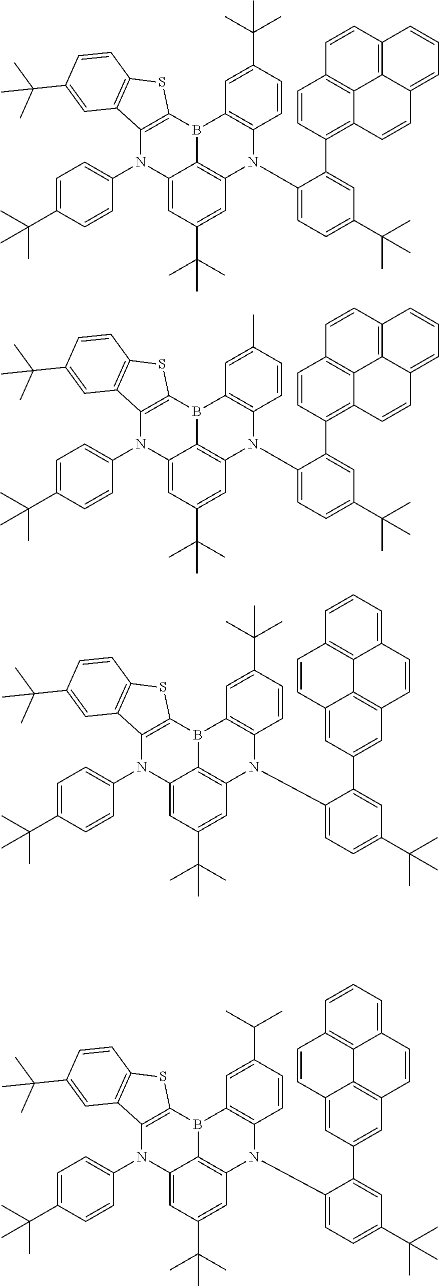

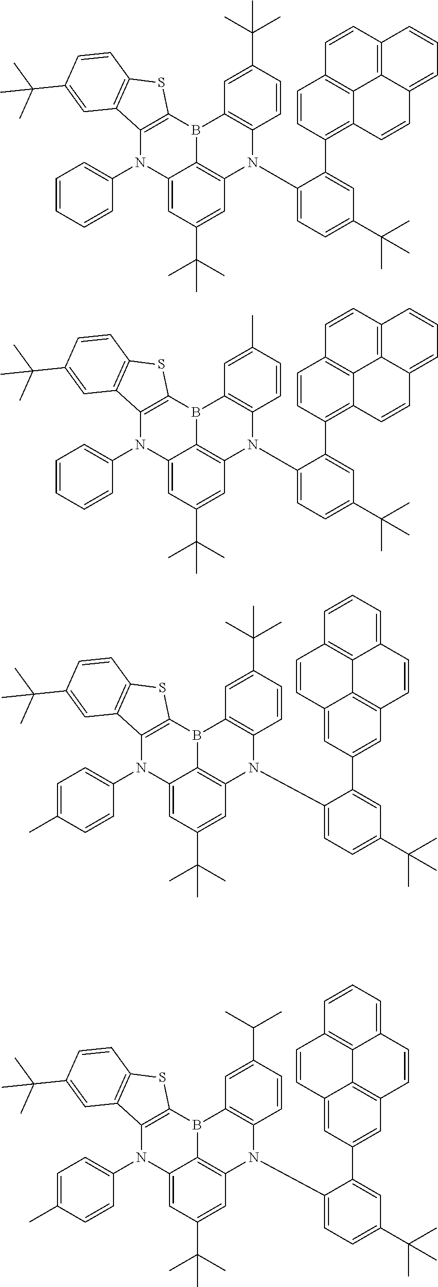

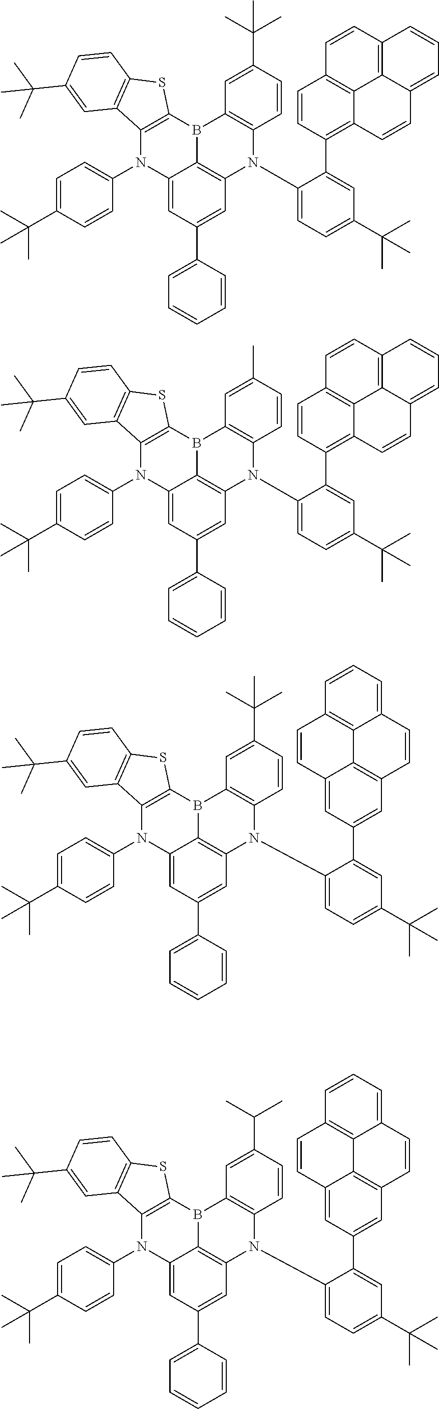

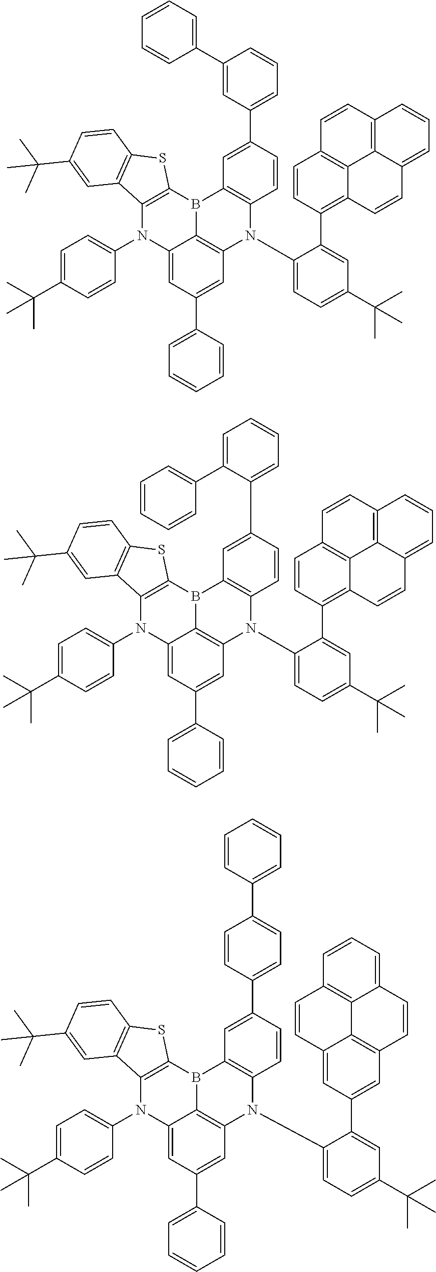 [SMILES: CC(C)(C)c1ccc(N2c3cc(-c4ccccc4)cc4c3B(c3cc(-c5cccc(-c6ccccc6)c5)ccc3N4c3ccc(C(C)(C)C)cc3-c3ccc4ccc5cccc6ccc3c4c56)c3sc4ccc(C(C)(C)C)cc4c32)cc1 ; CC(C)(C)c1ccc(N2c3cc(-c4ccccc4)cc4c3B(c3cc(-c5ccccc5-c5ccccc5)ccc3N4c3ccc(C(C)(C)C)cc3-c3ccc4ccc5cccc6ccc3c4c56)c3sc4ccc(C(C)(C)C)cc4c32)cc1 ; CC(C)(C)c1ccc(N2c3cc(-c4ccccc4)cc4c3B(c3cc(-c5ccc(-c6ccccc6)cc5)ccc3N4c3ccc(C(C)(C)C)cc3-c3cc4ccc5cccc6ccc(c3)c4c56)c3sc4ccc(C(C)(C)C)cc4c32)cc1]

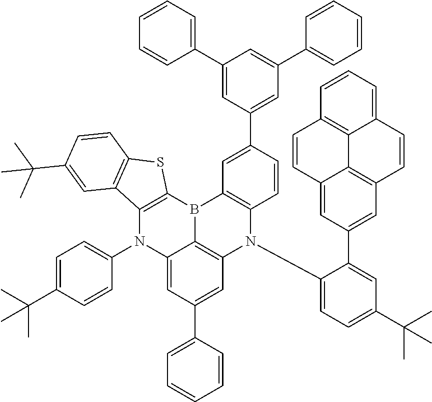 [SMILES: CC(C)(C)c1ccc(N2c3cc(-c4ccccc4)cc4c3B(c3cc(-c5cc(-c6ccccc6)cc(-c6ccccc6)c5)ccc3N4c3ccc(C(C)(C)C)cc3-c3cc4ccc5cccc6ccc(c3)c4c56)c3sc4ccc(C(C)(C)C)cc4c32)cc1]

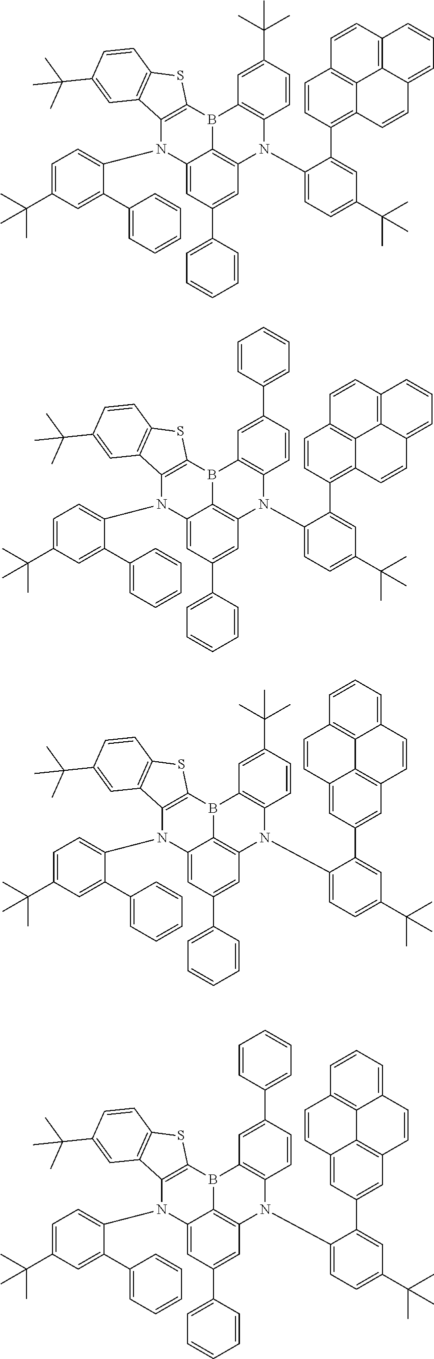

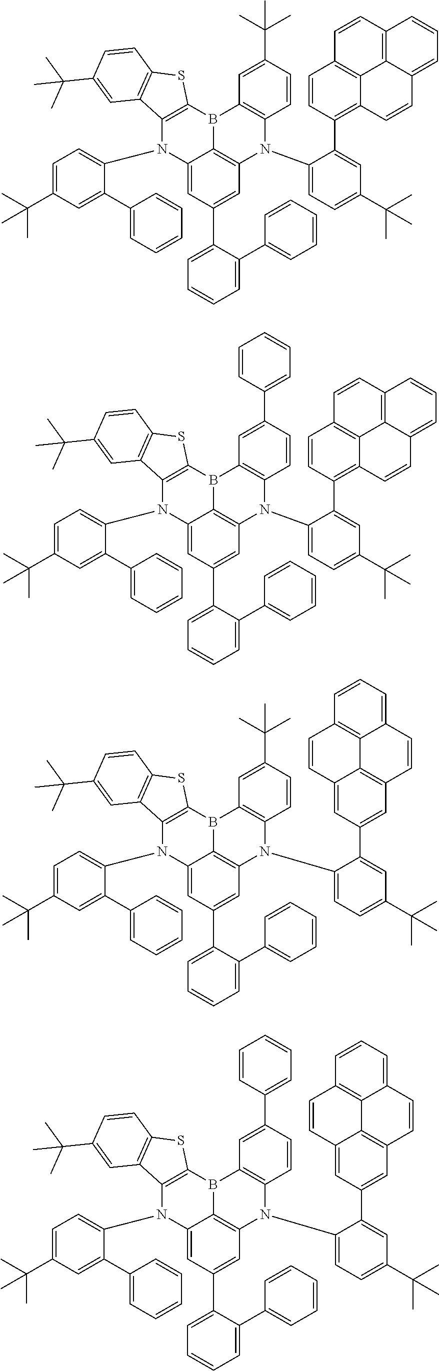

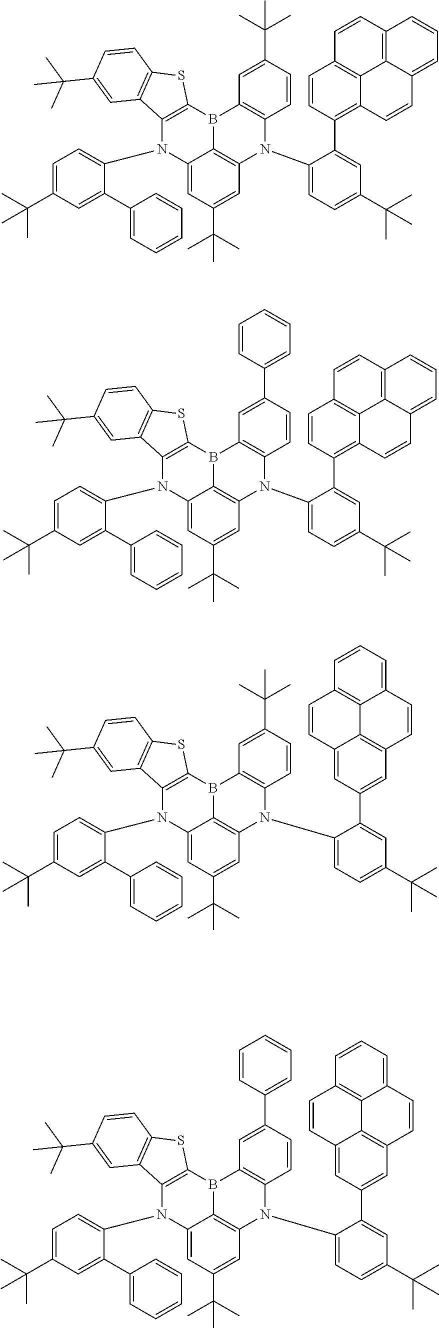

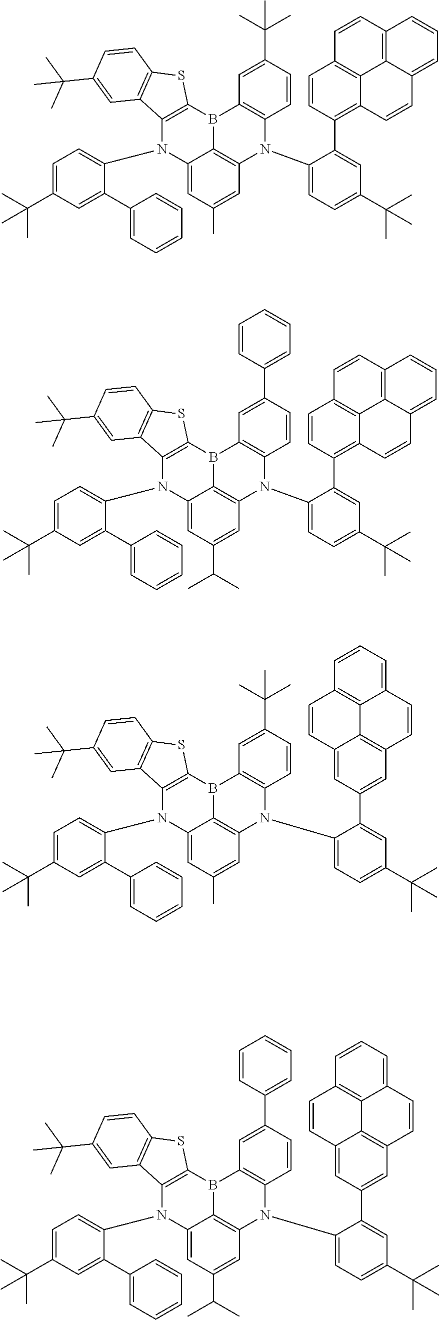

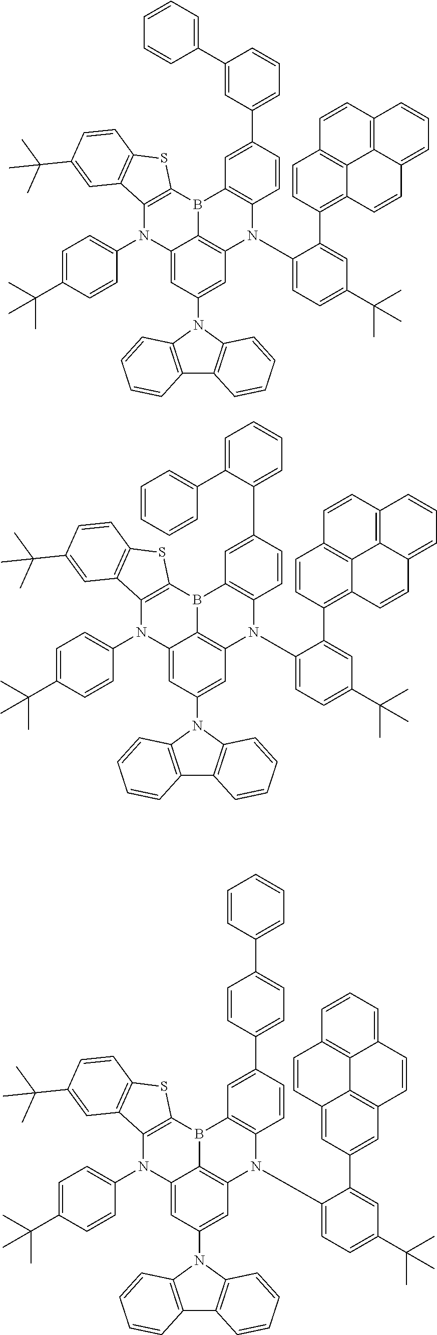

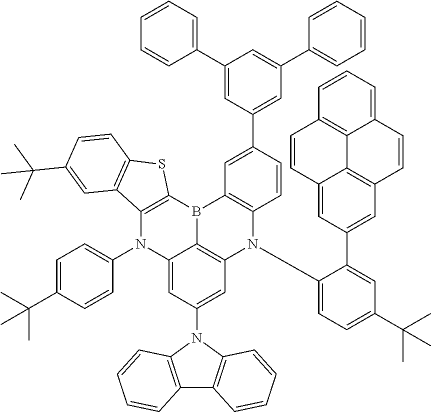 [SMILES: CC(C)(C)c1ccc(N2c3cc(-n4c5ccccc5c5ccccc54)cc4c3B(c3cc(-c5cc(-c6ccccc6)cc(-c6ccccc6)c5)ccc3N4c3ccc(C(C)(C)C)cc3-c3cc4ccc5cccc6ccc(c3)c4c56)c3sc4ccc(C(C)(C)C)cc4c32)cc1]

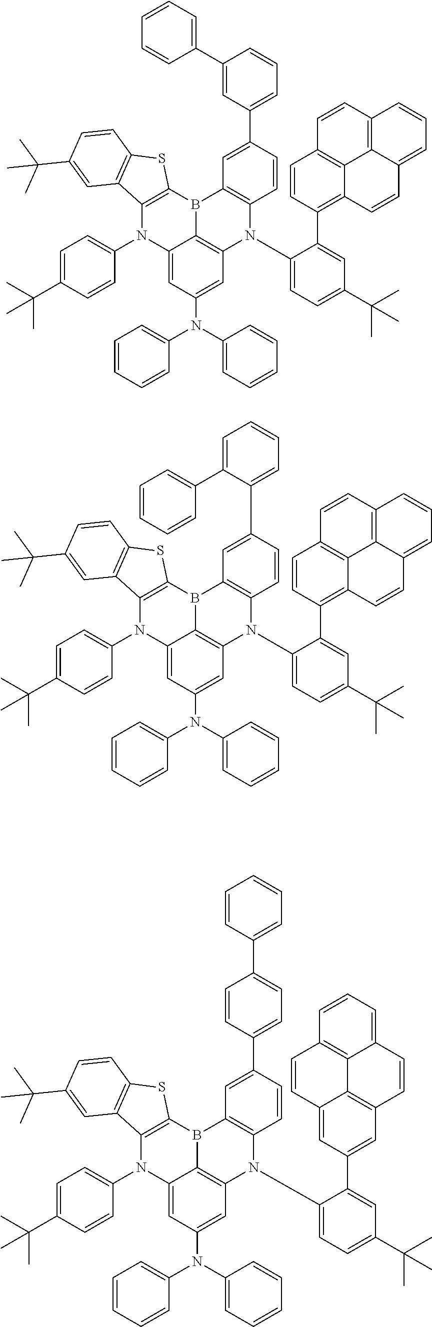

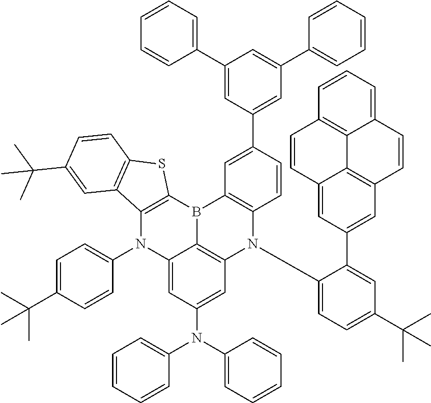 [SMILES: CC(C)(C)c1ccc(N2c3cc(N(c4ccccc4)c4ccccc4)cc4c3B(c3cc(-c5cc(-c6ccccc6)cc(-c6ccccc6)c5)ccc3N4c3ccc(C(C)(C)C)cc3-c3cc4ccc5cccc6ccc(c3)c4c56)c3sc4ccc(C(C)(C)C)cc4c32)cc1]

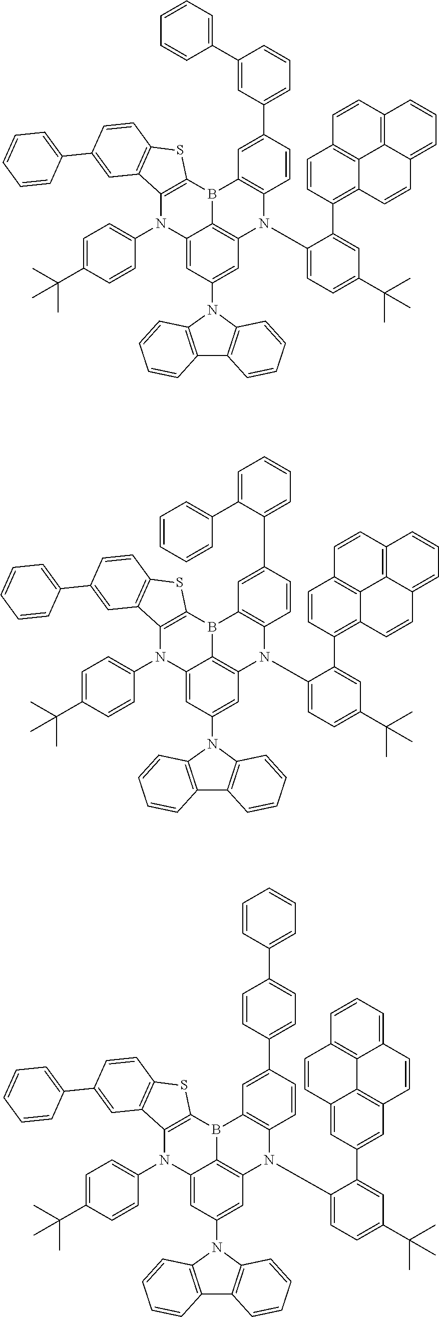 [SMILES: CC(C)(C)c1ccc(N2c3cc(-n4c5ccccc5c5ccccc54)cc4c3B(c3cc(-c5cccc(-c6ccccc6)c5)ccc3N4c3ccc(C(C)(C)C)cc3-c3ccc4ccc5cccc6ccc3c4c56)c3sc4ccc(-c5ccccc5)cc4c32)cc1 ; CC(C)(C)c1ccc(N2c3cc(-n4c5ccccc5c5ccccc54)cc4c3B(c3cc(-c5ccccc5-c5ccccc5)ccc3N4c3ccc(C(C)(C)C)cc3-c3ccc4ccc5cccc6ccc3c4c56)c3sc4ccc(-c5ccccc5)cc4c32)cc1 ; CC(C)(C)c1ccc(N2c3cc(-n4c5ccccc5c5ccccc54)cc4c3B(c3cc(-c5ccc(-c6ccccc6)cc5)ccc3N4c3ccc(C(C)(C)C)cc3-c3cc4ccc5cccc6ccc(c3)c4c56)c3sc4ccc(-c5ccccc5)cc4c32)cc1]

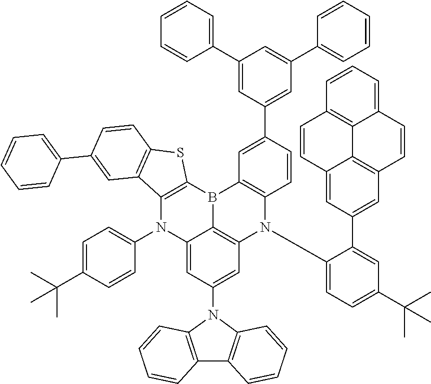 [SMILES: CC(C)(C)c1ccc(N2c3cc(-n4c5ccccc5c5ccccc54)cc4c3B(c3cc(-c5cc(-c6ccccc6)cc(-c6ccccc6)c5)ccc3N4c3ccc(C(C)(C)C)cc3-c3cc4ccc5cccc6ccc(c3)c4c56)c3sc4ccc(-c5ccccc5)cc4c32)cc1]

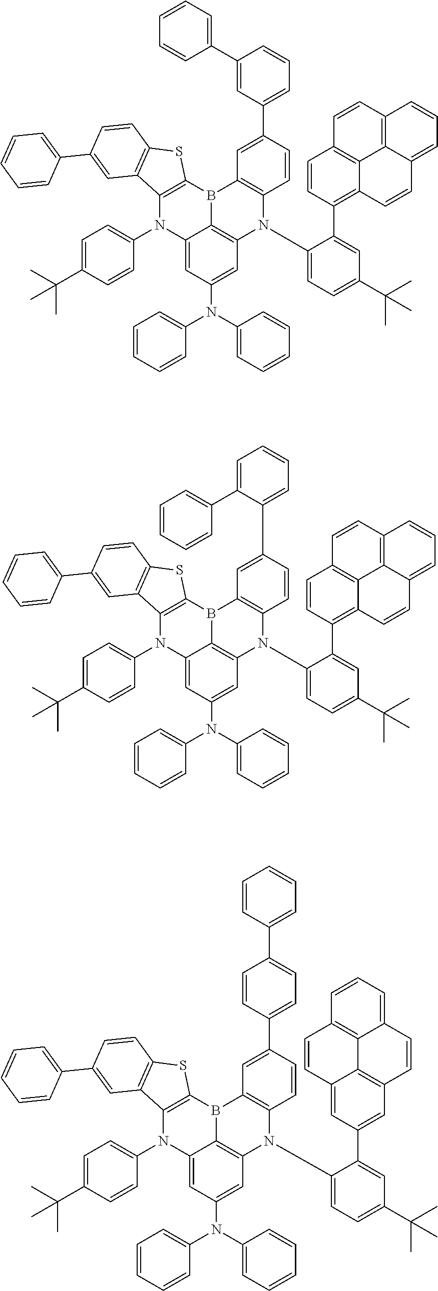 [SMILES: CC(C)(C)c1ccc(N2c3cc(N(c4ccccc4)c4ccccc4)cc4c3B(c3cc(-c5cccc(-c6ccccc6)c5)ccc3N4c3ccc(C(C)(C)C)cc3-c3ccc4ccc5cccc6ccc3c4c56)c3sc4ccc(-c5ccccc5)cc4c32)cc1 ; CC(C)(C)c1ccc(N2c3cc(N(c4ccccc4)c4ccccc4)cc4c3B(c3cc(-c5ccccc5-c5ccccc5)ccc3N4c3ccc(C(C)(C)C)cc3-c3ccc4ccc5cccc6ccc3c4c56)c3sc4ccc(-c5ccccc5)cc4c32)cc1 ; CC(C)(C)c1ccc(N2c3cc(N(c4ccccc4)c4ccccc4)cc4c3B(c3cc(-c5ccc(-c6ccccc6)cc5)ccc3N4c3ccc(C(C)(C)C)cc3-c3cc4ccc5cccc6ccc(c3)c4c56)c3sc4ccc(-c5ccccc5)cc4c32)cc1]

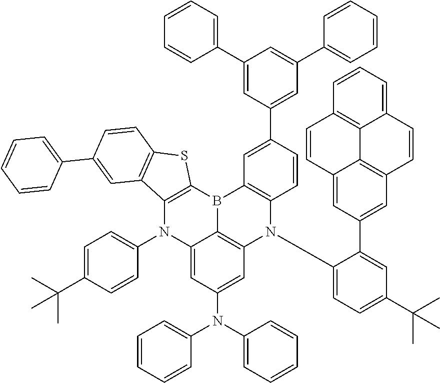 [SMILES: CC(C)(C)c1ccc(N2c3cc(N(c4ccccc4)c4ccccc4)cc4c3B(c3cc(-c5cc(-c6ccccc6)cc(-c6ccccc6)c5)ccc3N4c3ccc(C(C)(C)C)cc3-c3cc4ccc5cccc6ccc(c3)c4c56)c3sc4ccc(-c5ccccc5)cc4c32)cc1]

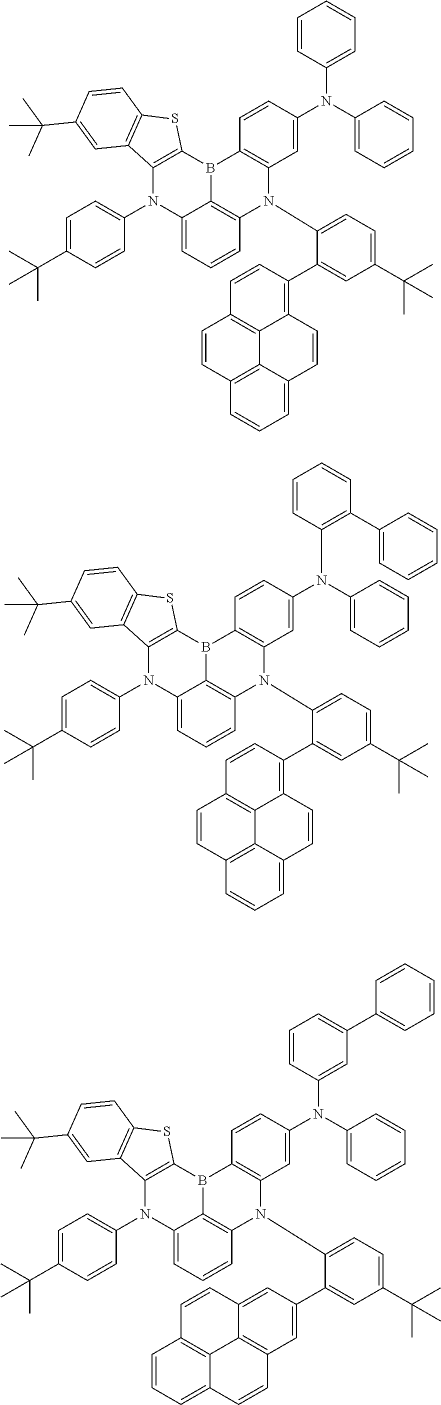

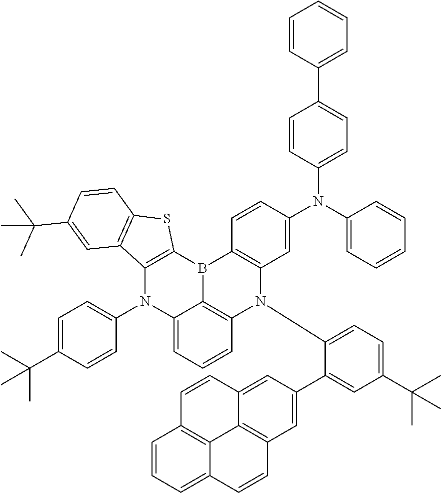 [SMILES: CC(C)(C)c1ccc(N2c3cccc4c3B(c3ccc(N(c5ccccc5)c5ccc(-c6ccccc6)cc5)cc3N4c3ccc(C(C)(C)C)cc3-c3cc4ccc5cccc6ccc(c3)c4c56)c3sc4ccc(C(C)(C)C)cc4c32)cc1]

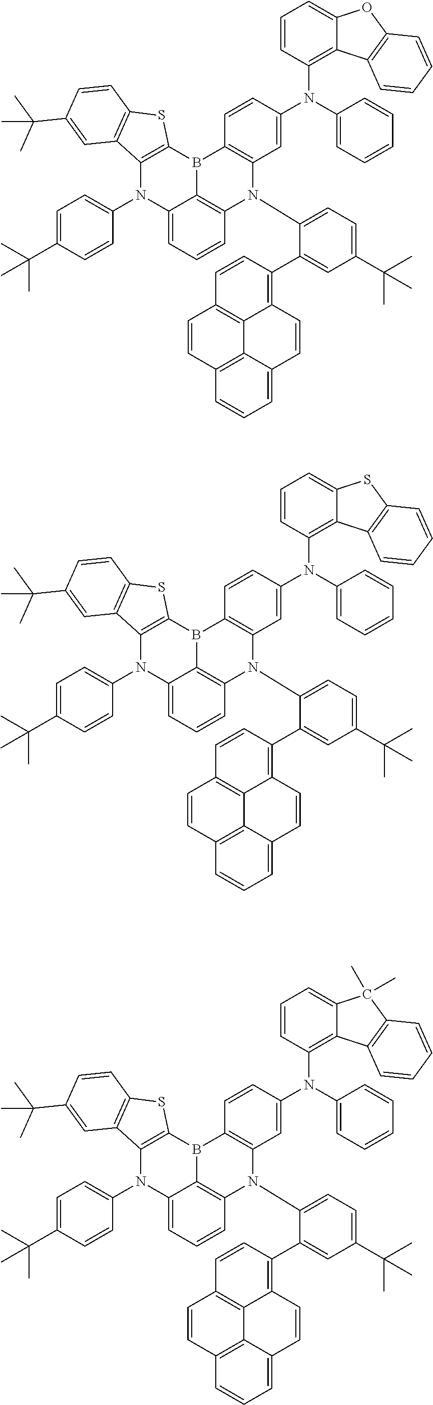 [SMILES: CC(C)(C)c1ccc(N2c3cccc4c3B(c3ccc(N(c5ccccc5)c5cccc6oc7ccccc7c56)cc3N4c3ccc(C(C)(C)C)cc3-c3ccc4ccc5cccc6ccc3c4c56)c3sc4ccc(C(C)(C)C)cc4c32)cc1 ; CC(C)(C)c1ccc(N2c3cccc4c3B(c3ccc(N(c5ccccc5)c5cccc6sc7ccccc7c56)cc3N4c3ccc(C(C)(C)C)cc3-c3ccc4ccc5cccc6ccc3c4c56)c3sc4ccc(C(C)(C)C)cc4c32)cc1 ; CC(C)(C)c1ccc(N2c3cccc4c3B(c3ccc(N(c5ccccc5)c5cccc6c5-c5ccccc5C6(C)C)cc3N4c3ccc(C(C)(C)C)cc3-c3ccc4ccc5cccc6ccc3c4c56)c3sc4ccc(C(C)(C)C)cc4c32)cc1]

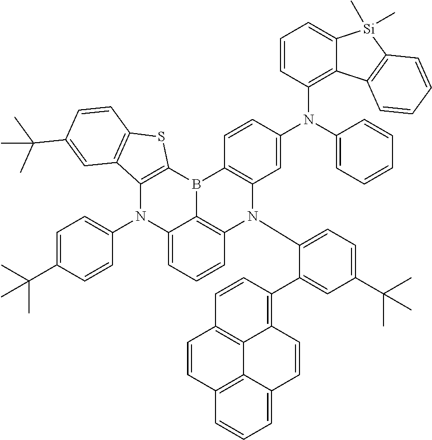 [SMILES: CC(C)(C)c1ccc(N2c3cccc4c3B(c3ccc(N(c5ccccc5)c5cccc6c5-c5ccccc5[Si]6(C)C)cc3N4c3ccc(C(C)(C)C)cc3-c3ccc4ccc5cccc6ccc3c4c56)c3sc4ccc(C(C)(C)C)cc4c32)cc1]

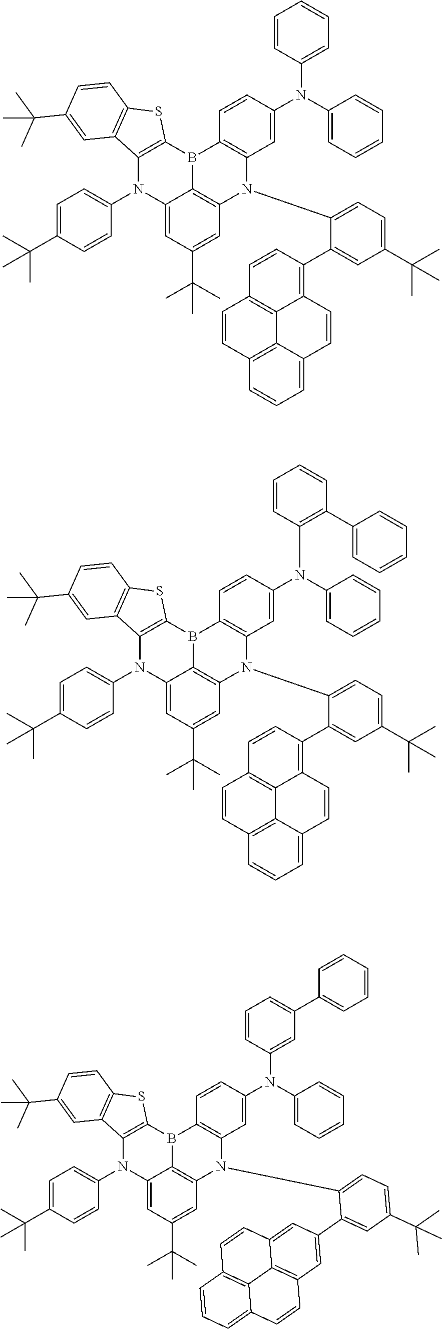

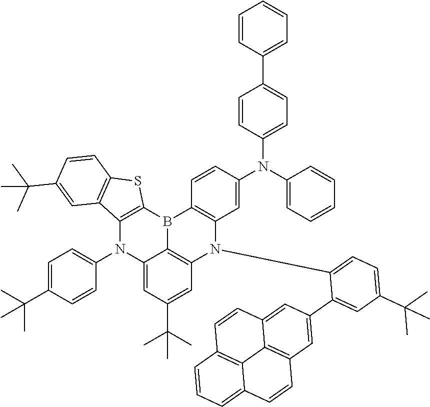 [SMILES: CC(C)(C)c1ccc(N2c3cc(C(C)(C)C)cc4c3B(c3ccc(N(c5ccccc5)c5ccc(-c6ccccc6)cc5)cc3N4c3ccc(C(C)(C)C)cc3-c3cc4ccc5cccc6ccc(c3)c4c56)c3sc4ccc(C(C)(C)C)cc4c32)cc1]

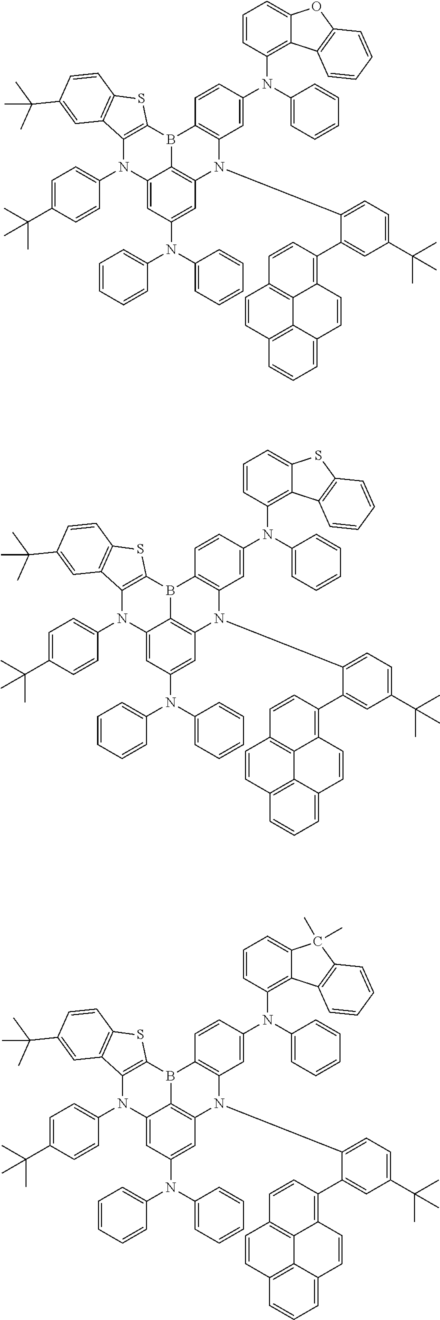

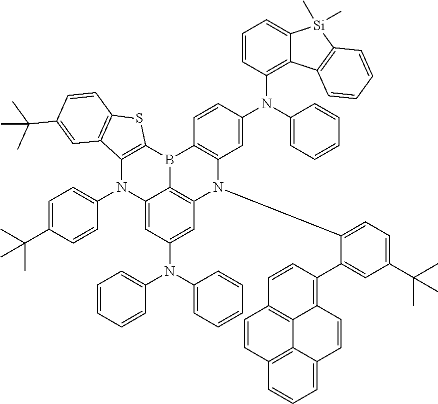 [SMILES: CC(C)(C)c1ccc(N2c3cc(N(c4ccccc4)c4ccccc4)cc4c3B(c3ccc(N(c5ccccc5)c5cccc6c5-c5ccccc5[Si]6(C)C)cc3N4c3ccc(C(C)(C)C)cc3-c3ccc4ccc5cccc6ccc3c4c56)c3sc4ccc(C(C)(C)C)cc4c32)cc1]

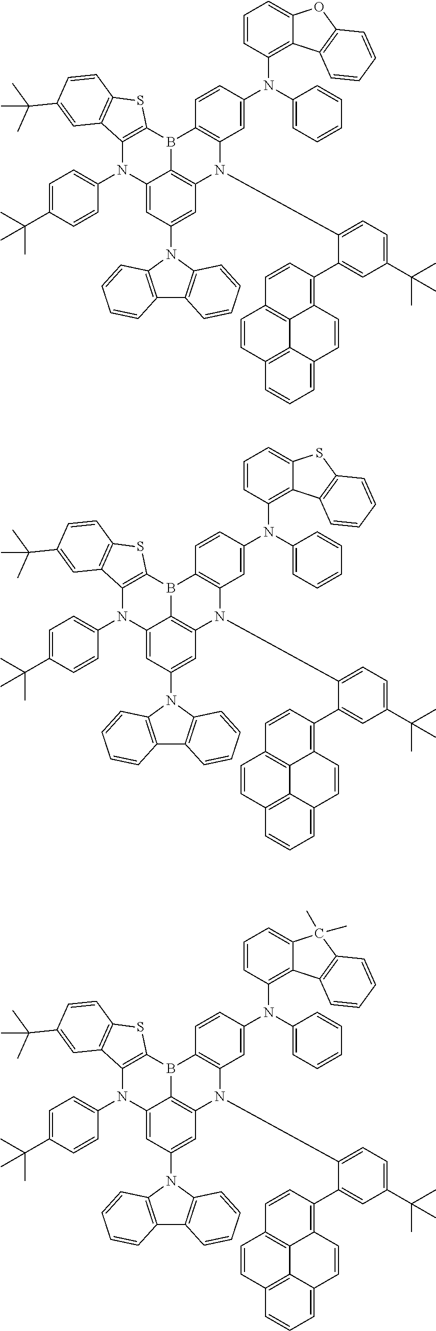

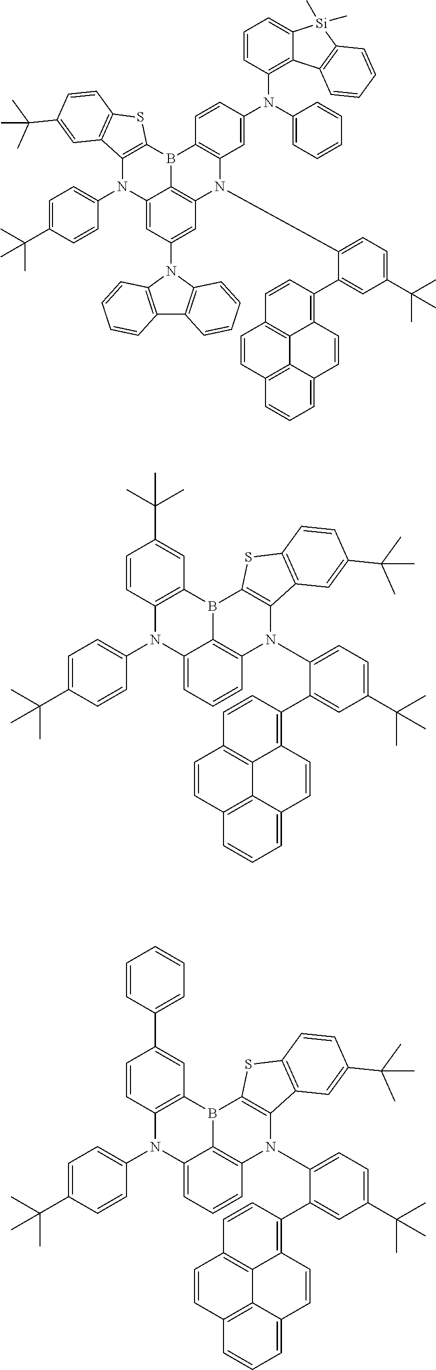

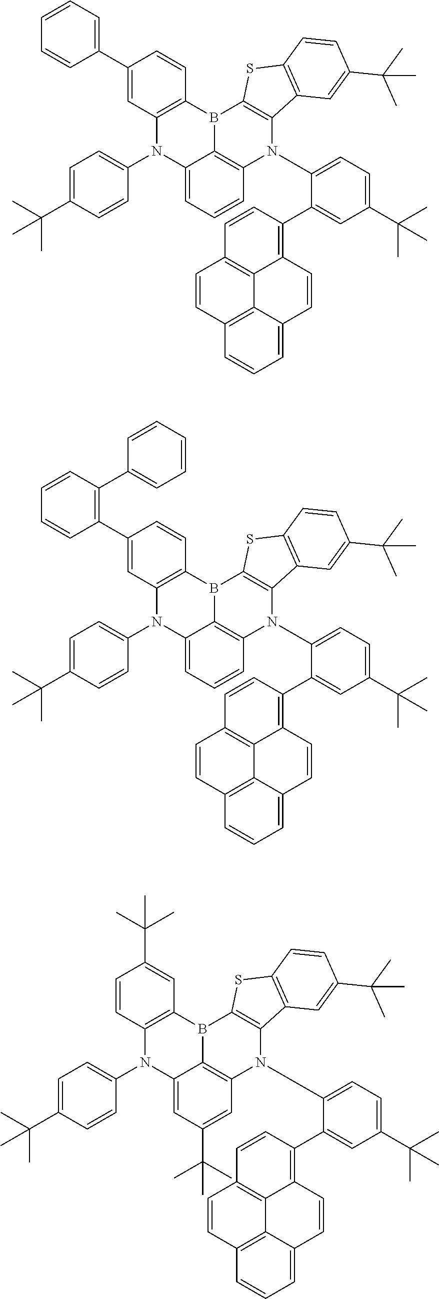

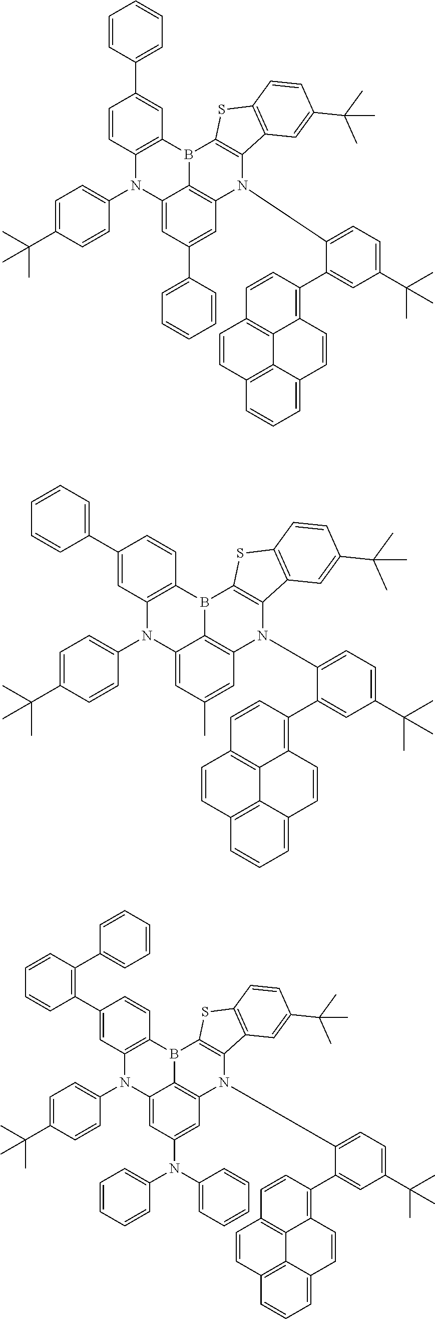

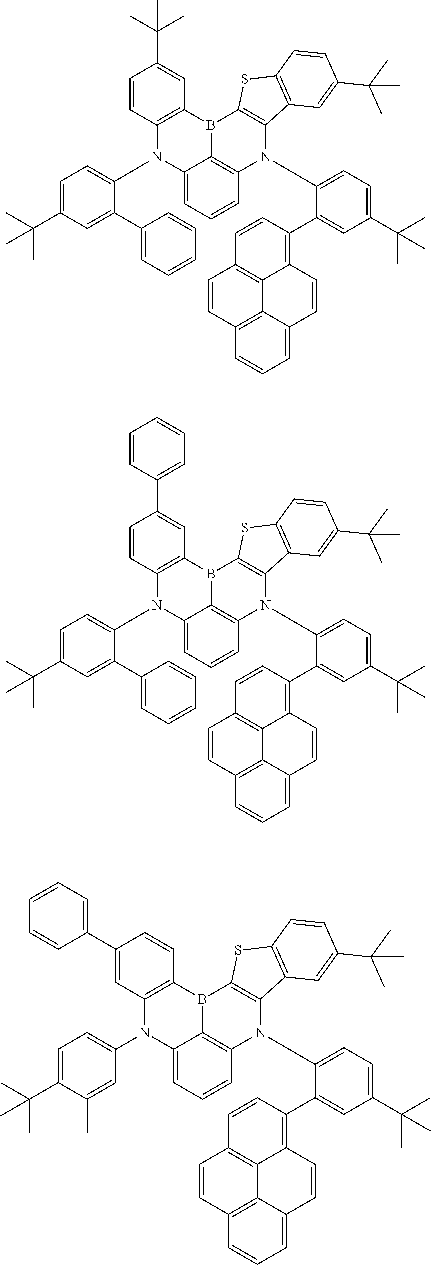

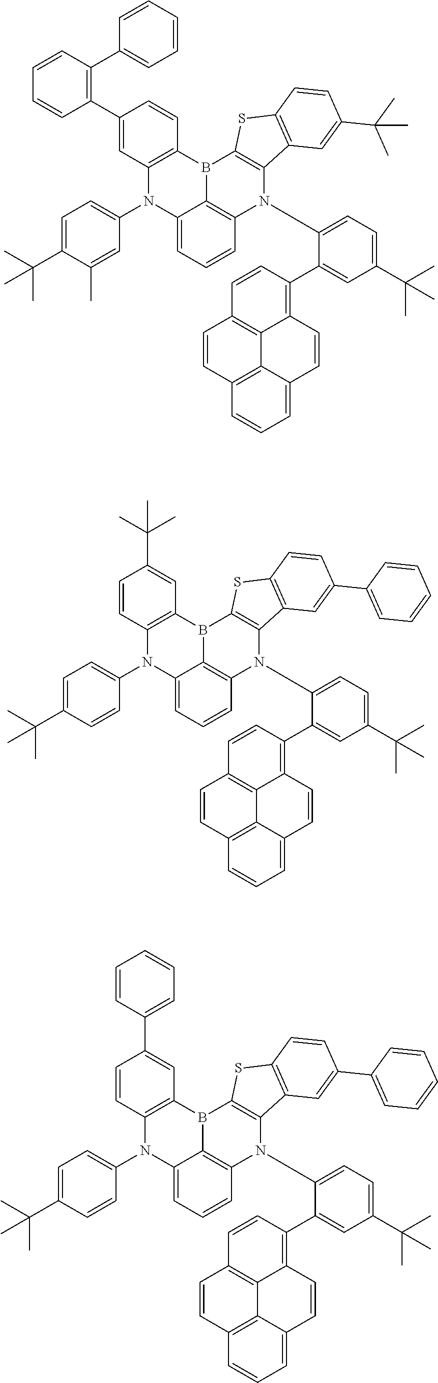

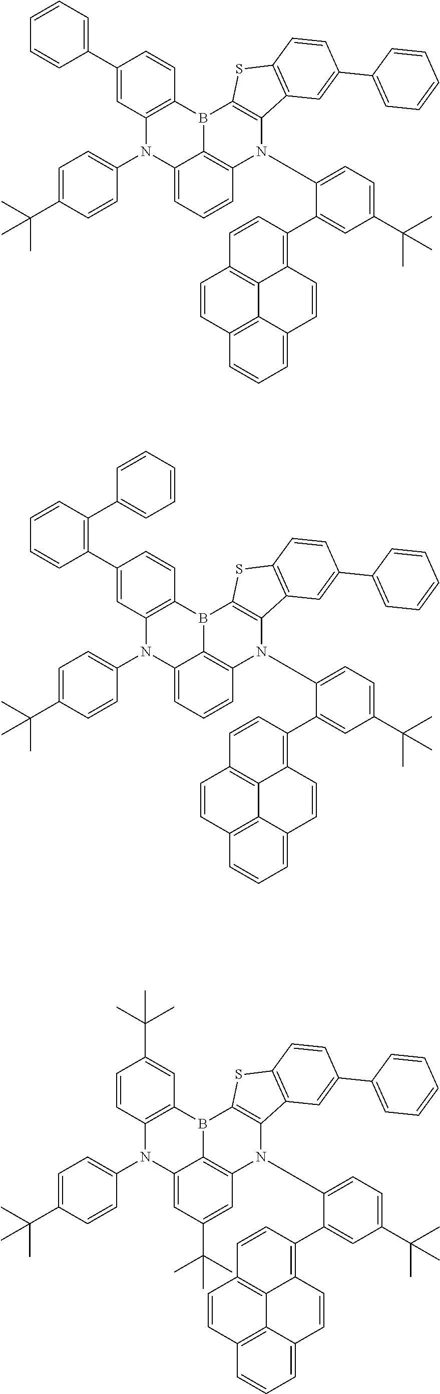 [SMILES: CC(C)(C)c1ccc(N2c3cc(-c4ccccc4)ccc3B3c4sc5ccc(-c6ccccc6)cc5c4N(c4ccc(C(C)(C)C)cc4-c4ccc5ccc6cccc7ccc4c5c67)c4cccc2c43)cc1 ; CC(C)(C)c1ccc(N2c3cc(-c4ccccc4-c4ccccc4)ccc3B3c4sc5ccc(-c6ccccc6)cc5c4N(c4ccc(C(C)(C)C)cc4-c4ccc5ccc6cccc7ccc4c5c67)c4cccc2c43)cc1 ; CC(C)(C)c1ccc(N2c3ccc(C(C)(C)C)cc3B3c4sc5ccc(-c6ccccc6)cc5c4N(c4ccc(C(C)(C)C)cc4-c4ccc5ccc6cccc7ccc4c5c67)c4cc(C(C)(C)C)cc2c43)cc1]

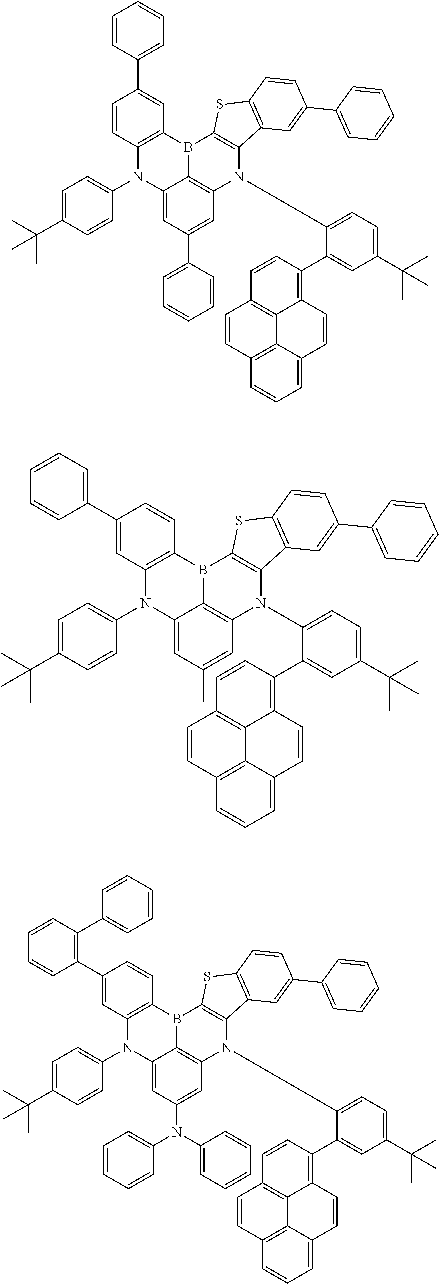

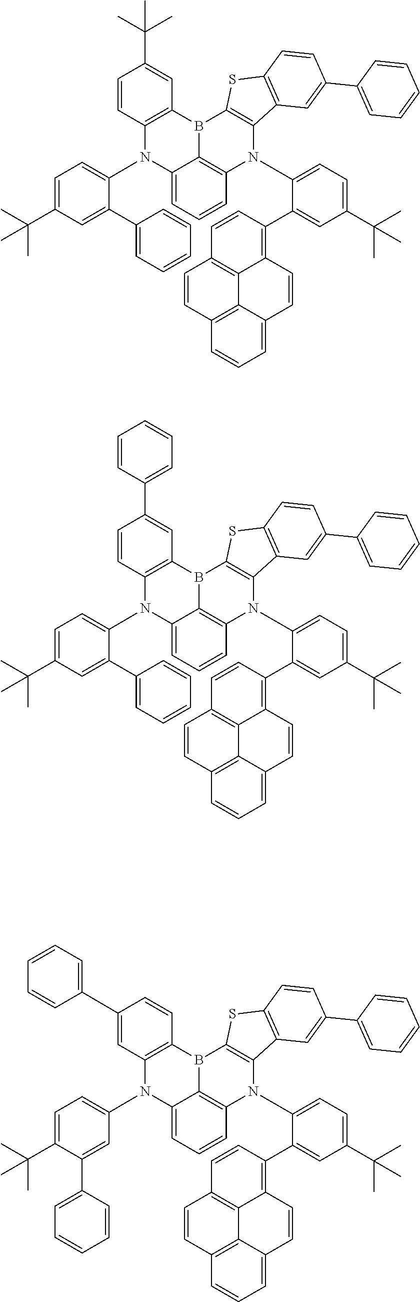 [SMILES: CC(C)(C)c1ccc2c(c1)B1c3sc4ccc(-c5ccccc5)cc4c3N(c3ccc(C(C)(C)C)cc3-c3ccc4ccc5cccc6ccc3c4c56)c3cccc(c31)N2c1ccc(C(C)(C)C)cc1-c1ccccc1 ; CC(C)(C)c1ccc(N2c3ccc(-c4ccccc4)cc3B3c4sc5ccc(-c6ccccc6)cc5c4N(c4ccc(C(C)(C)C)cc4-c4ccc5ccc6cccc7ccc4c5c67)c4cccc2c43)c(-c2ccccc2)c1 ; CC(C)(C)c1ccc(N2c3cccc4c3B(c3ccc(-c5ccccc5)cc3N4c3ccc(C(C)(C)C)c(-c4ccccc4)c3)c3sc4ccc(-c5ccccc5)cc4c32)c(-c2ccc3ccc4cccc5ccc2c3c45)c1]

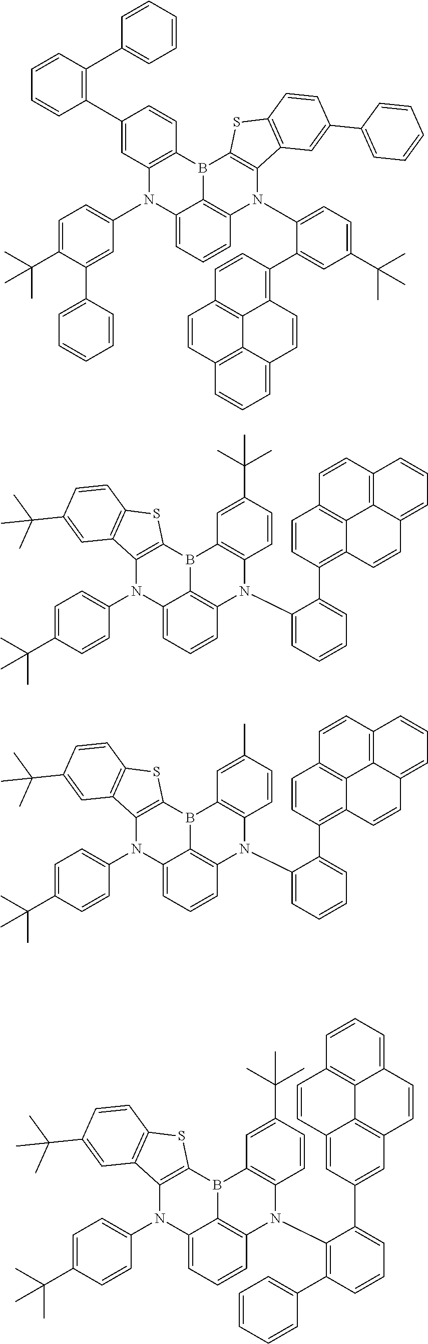

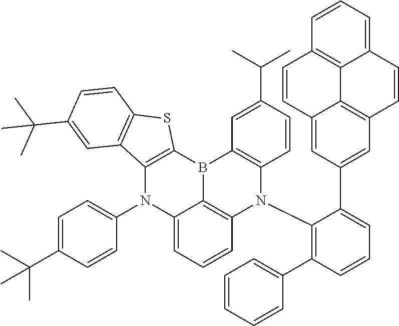 [SMILES: CC(C)c1ccc2c(c1)B1c3sc4ccc(C(C)(C)C)cc4c3N(c3ccc(C(C)(C)C)cc3)c3cccc(c31)N2c1c(-c2ccccc2)cccc1-c1cc2ccc3cccc4ccc(c1)c2c34]

The boron-nitrogen compound provided by the present disclosure can be used as an organic functional material in a functional layer of an organic electronic device, such as an OLED device. The functional layer includes, but not limited to, a hole injection layer, a hole transport layer, an electron transport layer, an electron injection layer, an electron blocking layer, a hole blocking layer, and a light-emitting layer.

In some embodiments, the boron-nitrogen compound provided by the present disclosure can be used in a light-emitting layer.

In some embodiments, the boron-nitrogen compound provided by the present disclosure can be used in a light-emitting layer for a blue light organic electronic device.

In some embodiments, the boron-nitrogen compound provided by the present disclosure can be used as a guest material for a light-emitting layer of a blue light organic electronic device.

The present disclosure further provides a mixture that includes at least one boron-nitrogen compound as described above and at least one organic functional material. The at least one organic functional material may be selected from a hole injection material, a hole transport material, an electron transport material, an electron injection material, an electron blocking material, a hole blocking material, a light-emitting host material, a light-emitting guest material, or an organic dye. The light-emitting guest material is selected from a singlet state of an emitter (such as a fluorescent emitter), a triplet state of an emitter (such as a phosphorescent emitter), or a thermal activation delayed fluorescence (TADF) material. The above-mentioned organic functional materials are described in detail in applications WO2010135519A1, US20090134784A1, and WO2011110277A1. Therefore, all contents of these three applications are hereby incorporated as a reference in the present disclosure.

In some embodiments, when the organic functional material is selected from one or more of the hole injection material, the hole transport material, the electron transport material, the hole blocking material, the light-emitting host material, and the organic dye, a mass ratio of the boron-nitrogen compound to the organic functional material ranges from 1:99 to 30:70 by a total weight of the mixture. In other embodiments, the mass ratio of the boron-nitrogen compound to the organic functional material ranges from 1:99 to 10:90.

In some embodiments, when the organic functional material is selected from the light-emitting guest material, the mass ratio of the boron-nitrogen compound to the organic functional material ranges from 99:1 to 70:30 by the total weight of the mixture. In other embodiments, the mass ratio of the boron-nitrogen compound to the organic functional material ranges from 99:1 to 90:10.

The present disclosure further provides a composition including at least one boron-nitrogen compound or the mixture as described above, and an organic solvent. The organic solvent may include a first organic solvent, and the first organic solvent may be selected from an aromatic-based solvent, an heteroaromatic-based solvent, an ester-based solvent, an aromatic ketone-based solvent, an aromatic ether-based solvent, an aliphatic ketone-based solvent, an aliphatic ether-based solvent, an alicyclic compound, an olefin compound, a borate ester compound, a phosphate ester compound, or a mixture of two or more than two organic solvents as described above.

In some embodiments, the first organic solvent is selected from an aromatic-based solvent or a heteroaromatic-based solvent. The aromatic-based solvent or the heteroaromatic-based solvent may be selected from but not limited to at least one of p-diisopropylbenzene, pentyl benzene, tetrahydronaphthalene, cyclohexylbenzene, chloronaphthalene, 1,4-dimethylnaphthalene, 3-isopropylbiphenyl, p-methylisopropyl benzene, dipentyl benzene, tripentyl benzene, pentyl toluene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butyl benzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-isopropyltoluene, 1-methylnaphthalene, 1,2,4-trichlorobenzene, 4,4-difluorodiphenylmethane, 1,2-dimethoxy-4-(1-propenyl) benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl) pyridine, benzyl benzoate, 1,1-bis(3,4-dimethylphenyl)ethane, 2-isopropylnaphthalene, quinoline, isoquinoline, methyl 2-furanoate, and ethyl 2-furanoate.

In some embodiments, the first organic solvent is selected from an aromatic ketone-based solvent. The aromatic ketone-based solvent may be selected from but not limited to at least one of 1-tetralone, 2-tetrahydronaphthalenone, 2-(phenylepoxy) tetrahydronaphthalenone, 6-(methoxyl)tetrahydronaphthalenone, acetophenone, phenylacetone, benzophenone, and derivatives of these compounds. For example, the above-mentioned derivatives may be selected from at least one of 4-methylacetophenone, 3-methylacetophenone, 2-methylacetophenone, 4-methylphenylacetone, 3-methylphenylacetone, and 2-methylphenylacetone.

In some embodiments, the first organic solvent is selected from an aromatic ether-based solvent. The aromatic ether-based solvent may be selected from but not limited to at least one of 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylphenyl ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenylanisole, 1,2-dimethoxybenzene, 1-methoxynapthalene, diphenyl ether, 2-phenoxymethyl ether, 2-phenoxytetrahydrofuran, and ethyl 2-naphthyl ether.

In some embodiments, the first organic solvent is selected from an aliphatic ketone-based solvent. The aliphatic ketone-based solvent may be selected from but not limited to at least one of 2-nonanone, 3-nonanone, 5-nonanone, 2-decanone, 2,5-hexanedione, 2,6,8-trimethyl-4-nonanone, fenchone, phorone, isophorone, and amyl ketone. In some embodiments, the first organic solvent is selected from an aliphatic ether-based solvent, and the aliphatic ether-based solvent may be selected from but not limited to at least one of amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, and tetraethylene glycol dimethyl ether.

In some embodiments, the first organic solvent is selected from an ester-based solvent. The ester-based solvent may be selected from but not limited to at least one of alkyl octanoate, alkyl sebacate, alkyl stearate, alkyl benzoate, alkyl phenylacetate, alkyl cinnamate, alkyl oxalate, alkyl maleate, alkyl lactone, alkyl oleate, and the like. Preferably, the ester-based solvent may be selected from at least one of octyl octanoate, diethyl sebacate, diallyl phthalate, and isononyl isononanoate.

In some embodiments, the organic solvent may also include a second organic solvent, examples of the second organic solvent include, but not limited to, methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decahydronaphthalene, indene, and/or mixtures thereof.

In some embodiments, organic solvents suitable for the present disclosure have Hansen solubility parameters within the following ranges: δd (a dispersion force) ranges from 17.0 MPa^{1/2} to 23.2 MPa^{1/2}, preferably from 18.5 MPa^{1/2} to 21.0 MPa^{1/2}; δp (a polarity force) ranges from 0.2 MPa^{1/2} to 12.5 MPa^{1/2}, preferably from 2.0 MPa^{1/2} to 6.0 MPa^{1/2}; and δh (a hydrogen bonding force) ranges from 0.9 MPa^{1/2} to 14.2 MPa^{1/2}, preferably from 2.0 MPa^{1/2} to 6.0 MPa^{1/2}.

In some embodiments, according to the composition of the present disclosure, a boiling point needs to be considered when selecting the organic solvent. In some specific embodiments, the boiling point of the organic solvent is greater than or equal to 150° C., 180° C., 200° C., 250° C., or 300° C. The boiling point within these ranges are beneficial to prevent nozzles of inkjet printing heads from clogging.

It can be understood that, the organic solvent can be evaporated from a solvent system to form a film including the boron-nitrogen compound.

In some embodiments, the composition may be a solution. In other embodiments, the composition may be a suspension. The solution or the suspension may also include an additive for adjusting viscosity, forming performance of a film, improving adhesion, and the like. The additive may be selected from but not limited to at least one of a surfactant, a lubricant, a wetting agent, a dispersant, a hydrophobic agent, and an adhesive.

In some embodiments, a mass percentage of the boron-nitrogen compound or the mixture in the composition may range from 0.01 wt % to 10 wt %. In some specific embodiments, the mass percentage of the boron-nitrogen compound or the mixture in the composition may range from 0.1 wt % to 15 wt %, 0.2 wt % to 5 wt %, or 0.25 wt % to 3 wt %.

In some embodiments, the composition may be ink, and the viscosity and surface tension of the ink are important parameters when used for printing processes. Appropriate surface tension parameters of the ink are suitable for specific substrates and specific printing methods. In some embodiments, the surface tension of the ink according to the present disclosure approximately ranges from 19 dyne/cm to 50 dyne/cm at an operation temperature or at a temperature of 25° C. For example, the surface tension of the ink may range from 22 dyne/cm to 35 dyne/cm, or from 25 dyne/cm to 33 dyne/cm. In some embodiments, the viscosity of the ink according to the present disclosure approximately ranges from 1 cps to 100 cps at an operation temperature or at a temperature of 25° C. For example, the viscosity of the ink may range from 1 cps to 50 cps, 1.5 cps to 20 cps, or 4.0 cps to 20 cps. The composition prepared in this way will facilitate the application in inkjet printing processes.

The present disclosure further provides a use of the composition as a coating material or printing ink in the preparation for organic electronic devices. In some embodiments, the composition may be used to prepare the organic electronic devices by a printing process or a coating process. The printing process or the coating process may include, but not limited to, inkjet printing, intaglio printing, jet printing, letterpress printing, screen printing, dip coating, rotating coating, scraper coating, roller printing, rotary roller printing, lithographic printing, flexographic printing brush, rotary printing, spray coating, brush coating or pad printing, slit extrusion coating, or the like. Preferably, the printing process or the coating process is selected from intaglio printing, jet printing, or inkjet printing.

The present disclosure further provides a use of the boron-nitrogen compound, the mixture, or the composition as described above in the preparation for an organic electronic device. The organic electronic device includes a first electrode, a second electrode, and one or more organic functional layers disposed between the first electrode and the second electrode. At least one organic functional layer includes the boron-nitrogen compound or the mixture as described above, or is prepared by the above-mentioned composition. In some specific embodiments, the organic electronic device includes a cathode, an anode, and one or more organic functional layers disposed between the cathode and the anode.

The organic electronic device may be, but not limited to, an OLED, an organic photovoltaic battery (OPV), an organic light-emitting battery (OLEEC), an organic field-effect tube (OFET), an organic light-emitting field-effect tube, an organic laser, an organic spin electron device, an organic sensor, an organic plasmon emission diode (OPED), or the like. In some embodiments, the organic electronic device may be an organic electroluminescent device, such as the OLED or the organic light-emitting field-effect tube. Preferably, the organic electronic device is the OLED.

In some embodiments, the organic functional layer is a single-layer structure. For example, the organic functional layer may be selected from any one of a hole injection layer (HIL), a hole transport layer (HTL), a light-emitting layer, an electron blocking layer (EBL), an electron injection layer (EIL), an electron transport layer (ETL), and a hole blocking layer (HBL).

In some embodiments, the organic functional layer is a multi-layer structure. For example, the organic functional layer may be selected from a hole injection layer, a hole transport layer, a light-emitting layer, an electron blocking layer, an electron injection layer, an electron transport layer, and a hole blocking layer.

In some embodiments, the organic functional layer includes at least a light-emitting layer including the boron-nitrogen compound or the mixture as described above, or is prepared by the above-mentioned composition. The light-emitting layer may include a light-emitting host material and a light-emitting guest material, and the light-emitting guest material is the boron-nitrogen compound as described above.

In some embodiments, a mass ratio of the light-emitting host material to the light-emitting guest material ranges from 99:1 to 70:30 by a total weight of materials in the light-emitting layer, for example, 90:10, 85:15, 80:20, or 75:25. In some embodiments, the mass ratio of the light-emitting host material to the light-emitting guest material ranges from 99:1 to 90:10, for example, 97:3, 96:4, 95:5, 93:7, or 92:8. When the light-emitting guest material is dispersed in the light-emitting host material, and the mass ratio of the light-emitting host material to the light-emitting guest material ranges from 99:1 to 70:30, it is conducive to inhibiting crystallization of the light-emitting layer and suppressing concentration quenching of the light-emitting guest material caused by high concentration, thus improving luminous efficiency of light-emitting devices.

In some embodiments, the organic electronic device is an OLED having an emission wavelength ranging from 300 nm to 1000 nm. For example, the above-mentioned emission wavelength may range from 350 nm to 900 nm, 400 nm-800 nm, or the like.

In some embodiments, the organic electronic device is an OLED that includes at least a substrate, an anode, a light-emitting layer, and a cathode disposed in sequence.

The substrate may be a transparent substrate or an opaque substrate. In addition, the substrate may be rigid or elastic. Specifically, the substrate may be made of plastics or a metal, or the substrate may be a semiconductor wafer or glass. The substrate preferably has a smooth surface. For example, the substrate without surface defects is a particular and ideal choice. In some embodiments, the substrate may be flexible, and the substrate may be a polymer film or a material of the substrate is plastics. A glass transition temperature Tg of the material of the substrate may be greater than or equal to 150° C., for example, greater than or equal to 200° C., 250° C., or 300° C. Examples of materials of a suitable flexible substrate include polyethylene terephthalate (PET) and polyethylene naphthalene-2,6-dicarboxylate (PEN).

The anode is an electrode used for injecting holes, and the holes in the anode may be easily injected into the hole injection layer, the hole transport layer, or the light-emitting layer. A material of the anode may include at least one of a conductive metal, a conductive metal oxide, and a conductive polymer. In some embodiments, absolute value of a difference between work function of the anode and highest occupied molecular orbital (HOMO) energy level or valence band energy level of an emitter of the light-emitting layer, or a p-type semiconductor material of the HIL, the HTL, or the EBL is less than 0.5 eV, preferably less than 0.3 eV, more preferably less than 0.2 eV. Examples of the material of the anode include, but not limited to, aluminum (Al), copper (Cu), aurum (Au), argentum (Ag), magnesium (Mg), ferrum (Fe), cobalt (Co), nickel (Ni), manganese (Mn), palladium (Pd), platinum (Pt), indium tin oxide (ITO), aluminum doped zinc oxide (AZO), and the like. Other suitable materials of the anode are known in the art, and can be easily selected for use by ordinary skilled in the art. The material of the anode can be deposited using any suitable technology, such as a physical vapor deposition method including RF magnetron sputtering, vacuum thermal evaporation, electron beam (e-beam), or the like. Further, in some embodiments, the anode is a patterned structure.

The light-emitting layer can emit red light, green light, or blue light, and may be made of phosphorescent materials or fluorescent materials. The light-emitting material in the light-emitting layer may be a material that can receive holes and electrons from the hole transport layer and the electron transport layer, respectively, and combine them to emit light in a visible light region. Preferably, the light-emitting material is a material having good fluorescent quantum efficiency or phosphorescent quantum efficiency.

Examples of a light-emitting host material used for the light-emitting layer include a fused aromatic derivative or a heteroaromatic compound. Specifically, examples of the fused aromatic derivative include, but not limited to, an anthracene derivative, a pyrene derivative, a naphthalene derivative, a pentacene derivative, a phenanthrene compound, a fluoranthene compound, or the like. Examples of the heteroaromatic compound include, but not limited to, a carbazole derivative, a dibenzofuran derivative, a ladder type of furan compound, a pyrimidine derivative, and the like.

The cathode is an electrode used for injecting electrons, and the electrons in the cathode can be easily injected into the electron injection layer, the electron transport layer, or the light-emitting layer. A material of the cathode may include a conductive metal and/or a conductive metal oxide. In some embodiments, absolute value of a difference between work function of the cathode and lowest unoccupied molecular orbital (LUMO) energy level or valence band energy level of the emitter of the light-emitting layer, or a n-type semiconductor material of the EIL, the ETL, or the HBL is less than 0.5 eV, preferably less than 0.3 eV, more preferably less than 0.2 eV In principle, all materials that can be used in the cathode of an organic electronic device can be used as the material of the cathode of the organic electronic device according to the present disclosure. Examples of the material of the cathode include, but not limited to, Al, Au, Ag, calcium (Ca), barium (Ba), Mg, LiF/Al, Mg—Ag alloy, BaF₂/Al, Cu, Fe, Co, Ni, Mn, Pd, Pt, ITO, and the like. The material of the cathode can be deposited using any suitable technology, such as a suitable physical vapor deposition method including RF magnetron sputtering, vacuum thermal evaporation, electron beam (e-beam), or the like.

In some embodiments, the OLED further includes a hole injection layer, a hole transport layer, an electron injection layer, and an electron transport layer.

The hole injection layer can be used for promoting an injection of holes from the anode to the light-emitting layer. A hole injection material in the hole injection layer can receive holes injected from a positive electrode at low voltages. Preferably, HOMO energy level of the hole injection material is between work function of a positive electrode material and HOMO energy level of a peripheral organic material layer. Specific examples of the hole injection material include, but not limited to, metalloporphyrin, oligothiophene, an organic material based on arylamine, an organic material based on hexacyano hexaazabenzophenanthrene, an organic material based on quinacridone, an organic material based on perylene, anthraquinone, conductive polymer based on polyaniline, polythiophene, and the like.

The hole transport layer can be used for transmitting holes. A hole transport material in the hole transport layer has high hole mobility, which is known in the art, and can receive holes transmitted from the anode or the hole injection layer and transmit the holes to the light-emitting layer. Specific examples of the hole transport material include, but not limited to, an organic material based on aromatic amine, an organic material based on carbazole, a conductive polymer, a block copolymer with both conjugated and non-conjugated portions.

The electron injection layer can be used for injecting electrons. Preferably, an electron injection material in the electron injection layer has ability to transmit electrons, and can achieve an effect of injecting electrons from a negative electrode and an excellent effect of injecting electrons into the light-emitting layer or the light-emitting material, preventing excitons generated by the light-emitting layer from transmitting to the hole injection layer. Further, the electron injection material has excellent ability to form a film. Specific examples of the electron injection material include, but not limited to, fluorenone, anthraquinone dimethyl, diphenoquinone, thian dioxide, azole, diazole, triazole, imidazole, perylene tetracarboxylic acid, fluorenyl methane, anthrone, derivatives thereof, a metal complex, a 5-membered ring derivative containing nitrogen, and the like.

The electron transport layer can be used for transmitting electrons. Preferably, an electron transport material in the electron transport layer has high electron mobility, and can receive electrons injected from a negative electrode and transmit the electrons to the light-emitting layer. Specific examples of the electron transport material may include but not limited to at least one of an Al-based complex of 8-hydroxyquinoline, a complex containing Alq₃, an organic radical compound, a hydroxyflavone metal complex, 8-hydroxyquinoline lithium (LiQ), and a compound based on benzimidazole.

It can be understood that, the organic electronic device may further include a hole blocking layer disposed between the light-emitting layer and the electron transport layer. The hole blocking layer is a layer that can block the holes from reaching a negative electrode and usually formed under the same conditions as the hole injection layer. Specific examples of a hole blocking material in the hole blocking layer may include, but not limited to, a diazole derivative, a triazole derivative, a phenanthroline derivative, bromocresol purple sodium salt (BCP), an aluminum complex, and the like.

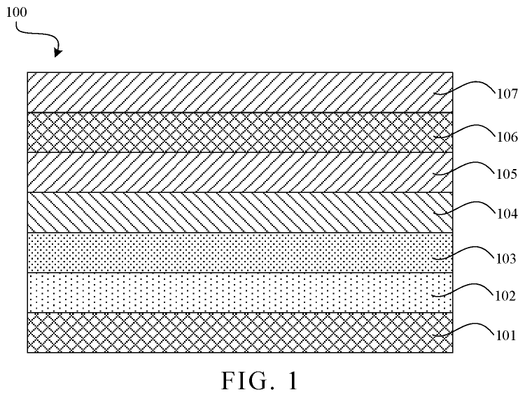

Referring to FIG. 1, a specific embodiment of the present disclosure provides an organic electronic device 100 that includes a substrate 101, an anode 102, a hole injection layer 103, a hole transport layer 104, a light-emitting layer 105, an electron transport layer 106, and a cathode 107. It should be noted that the structure and materials of each layer in the organic electronic device 100 can refer to the description of the above-mentioned embodiments, and will not be repeated here.

The present disclosure further provides a use of an organic electronic device in the preparation for various electronic devices. The electronic devices may include, but not limited to, display devices, illumination devices, sources, sensors, or the like.

### SPECIFIC EXAMPLES

The following is specific illustration of synthesis routes and synthesis methods of the boron-nitrogen compounds (hereinafter referred to compounds 1-22) provided by the present disclosure through specific examples. The following examples are only preferred examples of the present disclosure, but cannot be understood as limitations to the present disclosure.

### Example 1

### Synthesis of Compound 1

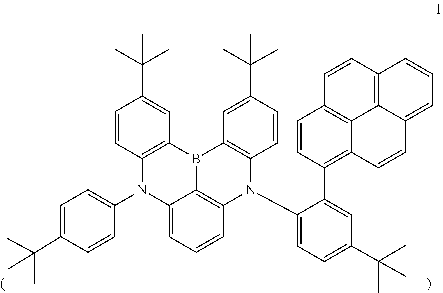 [SMILES: CC(C)(C)c1ccc(N2c3ccc(C(C)(C)C)cc3B3c4cc(C(C)(C)C)ccc4N(c4ccc(C(C)(C)C)cc4-c4ccc5ccc6cccc7ccc4c5c67)c4cccc2c43)cc1]

Synthetic Route of the Compound 1 is as follows:

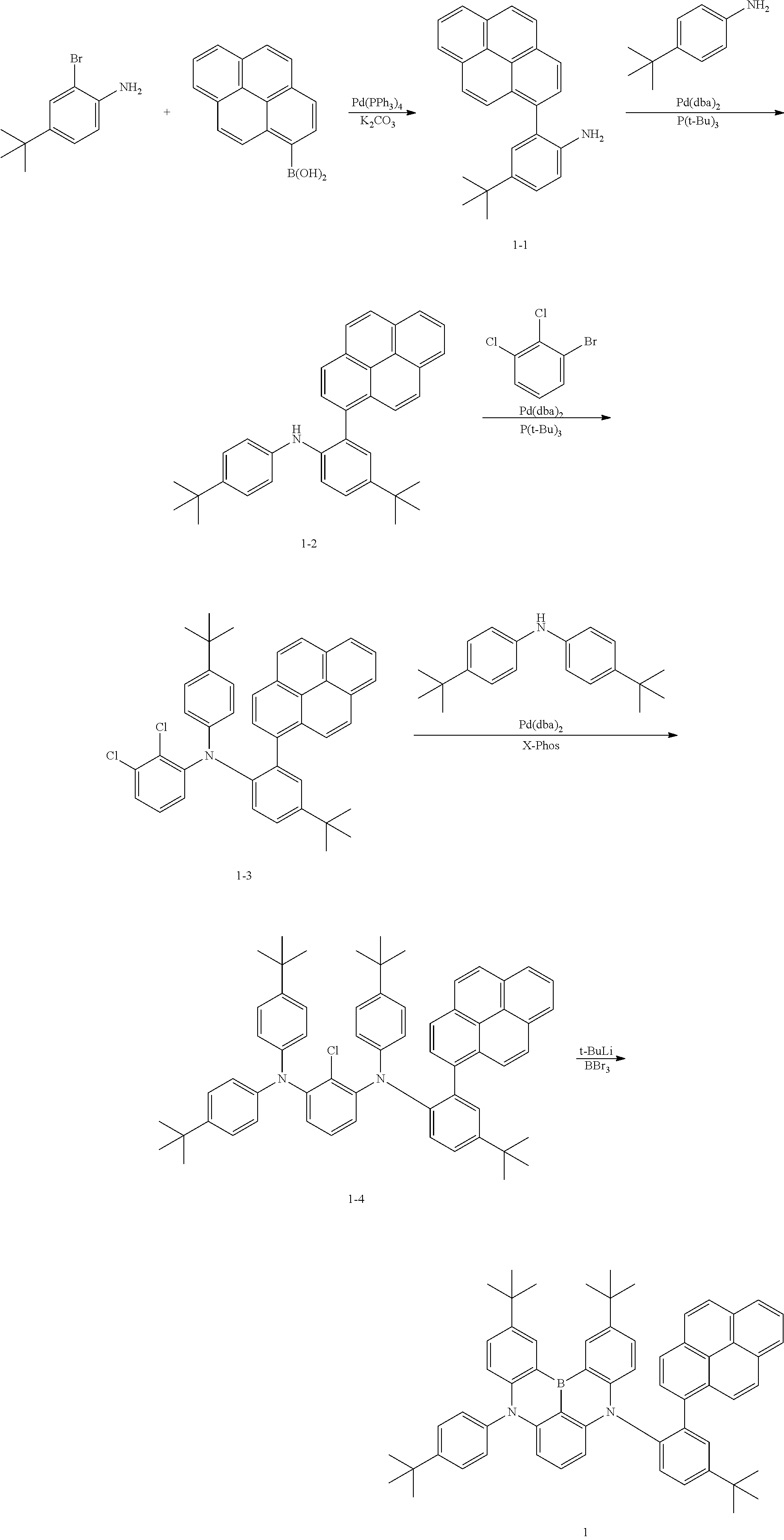

(1) Synthesis of Intermediate 1-1: 2-bromo-4-tert-butylaniline (22.7 g, 100 mmol), 1-pyreneboric acid (24.6 g, 100 mmol), tetratriphenylphosphine palladium (Pd(PPh₃)₄, 1.2 g, 1.0 mmol), and potassium carbonate (K₂CO₃, 41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 1-1 with yield of 91%. A result of atmospheric solids analysis probe-mass spectrometry (ASAP-MS) of intermediate 1-1 was as follows: MS (ASAP)=349.2.

(2) Synthesis of Intermediate 1-2: 4-tert-butyl-1-bromobenzene (21.2 g, 100 mmol), intermediate 1-1 (34.9 g, 100 mmol), bis(benzylidene)acetone palladium (Pd(dba)₂, 0.57 g, 1.0 mmol), tri-tert-butylphosphine (P(t-Bu)₃, 0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 1-2 with yield of 73%. MS (ASAP)=481.3.

(3) Synthesis of Intermediate 1-3: intermediate 1-2 (48.1 g, 100 mmol), 1,2-dichloro-3-bromobenzene (22.6 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 1-3 with yield of 84%. MS (ASAP)=625.2.

(4) Synthesis of Intermediate 1-4: intermediate 1-3 (62.5 g, 100 mmol), 4,4-di-tert-butyldiphenylamine (28.1 g, 100 mmol), Pd(dba)₂ (0.57 g, 1.0 mmol), 2-dicyclohexylphosphine-2,4,6-triaisopropylbiphenyl (X-Phos, 0.95 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 1-4 with yield of 87%. MS (ASAP)=870.5.

(5) Synthesis of Compound 1: intermediate 1-4 (43.5 g, 50 mmol) and dried tert-butyl benzene (200 mL) were added into a three necked-flask (500 mL), and cooled to a temperature of −30° C. in a nitrogen environment. Tert-butyl lithium (t-BuLi, 200 mmol) and n-hexane were added into the solution dropwise. The temperature of the solution was raised to 60° C., then the solution was carried out for 2 hours. After the reaction was completed, n-hexane was removed from the reaction solution by rotary evaporation. Subsequently, the reaction solution was cooled again to the temperature of −30° C., and boron tribromide (BBr₃, 75 g, 300 mmol) was added. Then the temperature was raised to room temperature, and the reaction solution was stirred for 2 hours. The reaction solution was cooled to a temperature of 0° C., and N,N-diisopropylethylamine (64.5 g, 500 mmol) was added dropwise. After the dropping was completed, the temperature was raised to room temperature under a stirring state. The temperature was continuously raised to 120° C., and the reaction solution was stirred for 12 hours and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography, the purified product was further purified by recrystallization using toluene and ethyl acetate as solvents, to obtain a light yellow solid powder that was the compound 1 with yield of 22%. MS (ASAP)=844.5.

### Example 2

### Synthesis of Compound 2

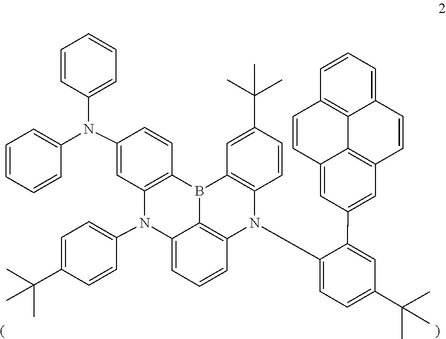 [SMILES: CC(C)(C)c1ccc(N2c3cc(N(c4ccccc4)c4ccccc4)ccc3B3c4cc(C(C)(C)C)ccc4N(c4ccc(C(C)(C)C)cc4-c4cc5ccc6cccc7ccc(c4)c5c67)c4cccc2c43)cc1]

Synthetic Route of the Compound 2 is as follows:

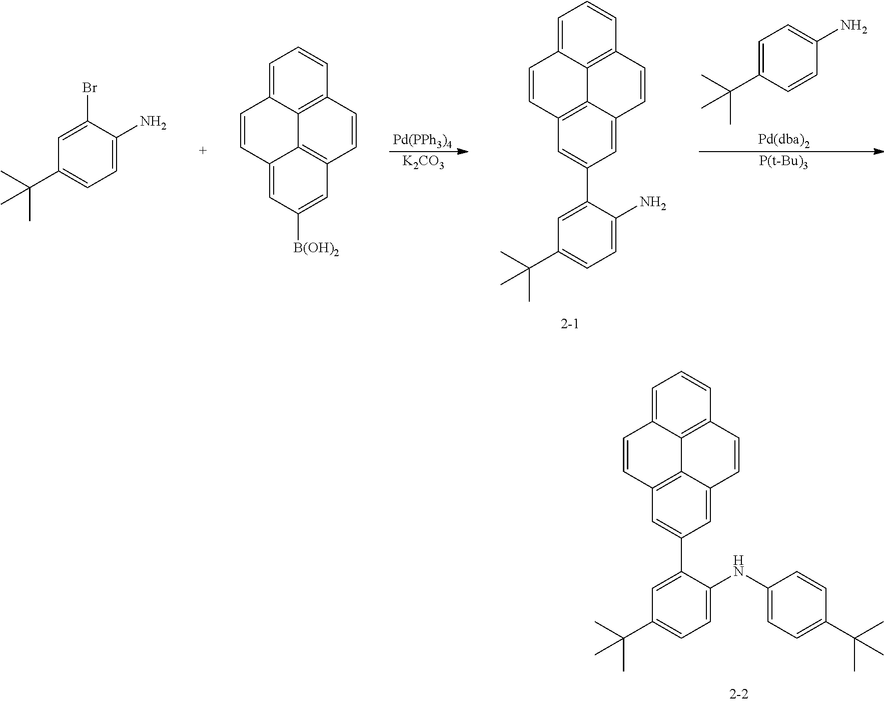

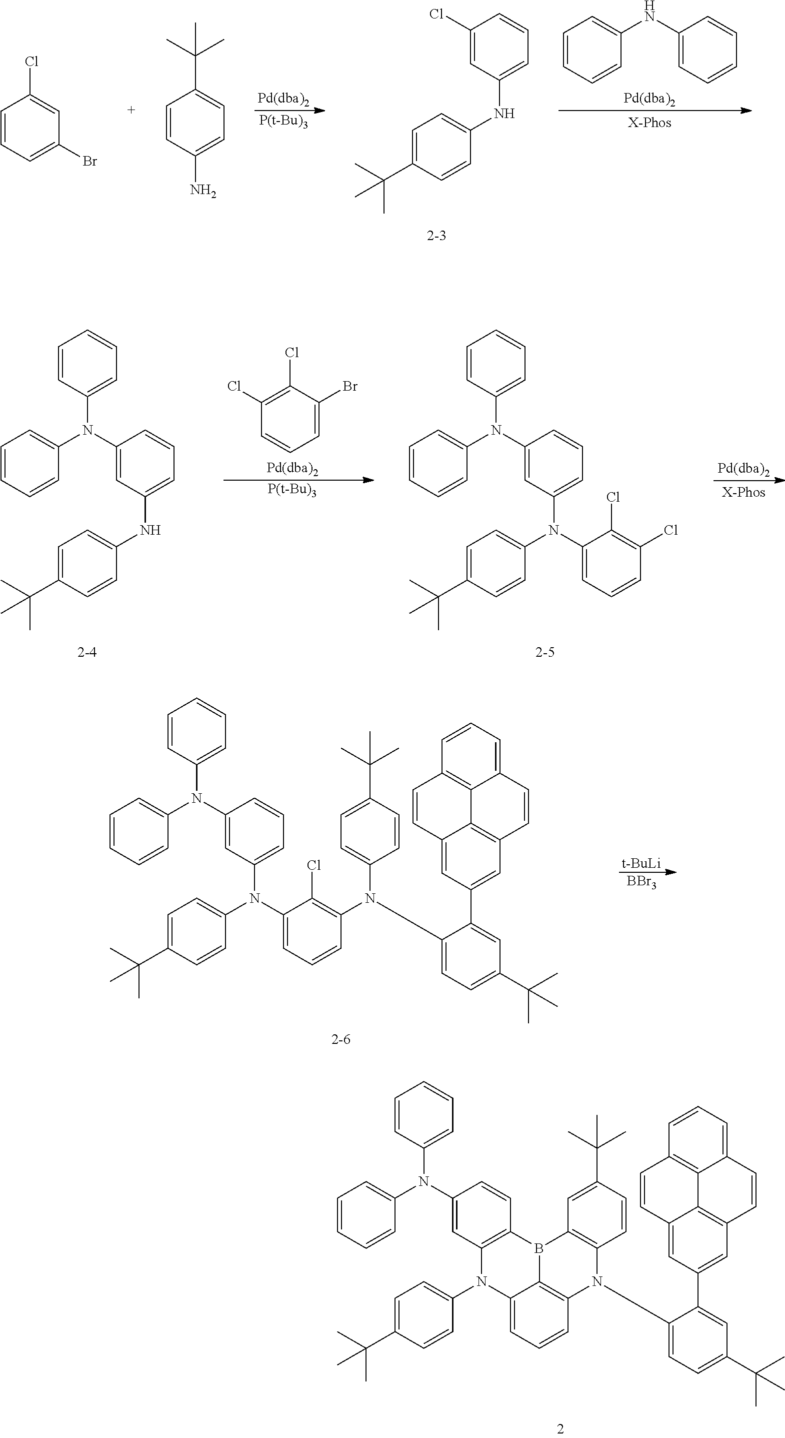

(1) Synthesis of Intermediate 2-1: 2-bromo-4-tert-butylaniline (22.7 g, 100 mmol), 2-pyreneboric acid (24.6 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 2-1 with yield of 93%. MS (ASAP)=349.2.

(2) Synthesis of Intermediate 2-2: 4-tert-butyl-1-bromobenzene (21.2 g, 100 mmol), intermediate 2-1 (34.9 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 2-2 with yield of 77%. MS (ASAP)=481.3.

(3) Synthesis of Intermediate 2-3: 1-chloro-3-bromobenzene (19.2 g, 100 mmol), 4-tert-butylaniline (14.9 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 2-3 with yield of 89%. MS (ASAP)=259.1.

(4) Synthesis of Intermediate 2-4: intermediate 2-3 (25.9 g, 100 mmol), diphenylamine (16.9 g, 100 mmol), Pd(dba)₂ (0.57 g, 1.0 mmol), X-Phos (0.95 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 2-4 with yield of 81%. MS (ASAP)=392.2.

(5) Synthesis of Intermediate 2-5: intermediate 2-4 (39.2 g, 100 mmol), 1,2-dichloro-3-bromobenzene (22.6 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 2-5 with yield of 78%. MS (ASAP)=536.2.

(6) Synthesis of Intermediate 2-6: intermediate 2-5 (53.6 g, 100 mmol), intermediate 2-2 (48.1 g, 100 mmol), Pd(dba)₂ (0.57 g, 1.0 mmol), X-Phos (0.95 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 2-6 with yield of 67%. MS (ASAP)=981.5.

(7) Synthesis of Compound 2: according to the synthesis method of compound 1, intermediate 2-6 (49.1 g, 50 mmol) was substituted for intermediate 1-4 (43.5 g, 50 mmol) to obtain the compound 2 with yield of 25%. MS (ASAP)=955.5.

### Example 3

### Synthesis of Compound 3

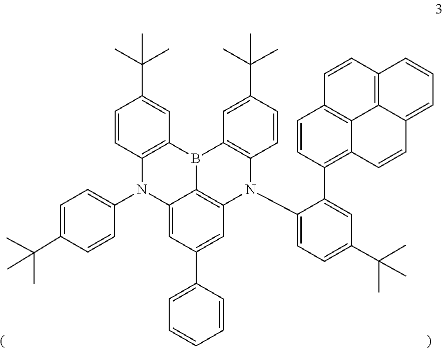 [SMILES: CC(C)(C)c1ccc(N2c3ccc(C(C)(C)C)cc3B3c4cc(C(C)(C)C)ccc4N(c4ccc(C(C)(C)C)cc4-c4ccc5ccc6cccc7ccc4c5c67)c4cc(-c5ccccc5)cc2c43)cc1]

Synthetic Route of the Compound 3 is as follows:

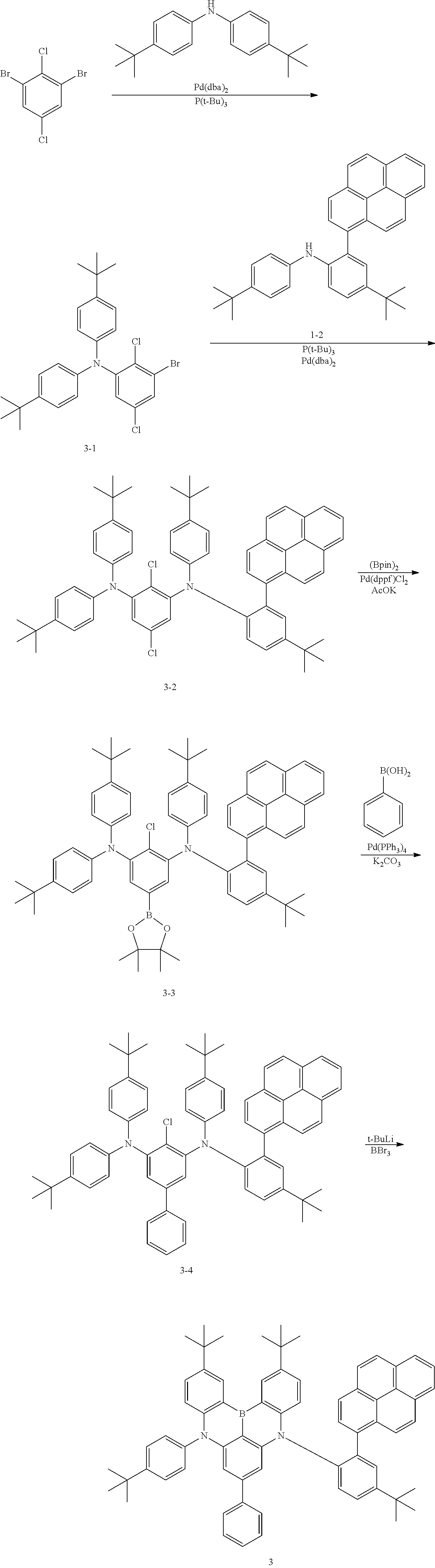

(1) Synthesis of Intermediate 3-1: 2,6-dibromo-1,4-dichlorobenzene (30.3 g, 100 mmol), 4,4′-di-tert-butyldiphenylamine (28.1 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 3-1 with yield of 72%. MS (ASAP)=505.1.

(2) Synthesis of Intermediate 3-2: intermediate 3-1 (50.5 g, 100 mmol), intermediate 1-2 (48.1 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 3-2 with yield of 81%. MS (ASAP)=904.4.

(3) Synthesis of Intermediate 3-3: intermediate 3-2 (90.4 g, 100 mmol), pinacol diborate ((Bpin)₂, 25.4 g, 100 mmol)), [1,1′-bis(diphenylphosphino)ferrocene]palladium dichloride (Pd(dppf)Cl₂, 0.73 g, 1.0 mmol), and potassium acetate (AcOK, 29.4 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 3-3 with yield of 72%. MS (ASAP)=996.6.

(4) Synthesis of Intermediate 3-4: intermediate 3-3 (99.6 g, 100 mmol), phenylboronic acid (12.2 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 3-4 with yield of 78%. MS (ASAP)=946.5.

(5) Synthesis of Compound 3: according to the synthesis method of compound 1, intermediate 3-4 (47.3 g, 50 mmol) was substituted for intermediate 1-4 (43.5 g, 50 mmol) to obtain the compound 3 with yield of 21%. MS (ASAP)=920.5.

### Example 4

### Synthesis of Compound 4

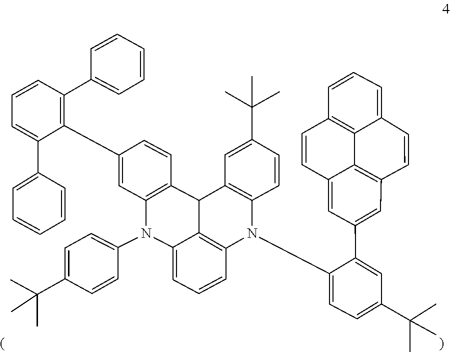 [SMILES: CC(C)(C)c1ccc(N2c3cc(-c4c(-c5ccccc5)cccc4-c4ccccc4)ccc3C3c4cc(C(C)(C)C)ccc4N(c4ccc(C(C)(C)C)cc4-c4cc5ccc6cccc7ccc(c4)c5c67)c4cccc2c43)cc1]

Synthetic Route of the Compound 4 is as follows:

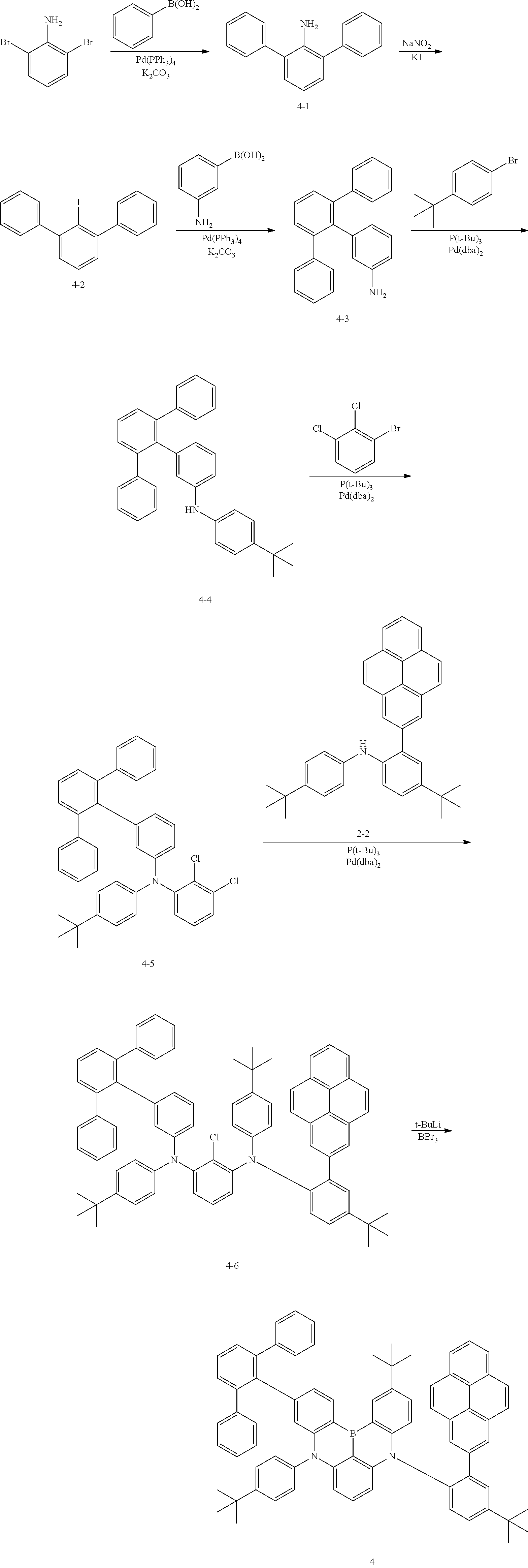

(1) Synthesis of Intermediate 4-1: 2,6-dibromoaniline (25.1 g, 100 mmol), phenylboronic acid (12.2 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 4-1 with yield of 94%. MS (ASAP)=245.1.

(2) Synthesis of Intermediate 4-2: sodium nitrite (6.9 g, 100 mmol) was slowly added in the mixed solution of intermediate 4-1 (24.5 g, 100 mmol), sulfuric acid (20 mL), and acetic acid (200 mL), and stirred at room temperature for 1 hour. Potassium iodide (16.6 g, 100 mmol) was dissolved in 20 mL of water and added in the reaction solution dropwise, then stirred at a temperature 70° C. for 1 hour. After the reaction was completed, the reaction solution was cooled, extracted and washed with water to obtain a crude product. The organic phase in the crude product was purified by column chromatography to obtain intermediate 4-2 with yield of 57%. MS (ASAP)=356.0.

(3) Synthesis of Intermediate 4-3: intermediate 4-2 (35.6 g, 100 mmol), 3-aminophenylboronic acid (13.7 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 4-3 with yield of 72%. MS (ASAP)=321.2.

(4) Synthesis of Intermediate 4-4: intermediate 4-3 (32.1 g, 100 mmol), 4-tert-butyl-bromobenzene (21.2 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 4-4 with yield of 88%. MS (ASAP)=453.3.

(5) Synthesis of Intermediate 4-5: intermediate 4-4 (45.3 g, 100 mmol), 1,2-dichloro-3-bromobenzene (22.6 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 4-5 with yield of 81%. MS (ASAP)=597.2.

(6) Synthesis of Intermediate 4-6: intermediate 4-5 (59.7 g, 100 mmol), intermediate 2-2 (48.1 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 4-6 with yield of 85%. MS (ASAP)=1042.5.

(7) Synthesis of Compound 4: according to the synthesis method of compound 1, intermediate 4-6 (52.1 g, 50 mmol) was substituted for intermediate 1-4 (43.5 g, 50 mmol) to obtain the compound 4 with yield of 23%. MS (ASAP)=1016.5.

### Example 5

### Synthesis of Compound 5

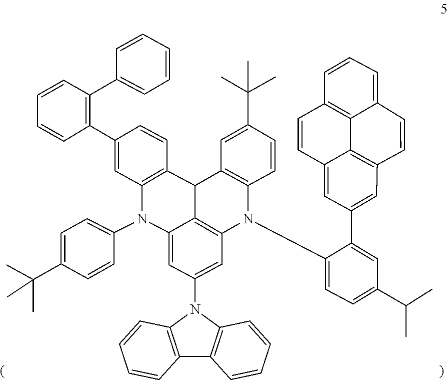 [SMILES: CC(C)c1ccc(N2c3ccc(C(C)(C)C)cc3C3c4ccc(-c5ccccc5-c5ccccc5)cc4N(c4ccc(C(C)(C)C)cc4)c4cc(-n5c6ccccc6c6ccccc65)cc2c43)c(-c2cc3ccc4cccc5ccc(c2)c3c45)c1]

Synthetic Route of the Compound 5 is as follows:

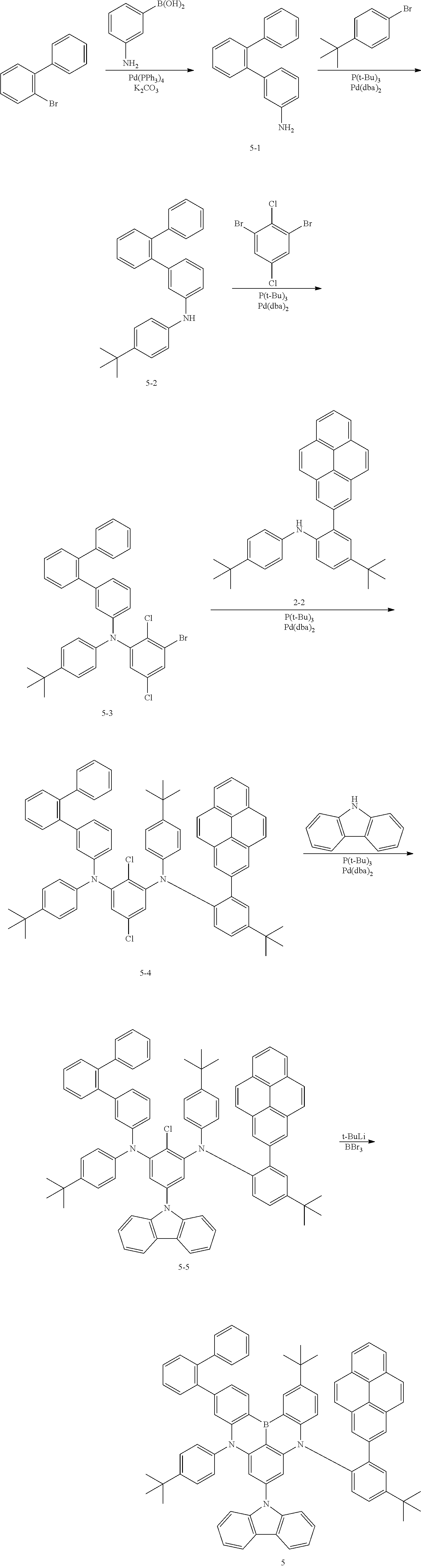

(1) Synthesis of Intermediate 5-1: 2-bromobiphenyl (23.3 g, 100 mmol), 3-aminophenylboronic acid (13.7 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 5-1 with yield of 78%. MS (ASAP)=245.1.

(2) Synthesis of Intermediate 5-2: intermediate 5-1 (24.5 g, 100 mmol), 4-tert-butyl-bromobenzene (21.2 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 5-2 with yield of 85%. MS (ASAP)=377.2.

(3) Synthesis of Intermediate 5-3: 2,6-dibromo-1,4-dichlorobenzene (30.3 g, 100 mmol), intermediate 5-2 (37.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 5-3 with yield of 77%. MS (ASAP)=601.1.

(4) Synthesis of Intermediate 5-4: intermediate 2-2 (48.1 g, 100 mmol), intermediate 5-3 (60.1 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 5-4 with yield of 72%. MS (ASAP)=1000.4.

(5) Synthesis of Intermediate 5-5: intermediate 5-4 (100 g, 100 mmol), carbazole (16.7 g, 100 mmol), Pd(dba)₂ (0.57 g, 1.0 mmol), X-Phos (0.95 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 5-5 with yield of 87%. MS (ASAP)=1131.5.

(6) Synthesis of Compound 5: according to the synthesis method of compound 1, intermediate 5-5 (56.5 g, 50 mmol) was substituted for intermediate 1-4 (43.5 g, 50 mmol) to obtain the compound 5 with yield of 24%. MS (ASAP)=1105.5.

### Example 6

### Synthesis of Compound 6

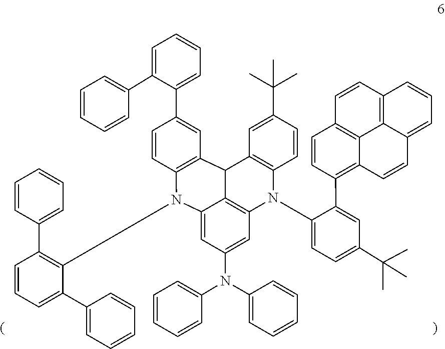 [SMILES: CC(C)(C)c1ccc(N2c3ccc(C(C)(C)C)cc3C3c4cc(-c5ccccc5-c5ccccc5)ccc4N(c4c(-c5ccccc5)cccc4-c4ccccc4)c4cc(N(c5ccccc5)c5ccccc5)cc2c43)c(-c2ccc3ccc4cccc5ccc2c3c45)c1]

Synthetic Route of the Compound 6 is as follows:

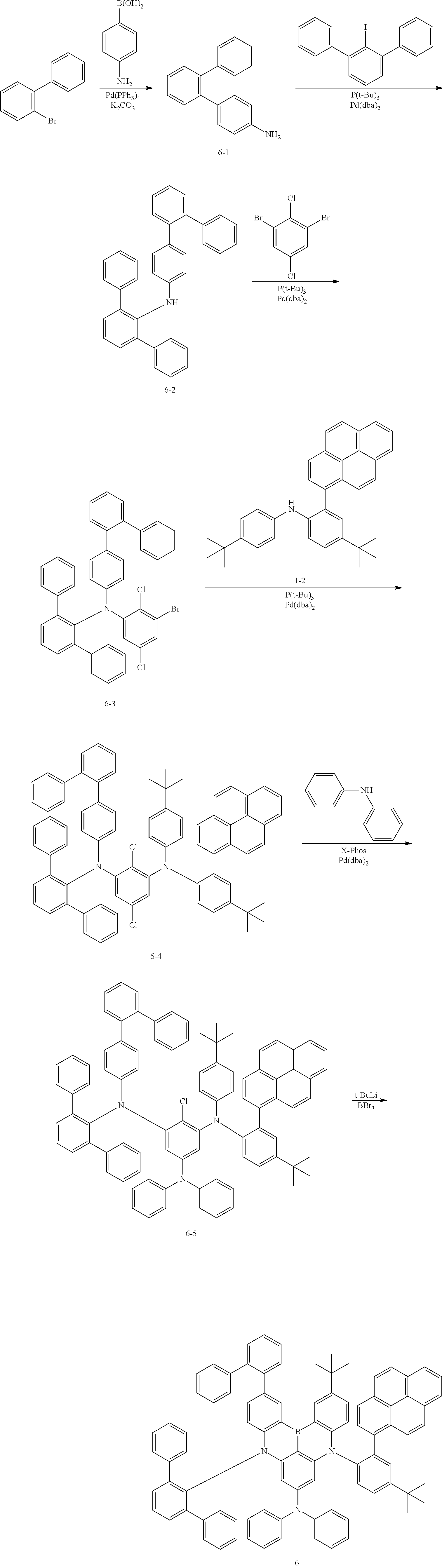

(1) Synthesis of Intermediate 6-1: 2-bromobiphenyl (23.3 g, 100 mmol), 4-aminophenylboronic acid (13.7 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 6-1 with yield of 82%. MS (ASAP)=245.1.

(2) Synthesis of Intermediate 6-2: intermediate 6-1 (24.5 g, 100 mmol), intermediate 4-2 (35.6 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 6-2 with yield of 82%. MS (ASAP)=473.2.

(3) Synthesis of Intermediate 6-3: 2,6-dibromo-1,4-dichlorobenzene (30.3 g, 100 mmol), intermediate 6-2 (47.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 6-3 with yield of 71%. MS (ASAP)=697.1.

(4) Synthesis of Intermediate 6-4: intermediate 1-2 (48.1 g, 100 mmol), intermediate 6-3 (69.7 g, 100 mmol), Pd(dba)₂ (0.57 g, 1.0 mmol), P(t-Bu)₃ (0.4 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 6-4 with yield of 68%. MS (ASAP)=1096.4.

(5) Synthesis of Intermediate 6-5: intermediate 6-4 (109 g, 100 mmol), diphenylamine (16.9 g, 100 mmol), Pd(dba)₂ (0.57 g, 1.0 mmol), X-Phos (0.95 g, 2.0 mmol), and sodium tert-butoxide (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 6-5 with yield of 83%. MS (ASAP)=1229.5.

(6) Synthesis of Compound 6: according to the synthesis method of compound 1, intermediate 6-5 (61.5 g, 50 mmol) was substituted for intermediate 1-4 (43.5 g, 50 mmol) to obtain the compound 6 with yield of 22%. MS (ASAP)=1203.6.

### Example 7

### Synthesis of Compound 7

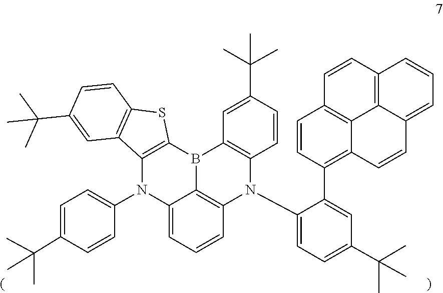 [SMILES: CC(C)(C)c1ccc(N2c3cccc4c3B(c3cc(C(C)(C)C)ccc3N4c3ccc(C(C)(C)C)cc3-c3ccc4ccc5cccc6ccc3c4c56)c3sc4ccc(C(C)(C)C)cc4c32)cc1]

Synthetic Route of the Compound 7 is as follows:

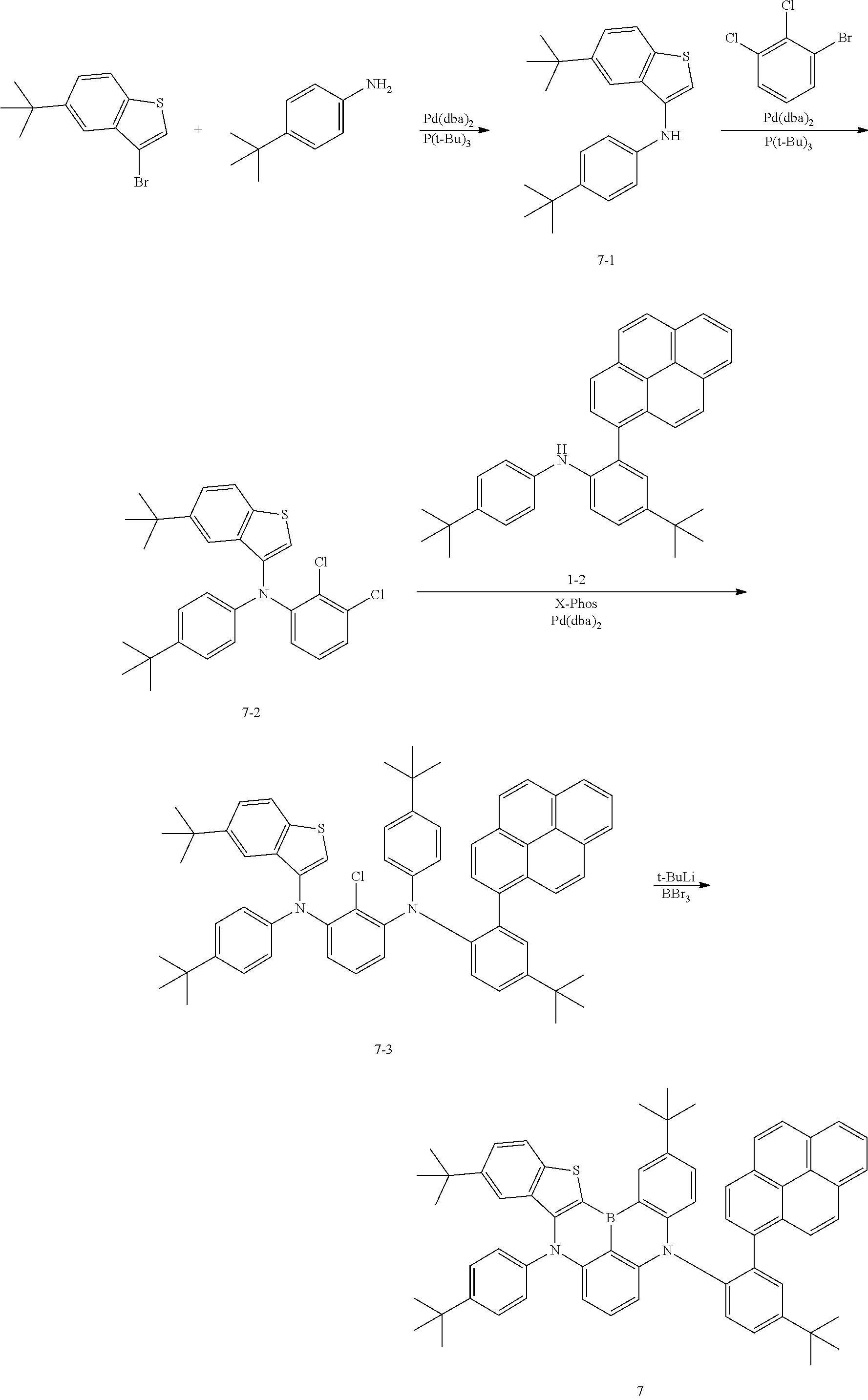

(1) Synthesis of Intermediate 7-1: 3-bromo-5-tert-butylbenzothiophene (27.0 g, 100 mmol), 4-tert-butylaniline (14.9 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 7-1 with yield of 57%. MS (ASAP)=337.2.

(2) Synthesis of Intermediate 7-2: intermediate 7-1 (33.7 g, 100 mmol), 1,2-dichloro-3-bromobenzene (22.6 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 7-2 with yield of 76%. MS (ASAP)=481.1.

(3) Synthesis of Intermediate 7-3: intermediate 7-2 (48.1 g, 100 mmol), intermediate 1-2 (48.1 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 7-3 with yield of 74%. MS (ASAP)=926.4.

(4) Synthesis of Compound 7: according to the synthesis method of compound 1, intermediate 7-3 (46.3 g, 50 mmol) was substituted for intermediate 1-4 (43.5 g, 50 mmol) to obtain the compound 7 with yield of 23%. MS (ASAP)=900.5.

### Example 8

### Synthesis of Compound 8

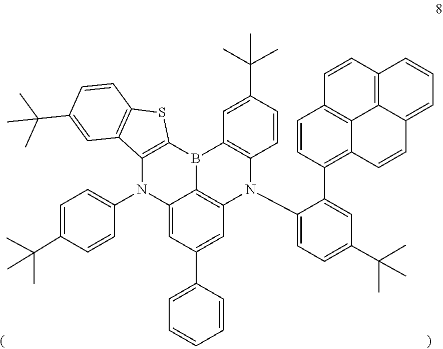 [SMILES: CC(C)(C)c1ccc(N2c3cc(-c4ccccc4)cc4c3B(c3cc(C(C)(C)C)ccc3N4c3ccc(C(C)(C)C)cc3-c3ccc4ccc5cccc6ccc3c4c56)c3sc4ccc(C(C)(C)C)cc4c32)cc1]

Synthetic Route of the Compound 8 is as follows:

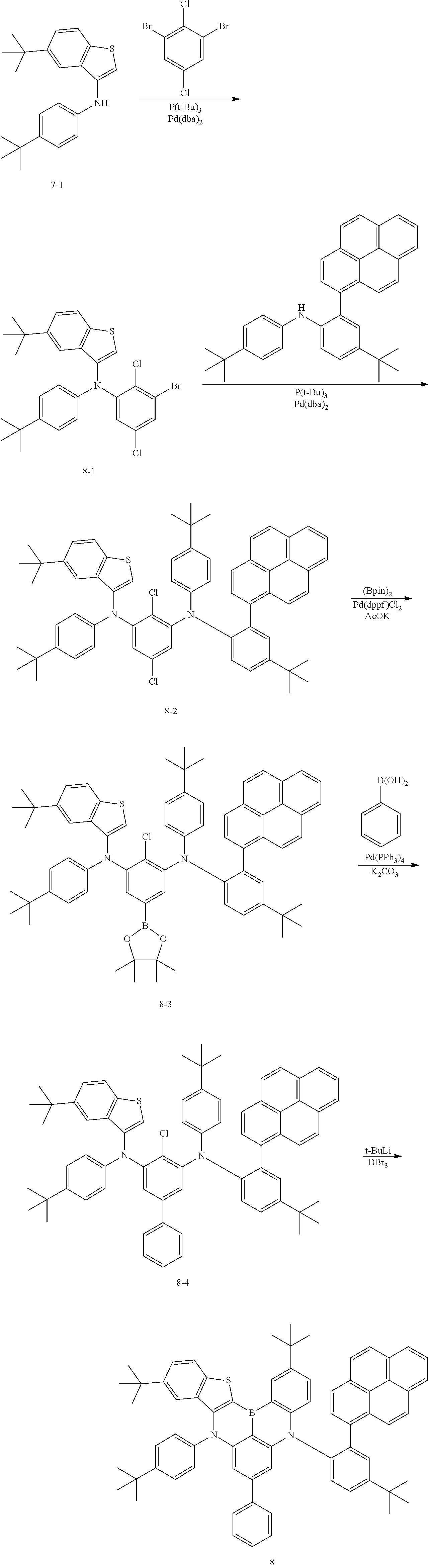

(1) Synthesis of Intermediate 8-1: 2,6-dibromo-1,4-dichlorobenzene (30.3 g, 100 mmol), intermediate 7-1 (33.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 8-1 with yield of 75%. MS (ASAP)=561.1.

(2) Synthesis of Intermediate 8-2: intermediate 8-1 (56.1 g, 100 mmol), intermediate 1-2 (48.1 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 8-2 with yield of 82%. MS (ASAP)=960.4.

(3) Synthesis of Intermediate 8-3: intermediate 8-2 (96.0 g, 100 mmol), pinacol diborate (25.4 g, 100 mmol), Pd(dppf)Cl₂ (0.73 g, 1.0 mmol), and AcOK (29.4 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 8-3 with yield of 67%. MS (ASAP)=1052.5.

(4) Synthesis of Intermediate 8-4: intermediate 8-3 (105 g, 100 mmol), phenylboronic acid (12.2 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 8-4 with yield of 81%. MS (ASAP)=1002.5.

(5) Synthesis of Compound 8: according to the synthesis method of compound 1, intermediate 8-4 (50.1 g, 50 mmol) was substituted for intermediate 1-4 (43.5 g, 50 mmol) to obtain the compound 8 with yield of 26%. MS (ASAP)=976.5.

### Example 9

### Synthesis of Compound 9

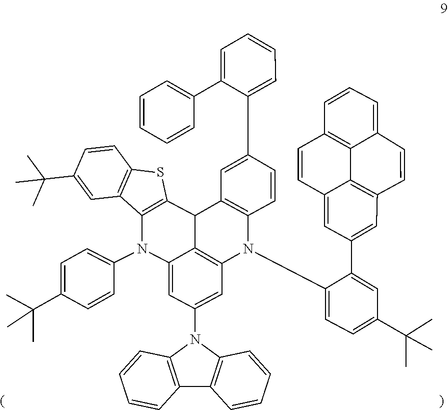 [SMILES: CC(C)(C)c1ccc(N2c3cc(-n4c5ccccc5c5ccccc54)cc4c3C(c3cc(-c5ccccc5-c5ccccc5)ccc3N4c3ccc(C(C)(C)C)cc3-c3cc4ccc5cccc6ccc(c3)c4c56)c3sc4ccc(C(C)(C)C)cc4c32)cc1]

Synthetic Route of the Compound 9 is as follows:

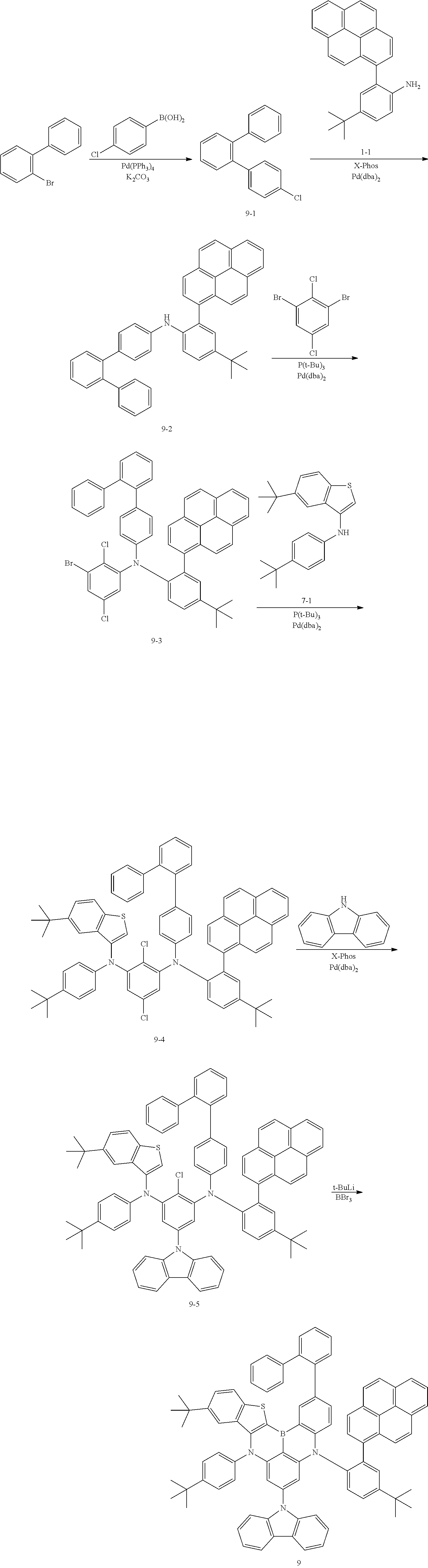

(1) Synthesis of Intermediate 9-1: 2-bromobiphenyl (23.3 g, 100 mmol), 4-chlorophenylboronic acid (15.6 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 9-1 with yield of 88%. MS (ASAP)=264.1.

(2) Synthesis of Intermediate 9-2: intermediate 9-1 (26.4 g, 100 mmol), intermediate 1-1 (34.9 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 9-2 with yield of 78%. MS (ASAP)=577.3.

(3) Synthesis of Intermediate 9-3: 2,6-dibromo-1,4-dichlorobenzene (30.3 g, 100 mmol), intermediate 9-2 (57.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 9-3 with yield of 66%. MS (ASAP)=801.1.

(4) Synthesis of Intermediate 9-4: intermediate 7-1 (33.7 g, 100 mmol), intermediate 9-3 (80.1 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 9-3 with yield of 64%. MS (ASAP)=1056.4.

(5) Synthesis of Intermediate 9-5: intermediate 9-4 (105 g, 100 mmol), carbazole (16.7 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 9-5 with yield of 81%. MS (ASAP)=1187.5.

(6) Synthesis of Compound 9: according to the synthesis method of compound 1, intermediate 9-5 (59.4 g, 50 mmol) was substituted for intermediate 1-4 (43.5 g, 50 mmol) to obtain the compound 9 with yield of 27%. MS (ASAP)=1162.5.

### Example 10

### Synthesis of Compound 10

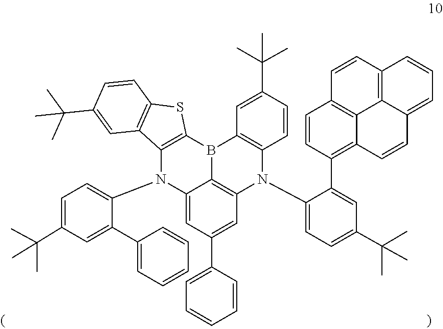 [SMILES: CC(C)(C)c1ccc2c(c1)B1c3sc4ccc(C(C)(C)C)cc4c3N(c3ccc(C(C)(C)C)cc3-c3ccccc3)c3cc(-c4ccccc4)cc(c31)N2c1ccc(C(C)(C)C)cc1-c1ccc2ccc3cccc4ccc1c2c34]

Synthetic Route of the Compound 10 is as follows:

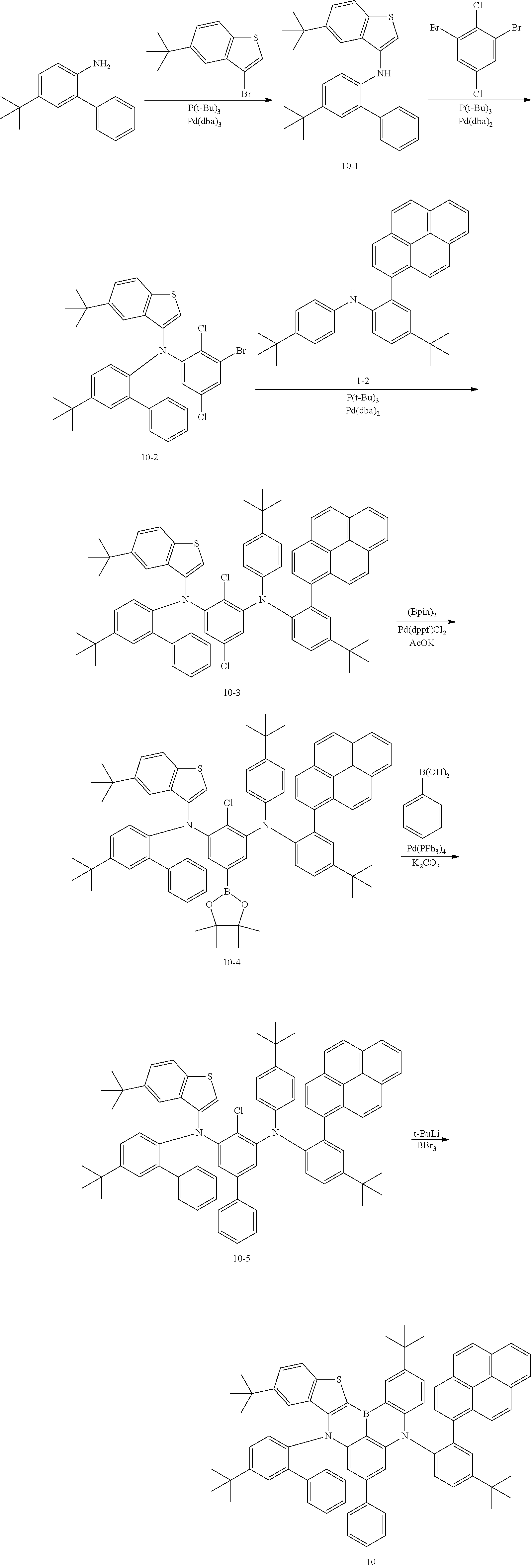

(1) Synthesis of Intermediate 10-1: 3-bromo-5-tert-butylbenzothiophene (27.0 g, 100 mmol), 4-tert-butyl-2-phenyl-1-aniline (22.5 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 10-1 with yield of 63%. MS (ASAP)=413.2.

(2) Synthesis of Intermediate 10-2: 2,6-dibromo-1,4-dichlorobenzene (30.3 g, 100 mmol), intermediate 10-1 (41.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 10-2 with yield of 67%. MS (ASAP)=637.1.

(3) Synthesis of Intermediate 10-3: intermediate 10-2 (63.7 g, 100 mmol), intermediate 1-2 (48.1 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 10-3 with yield of 81%. MS (ASAP)=1036.4.

(4) Synthesis of Intermediate 10-4: intermediate 10-3 (103.6 g, 100 mmol), pinacol diborate (25.4 g, 100 mmol), Pd(dppf)Cl₂ (0.73 g, 1.0 mmol), and AcOK (29.4 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 10-4 with yield of 77%. MS (ASAP)=1128.6.

(5) Synthesis of Intermediate 10-5: intermediate 10-4 (112.8 g, 100 mmol), phenylboronic acid (12.2 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 10-5 with yield of 83%. MS (ASAP)=1078.5.

(6) Synthesis of Compound 10: according to the synthesis method of compound 1, intermediate 10-5 (53.9 g, 50 mmol) was substituted for intermediate 1-4 (43.5 g, 50 mmol) to obtain the compound 10 with yield of 19%. MS (ASAP)=1052.5.

### Example 11

### Synthesis of Compound 11

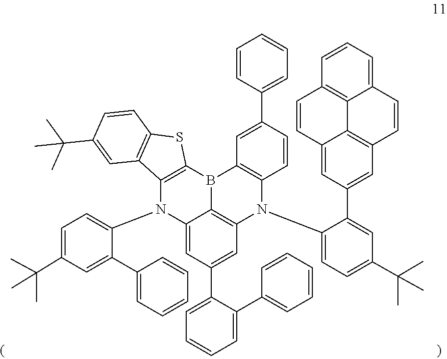 [SMILES: CC(C)(C)c1ccc(N2c3ccc(-c4ccccc4)cc3B3c4sc5ccc(C(C)(C)C)cc5c4N(c4ccc(C(C)(C)C)cc4-c4ccccc4)c4cc(-c5ccccc5-c5ccccc5)cc2c43)c(-c2cc3ccc4cccc5ccc(c2)c3c45)c1]

Synthetic Route of the Compound 11 is as follows:

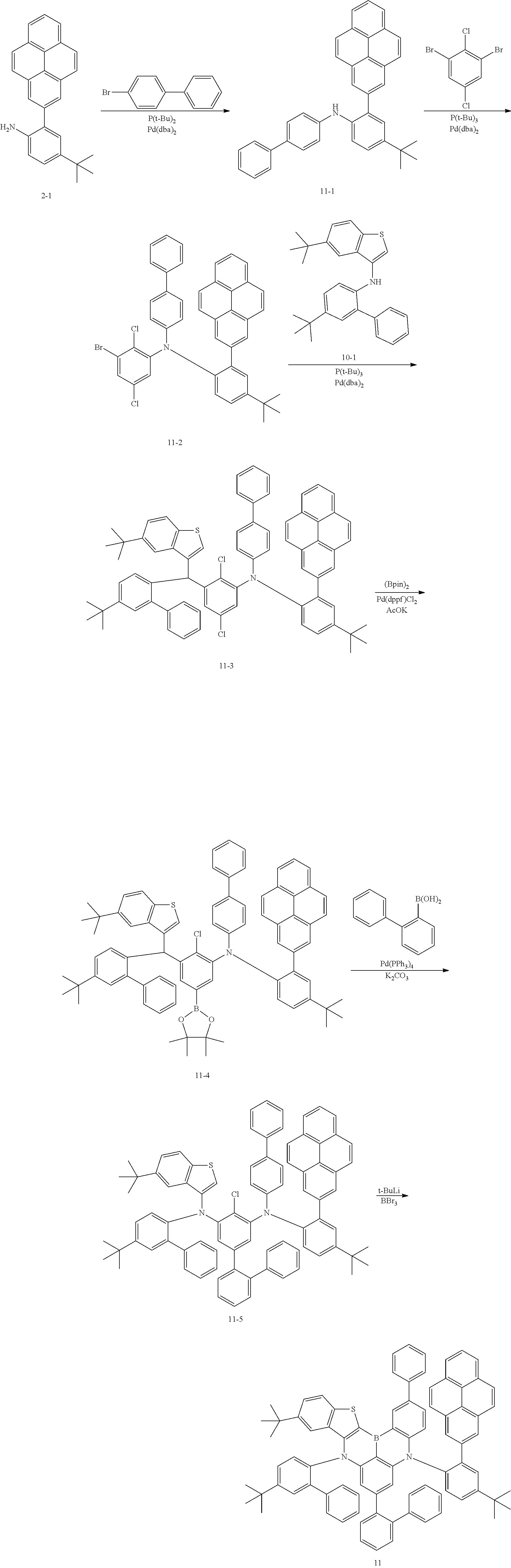

(1) Synthesis of Intermediate 11-1: 4-bromobiphenyl (23.2 g, 100 mmol), intermediate 2-1 (34.9 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 11-1 with yield of 88%. MS (ASAP)=501.3.

(2) Synthesis of Intermediate 11-2: 2,6-dibromo-1,4-dichlorobenzene (30.3 g, 100 mmol), intermediate 11-1 (50.1 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 11-2 with yield of 67%. MS (ASAP)=725.1.

(3) Synthesis of Intermediate 11-3: intermediate 11-2 (72.5 g, 100 mmol), intermediate 10-1 (41.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 11-3 with yield of 62%. MS (ASAP)=1056.4.

(4) Synthesis of Intermediate 11-4: intermediate 11-3 (105.6 g, 100 mmol), pinacol borate (25.4 g, 100 mmol), Pd(dppf)Cl₂ (0.73 g, 1.0 mmol), and AcOK (29.4 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 11-4 with yield of 68%. MS (ASAP)=1148.5.

(5) Synthesis of Intermediate 11-5: intermediate 11-4 (114.8 g, 100 mmol), 2-biphenylboronic acid (19.8 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 11-5 with yield of 82%. MS (ASAP)=1174.5.

(6) Synthesis of Compound 11: according to the synthesis method of compound 1, intermediate 11-5 (58.7 g, 50 mmol) was substituted for intermediate 1-4 (43.5 g, 50 mmol) to obtain the compound 11 with yield of 22%. MS (ASAP)=1148.5.

### Example 12

### Synthesis of Compound 12

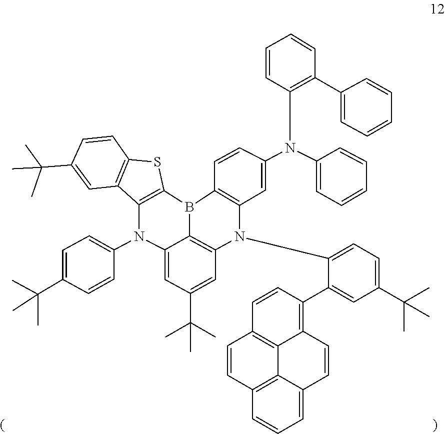 [SMILES: CC(C)(C)c1ccc(N2c3cc(C(C)(C)C)cc4c3B(c3ccc(N(c5ccccc5)c5ccccc5-c5ccccc5)cc3N4c3ccc(C(C)(C)C)cc3-c3ccc4ccc5cccc6ccc3c4c56)c3sc4ccc(C(C)(C)C)cc4c32)cc1]

Synthetic Route of the Compound 12 is as follows:

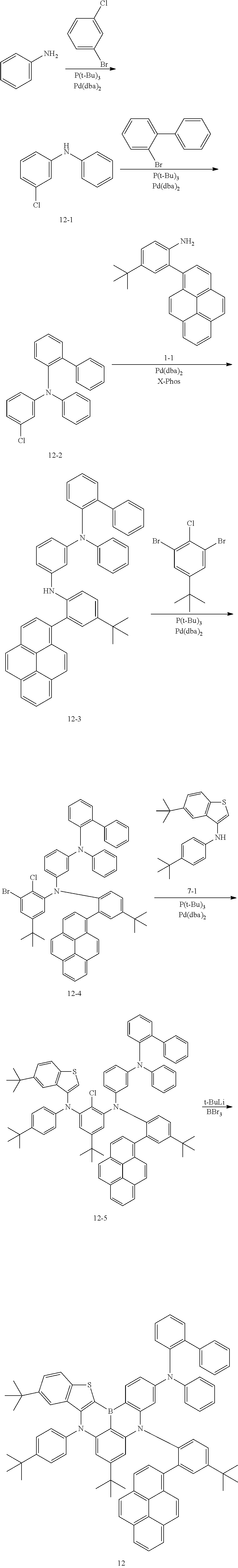

(1) Synthesis of Intermediate 12-1: aniline (9.3 g, 100 mmol), 1-chloro-3-bromobenzene (19.2 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 12-1 with yield of 97%. MS (ASAP)=203.1.

(2) Synthesis of Intermediate 12-2: intermediate 12-1 (20.3 g, 100 mmol), 2-bromobiphenyl (23.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 12-2 with yield of 85%. MS (ASAP)=355.1.

(3) Synthesis of Intermediate 12-3: intermediate 12-2 (35.5 g, 100 mmol), intermediate 1-1 (34.9 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 12-3 with yield of 82%. MS (ASAP)=668.3.

(4) Synthesis of Intermediate 12-4: intermediate 12-3 (66.8 g, 100 mmol), 3,5-dibromo-4-chloro-1-tert-butylbenzene (32.6 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 12-4 with yield of 84%. MS (ASAP)=914.3.

(5) Synthesis of Intermediate 12-5: intermediate 12-4 (91.4 g, 100 mmol), intermediate 7-1 (33.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 12-5 with yield of 81%. MS (ASAP)=1169.5.

(6) Synthesis of Compound 12: according to the synthesis method of compound 1, intermediate 12-5 (58.5 g, 50 mmol) was substituted for intermediate 1-4 (43.5 g, 50 mmol) to obtain the compound 12 with yield of 24%. MS (ASAP)=1143.6.

### Example 13

### Synthesis of Compound 13

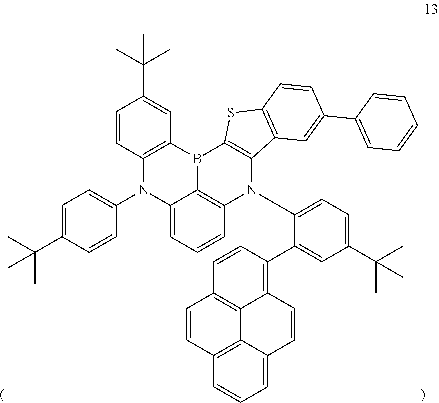 [SMILES: CC(C)(C)c1ccc(N2c3ccc(C(C)(C)C)cc3B3c4sc5ccc(-c6ccccc6)cc5c4N(c4ccc(C(C)(C)C)cc4-c4ccc5ccc6cccc7ccc4c5c67)c4cccc2c43)cc1]

Synthetic Route of the Compound 13 is as follows:

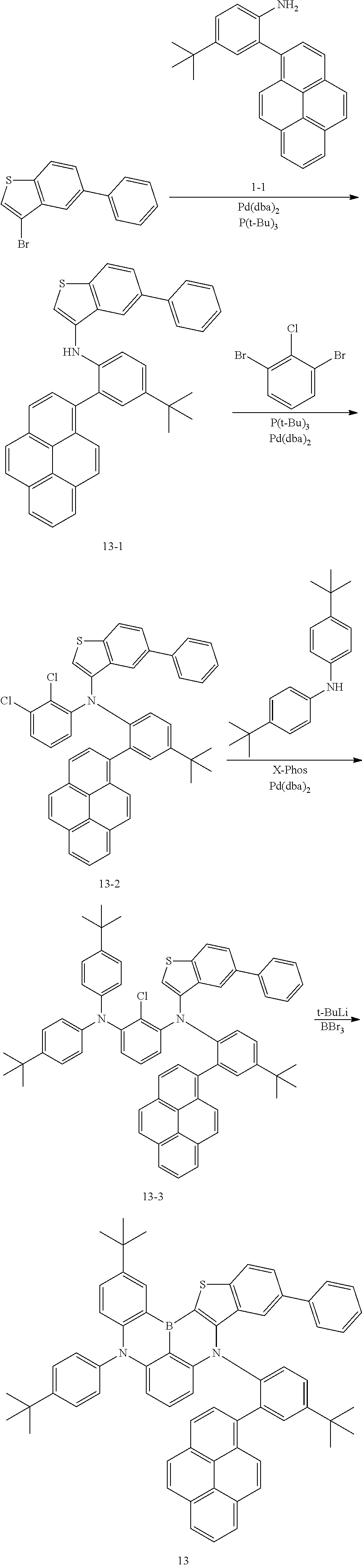

(1) Synthesis of Intermediate 13-1: 3-bromo-5-phenylbenzothiophene (29.0 g, 100 mmol), intermediate 1-1 (34.9 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 13-1 with yield of 64%. MS (ASAP)=557.2.

(2) Synthesis of Intermediate 13-2: intermediate 13-1 (55.7 g, 100 mmol), 1,2-dichloro-3-bromobenzene (22.6 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 13-2 with yield of 73%. MS (ASAP)=701.2.

(3) Synthesis of Intermediate 13-3: intermediate 13-2 (70.1 g, 100 mmol), 4,4′-di-tert-butyldiphenylamine (28.1 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 13-3 with yield of 66%. MS (ASAP)=946.4.

(4) Synthesis of Compound 13: according to the synthesis method of compound 1, intermediate 13-3 (47.3 g, 50 mmol) was substituted for intermediate 1-4 (43.5 g, 50 mmol) to obtain the compound 13 with yield of 26%. MS (ASAP)=920.4.

### Example 14

### Synthesis of Compound 14

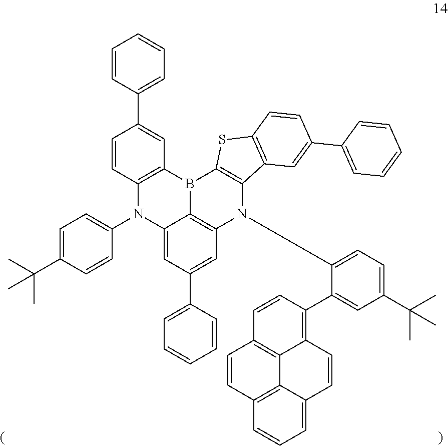 [SMILES: CC(C)(C)c1ccc(N2c3ccc(-c4ccccc4)cc3B3c4sc5ccc(-c6ccccc6)cc5c4N(c4ccc(C(C)(C)C)cc4-c4ccc5ccc6cccc7ccc4c5c67)c4cc(-c5ccccc5)cc2c43)cc1]

Synthetic Route of the Compound 14 is as follows:

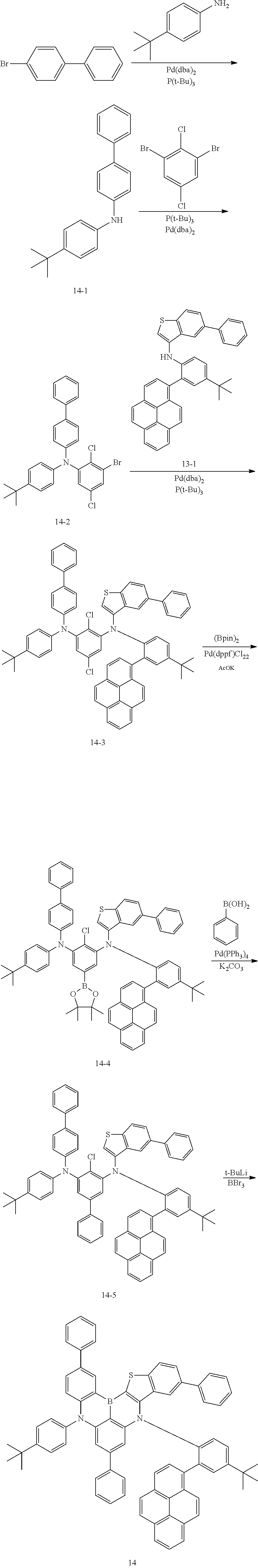

(1) Synthesis of Intermediate 14-1: 4-bromobiphenyl (23.2 g, 100 mmol), 4-tert-butylaniline (14.9 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 14-1 with yield of 95%. MS (ASAP)=301.2.

(2) Synthesis of Intermediate 14-2: 2,6-dibromo-1,4-dichlorobenzene (30.3 g, 100 mmol), intermediate 14-1 (30.1 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 14-2 with yield of 77%. MS (ASAP)=525.0.

(3) Synthesis of Intermediate 14-3: intermediate 14-2 (52.5 g, 100 mmol), intermediate 13-1 (55.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 14-3 with yield of 72%. MS (ASAP)=1000.3.

(4) Synthesis of Intermediate 14-4: intermediate 14-3 (100.0 g, 100 mmol), pinacol diborate (25.4 g, 100 mmol), Pd(dppf)Cl₂ (0.73 g, 1.0 mmol), and AcOK (29.4 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 14-4 with yield of 61%. MS (ASAP)=1092.5.

(5) Synthesis of Intermediate 14-5: intermediate 14-4 (109.2 g, 100 mmol), phenylboronic acid (12.2 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 14-5 with yield of 86%. MS (ASAP)=1042.4.

(6) Synthesis of Compound 14: according to the synthesis method of compound 1, intermediate 14-5 (52.1 g, 50 mmol) was substituted for intermediate 1-4 (43.5 g, 50 mmol) to obtain the compound 14 with yield of 20%. MS (ASAP)=1016.4.

### Example 15

### Synthesis of Compound 15

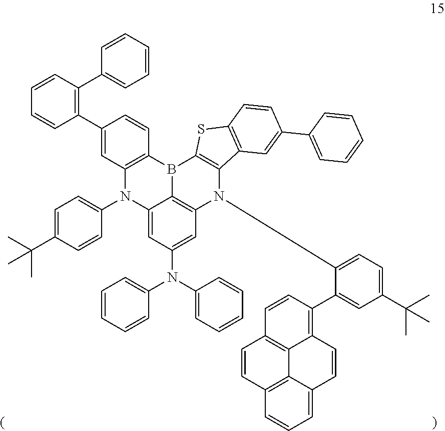 [SMILES: CC(C)(C)c1ccc(N2c3cc(-c4ccccc4-c4ccccc4)ccc3B3c4sc5ccc(-c6ccccc6)cc5c4N(c4ccc(C(C)(C)C)cc4-c4ccc5ccc6cccc7ccc4c5c67)c4cc(N(c5ccccc5)c5ccccc5)cc2c43)cc1]

Synthetic Route of the Compound 15 is as follows:

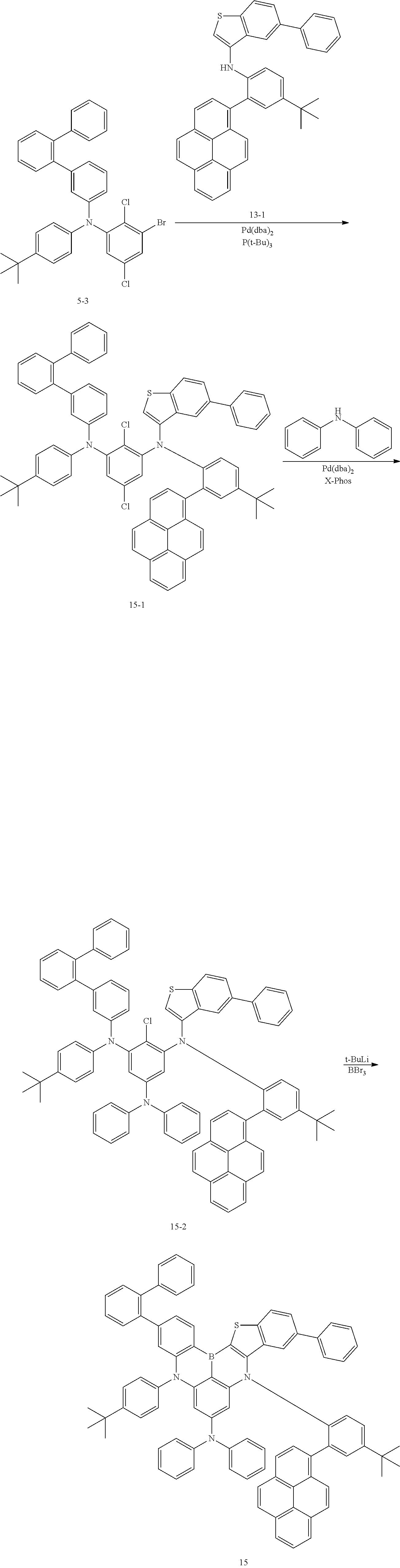

(1) Synthesis of Intermediate 15-1: intermediate 5-3 (60.1 g, 100 mmol), intermediate 13-1 (55.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 15-1 with yield of 65%. MS (ASAP)=1076.4.

(2) Synthesis of Intermediate 15-2: intermediate 15-1 (107 g, 100 mmol), diphenylamine (16.9 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 15-2 with yield of 85%. MS (ASAP)=1209.5.

(3) Synthesis of Compound 15: according to the synthesis method of compound 1, intermediate 15-2 (60.5 g, 50 mmol) was substituted for intermediate 1-4 (43.5 g, 50 mmol) to obtain the compound 15 with yield of 28%. MS (ASAP)=1183.5.

### Example 16

### Synthesis of Compound 16

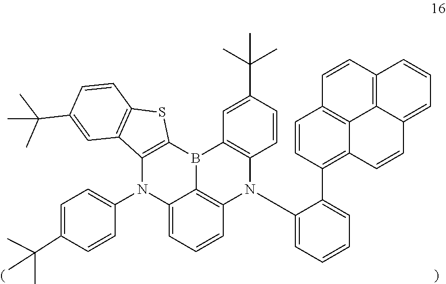 [SMILES: CC(C)(C)c1ccc(N2c3cccc4c3B(c3cc(C(C)(C)C)ccc3N4c3ccccc3-c3ccc4ccc5cccc6ccc3c4c56)c3sc4ccc(C(C)(C)C)cc4c32)cc1]

Synthetic Route of the Compound 16 is as follows:

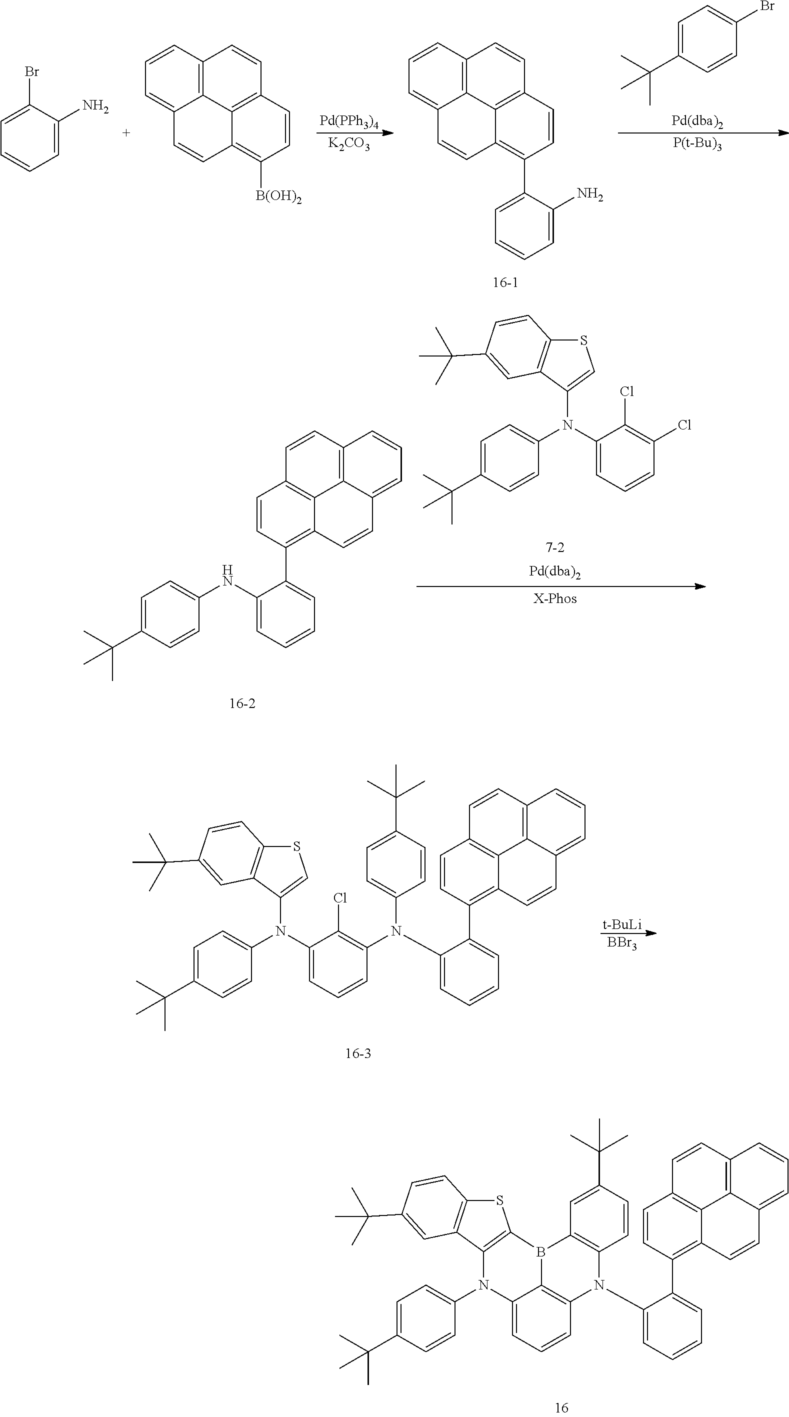

(1) Synthesis of Intermediate 16-1: 2-bromo-aniline (17.1 g, 100 mmol), 1-pyreneboric acid (24.6 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 16-1 with yield of 93%. MS (ASAP)=293.1.

(2) Synthesis of Intermediate 16-2: 4-tert-butyl-1-bromobenzene (21.2 g, 100 mmol), intermediate 16-1 (29.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 16-2 with yield of 74%. MS (ASAP)=425.5.

(3) Synthesis of Intermediate 16-3: intermediate 7-2 (48.1 g, 100 mmol), intermediate 16-2 (42.5 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 16-3 with yield of 77%. MS (ASAP)=870.4.

(4) Synthesis of Compound 16: according to the synthesis method of compound 1, intermediate 16-3 (43.5 g, 50 mmol) was substituted for intermediate 1-4 (43.5 g, 50 mmol) to obtain the compound 16 with yield of 21%. MS (ASAP)=844.4.

### Example 17

### Synthesis of Compound 17

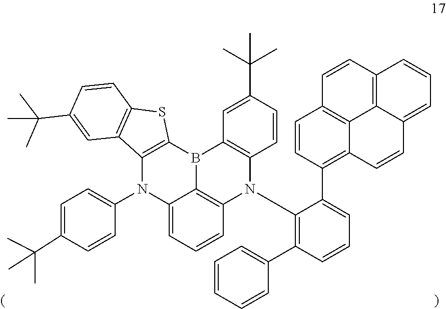 [SMILES: CC(C)(C)c1ccc(N2c3cccc4c3B(c3cc(C(C)(C)C)ccc3N4c3c(-c4ccccc4)cccc3-c3ccc4ccc5cccc6ccc3c4c56)c3sc4ccc(C(C)(C)C)cc4c32)cc1]

Synthetic Route of the Compound 17 is as follows:

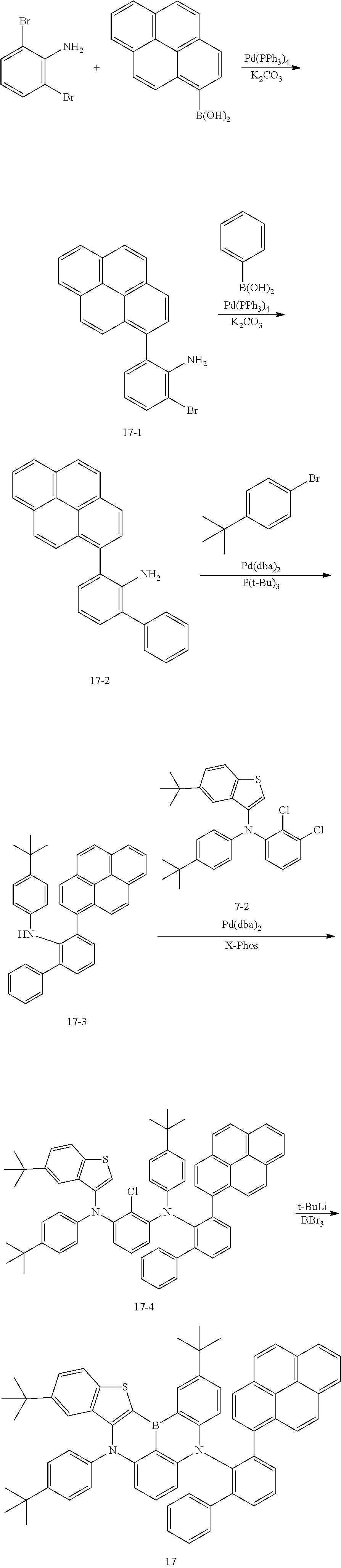

(1) Synthesis of Intermediate 17-1: 2,6-dibromo-aniline (25.1 g, 100 mmol), 1-pyreneboric acid (24.6 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 17-1 with yield of 87%. MS (ASAP)=371.0.

(2) Synthesis of Intermediate 17-2: intermediate 17-1 (37.1 g, 100 mmol), 1-phenylboronic acid (12.2 g, 100 mmol), Pd(PPh₃)₄ (1.2 g, 1.0 mmol), and K₂CO₃ (41.4 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 17-2 with yield of 95%. MS (ASAP)=369.1.

(3) Synthesis of Intermediate 17-3: 4-tert-butyl-1-bromobenzene (21.2 g, 100 mmol), intermediate 17-2 (36.9 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 17-3 with yield of 82%. MS (ASAP)=501.2.

(4) Synthesis of Intermediate 17-4: intermediate 7-2 (48.1 g, 100 mmol), intermediate 17-3 (50.1 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 17-4 with yield of 76%. MS (ASAP)=946.4.

(5) Synthesis of Compound 17: according to the synthesis method of compound 1, intermediate 17-4 (47.3 g, 50 mmol) was substituted for intermediate 1-4 (43.5 g, 50 mmol) to obtain the compound 17 with yield of 24%. MS (ASAP)=920.4.

### Example 18

### Synthesis of Compound 18

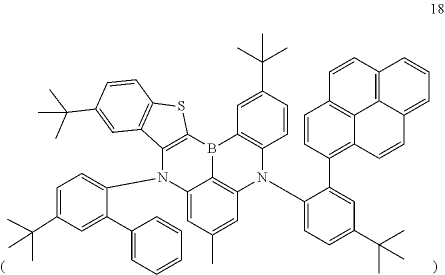 [SMILES: Cc1cc2c3c(c1)N(c1ccc(C(C)(C)C)cc1-c1ccccc1)c1c(sc4ccc(C(C)(C)C)cc14)B3c1cc(C(C)(C)C)ccc1N2c1ccc(C(C)(C)C)cc1-c1ccc2ccc3cccc4ccc1c2c34]

Synthetic Route of the Compound 18 is as follows:

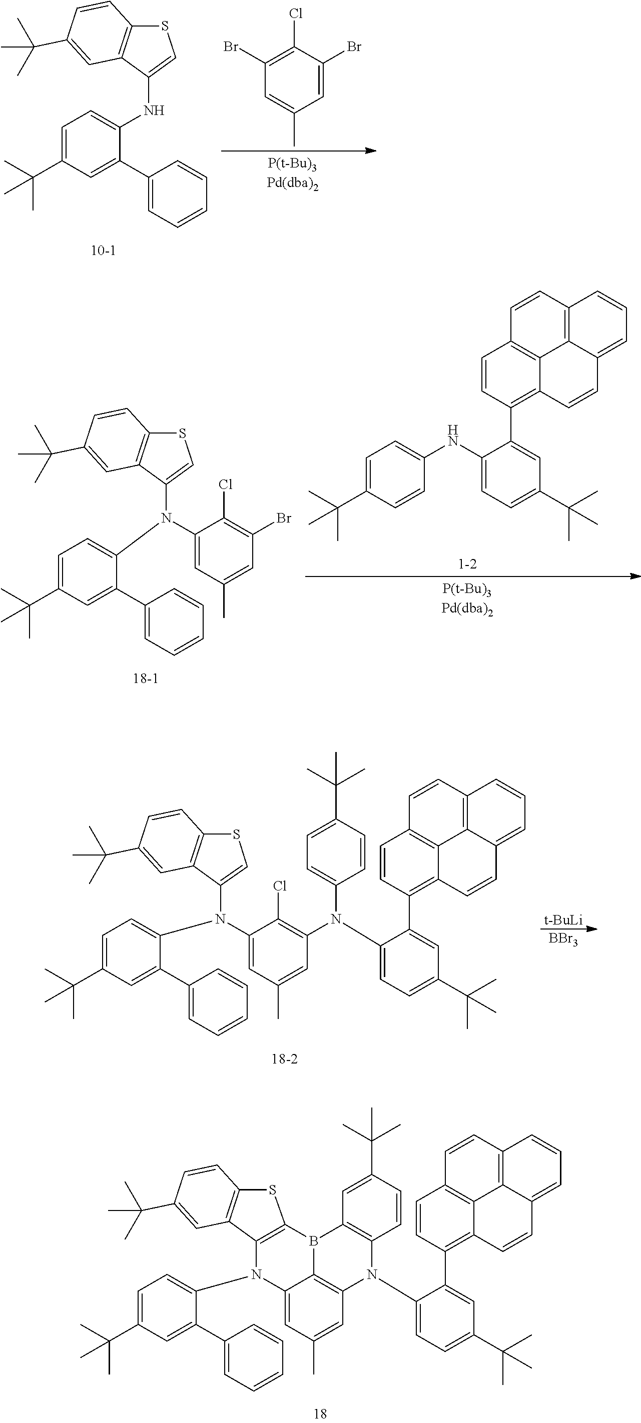

(1) Synthesis of Intermediate 18-1: 3,5-dibromo-4-chlorotoluene (28.3 g, 100 mmol), intermediate 10-1 (41.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 18-1 with yield of 71%. MS (ASAP)=615.1.

(2) Synthesis of Intermediate 18-2: intermediate 18-2 (61.5 g, 100 mmol), intermediate 1-2 (48.1 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 18-2 with yield of 77%. MS (ASAP)=1016.5.

(3) Synthesis of Compound 18: according to the synthesis method of compound 1, intermediate 18-2 (50.8 g, 50 mmol) was substituted for intermediate 1-4 (43.5 g, 50 mmol) to obtain the compound 18 with yield of 14%. MS (ASAP)=990.5.

### Example 19

### Synthesis of Compound 19

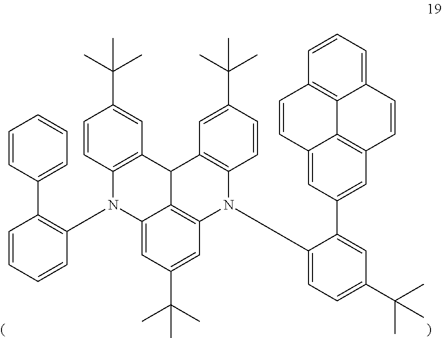 [SMILES: CC(C)(C)c1ccc(N2c3ccc(C(C)(C)C)cc3C3c4cc(C(C)(C)C)ccc4N(c4ccccc4-c4ccccc4)c4cc(C(C)(C)C)cc2c43)c(-c2cc3ccc4cccc5ccc(c2)c3c45)c1]

Synthetic Route of the Compound 19 is as follows:

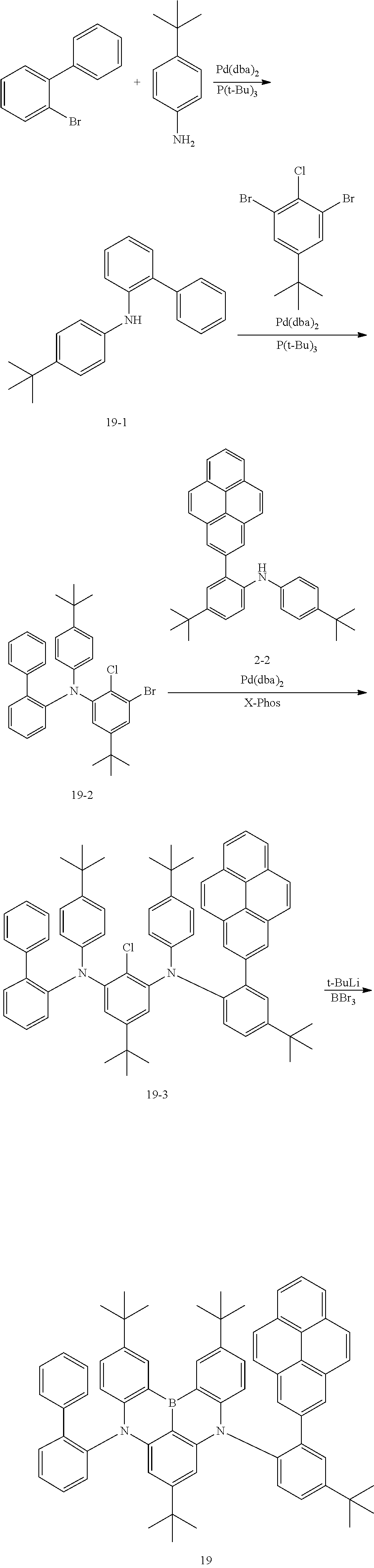

(1) Synthesis of Intermediate 19-1: 2-biphenyl (61.5 g, 100 mmol), 4-tert-butylaniline (48.1 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 19-1 with yield of 72%. MS (ASAP)=301.1.

(2) Synthesis of Intermediate 19-2: intermediate 19-1 (30.1 g, 100 mmol), 3,5-dibromo-4-chloro-1-tert-butylbenzene (32.6 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 19-2 with yield of 76%. MS (ASAP)=545.1.

(3) Synthesis of Intermediate 19-3: intermediate 19-2 (54.5 g, 100 mmol), intermediate 2-2 (48.1 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 19-3 with yield of 71%. MS (ASAP)=946.5.

(4) Synthesis of Compound 19: according to the synthesis method of compound 1, intermediate 19-3 (47.3 g, 50 mmol) was substituted for intermediate 1-4 (43.5 g, 50 mmol) to obtain the compound 19 with yield of 16%. MS (ASAP)=920.5.

### Example 20

### Synthesis of Compound 20

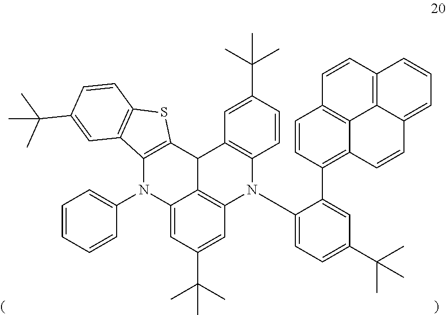 [SMILES: CC(C)(C)c1ccc(N2c3ccc(C(C)(C)C)cc3C3c4sc5ccc(C(C)(C)C)cc5c4N(c4ccccc4)c4cc(C(C)(C)C)cc2c43)c(-c2ccc3ccc4cccc5ccc2c3c45)c1]

Synthetic Route of the Compound 20 is as follows:

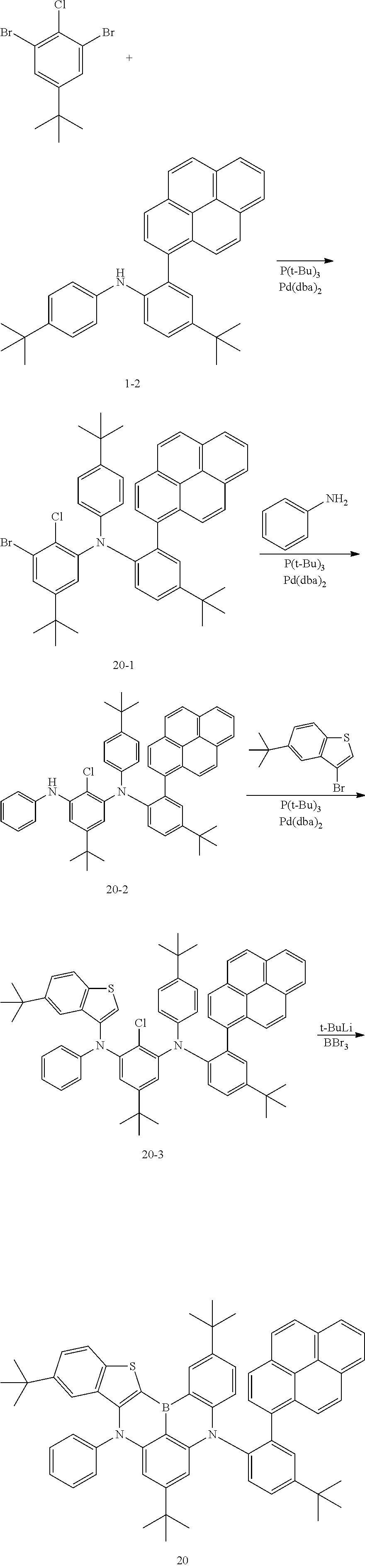

(1) Synthesis of Intermediate 20-1: intermediate 1-2 (48.1 g, 100 mmol), 3,5-Dibromo-4-chloro-1-tert-butylbenzene (32.6 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 20-1 with yield of 72%. MS (ASAP)=725.2.

(2) Synthesis of Intermediate 20-2: intermediate 20-1 (72.5 g, 100 mmol), aniline (9.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 20-2 with yield of 88%. MS (ASAP)=738.4.

(3) Synthesis of Intermediate 20-3: intermediate 20-2 (73.8 g, 100 mmol), 3-bromo-5-tert-butylbenzothiophene (26.8 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 20-3 with yield of 68%. MS (ASAP)=926.4.

(4) Synthesis of Compound 20: according to the synthesis method of compound 1, intermediate 20-3 (46.3 g, 50 mmol) was substituted for intermediate 1-4 (43.5 g, 50 mmol) to obtain the compound 20 with yield of 24%. MS (ASAP)=900.5.

### Example 21

### Synthesis of Compound 21

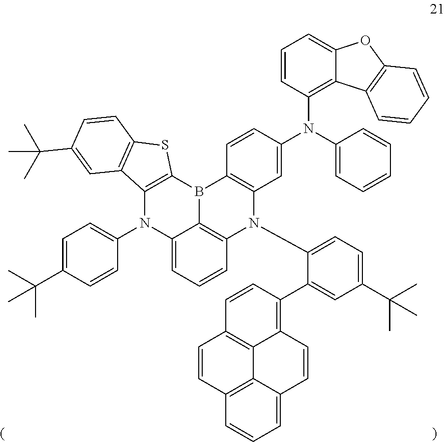 [SMILES: CC(C)(C)c1ccc(N2c3cccc4c3B(c3ccc(N(c5ccccc5)c5cccc6oc7ccccc7c56)cc3N4c3ccc(C(C)(C)C)cc3-c3ccc4ccc5cccc6ccc3c4c56)c3sc4ccc(C(C)(C)C)cc4c32)cc1]

Synthetic Route of the Compound 21 is as follows:

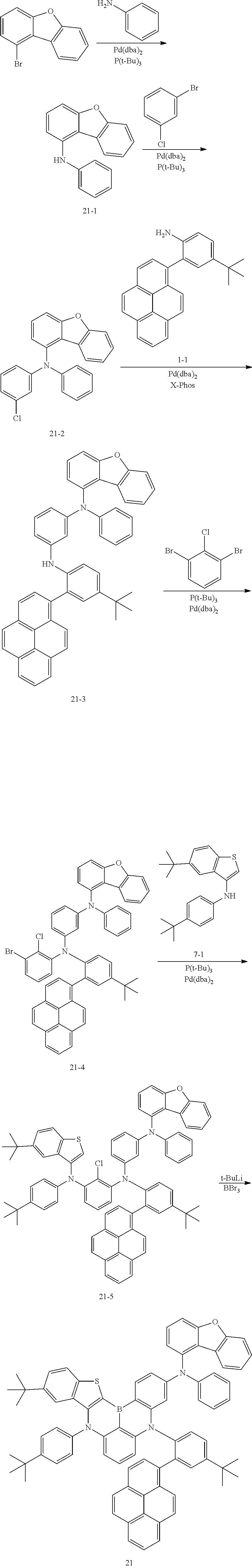

(1) Synthesis of Intermediate 21-1: 1-bromodibenzofuran (24.6 g, 100 mmol), aniline (9.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 21-1 with yield of 96%. MS (ASAP)=259.1.

(2) Synthesis of Intermediate 21-2: intermediate 21-1 (25.9 g, 100 mmol), 3-bromo-1-chlorobenzene (19.0 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 21-2 with yield of 85%. MS (ASAP)=369.1.

(3) Synthesis of Intermediate 21-3: intermediate 21-2 (36.9 g, 100 mmol), intermediate 1-1 (34.9 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 21-3 with yield of 73%. MS (ASAP)=682.3.

(4) Synthesis of Intermediate 21-4: intermediate 21-3 (68.2 g, 100 mmol), 2,6-dibromo-1-chlorobenzene (27.0 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 21-4 with yield of 85%. MS (ASAP)=870.2.

(5) Synthesis of Intermediate 21-5: intermediate 21-4 (87.0 g, 100 mmol), intermediate 7-1 (33.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 21-5 with yield of 81%. MS (ASAP)=1127.5.

(6) Synthesis of Compound 21: according to the synthesis method of compound 1, intermediate 21-5 (56.4 g, 50 mmol) was substituted for intermediate 1-4 (43.5 g, 50 mmol) to obtain the compound 21 with yield of 22%. MS (ASAP)=1101.5.

### Example 22

### Synthesis of Compound 22

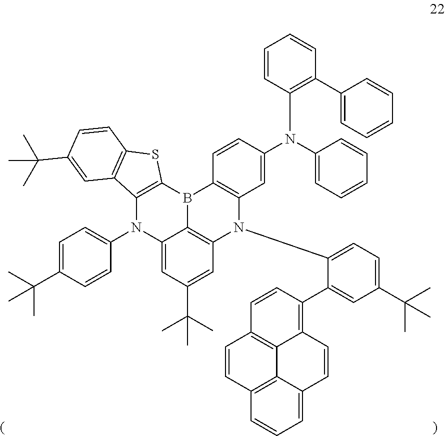 [SMILES: CC(C)(C)c1ccc(N2c3cc(C(C)(C)C)cc4c3B(c3ccc(N(c5ccccc5)c5ccccc5-c5ccccc5)cc3N4c3ccc(C(C)(C)C)cc3-c3ccc4ccc5cccc6ccc3c4c56)c3sc4ccc(C(C)(C)C)cc4c32)cc1]

Synthetic Route of the Compound 22 is as follows:

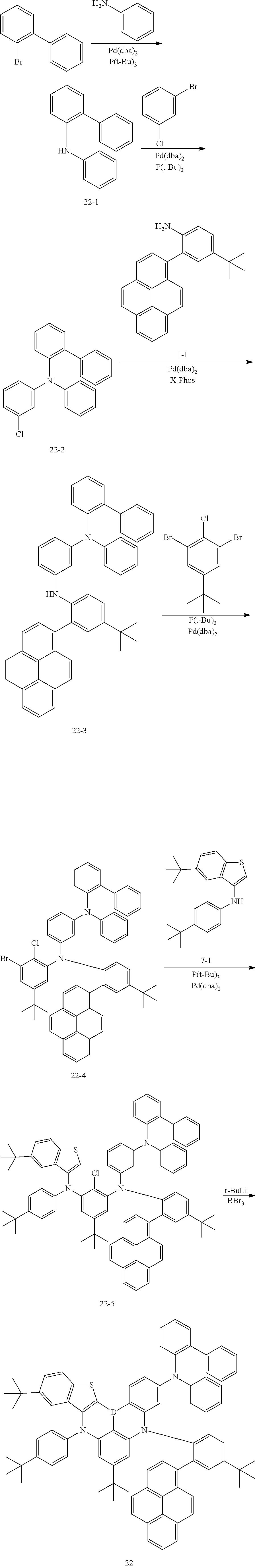

(1) Synthesis of Intermediate 22-1: 2-bromobiphenyl (23.3 g, 100 mmol), aniline (9.3 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 22-1 with yield of 93%. MS (ASAP)=245.1.

(2) Synthesis of Intermediate 22-2: intermediate 22-1 (24.5 g, 100 mmol), 3-bromo-1-chlorobenzene (19.0 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 22-2 with yield of 86%. MS (ASAP)=355.1.

(3) Synthesis of Intermediate 22-3: intermediate 22-2 (35.5 g, 100 mmol), intermediate 1-1 (34.9 g, 100 mmol), Pd(dba)₂ (0.57 g, 1.0 mmol), X-Phos (0.95 g, 2.0 mmol), and sodium tert-butanol (28.8 g, 300 mmol) were dissolved in toluene, and stirred at a temperature of 100° C. for 12 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 22-3 with yield of 77%. MS (ASAP)=684.4.

(4) Synthesis of Intermediate 22-4: intermediate 22-3 (68.4 g, 100 mmol), 3,5-dibromo-4-chloro-tert-butylbenzene (32.6 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 22-4 with yield of 81%. MS (ASAP)=912.3.

(5) Synthesis of Intermediate 22-5: intermediate 22-4 (91.2 g, 100 mmol), intermediate 7-1 (33.7 g, 100 mmol), Pd(dba)₂ (0.57 g, 1.0 mmol), P(t-Bu)₃ (0.4 g, 2.0 mmol), and sodium tert-butanol (28.8 g, 300 mmol) were dissolved in toluene, and stirred at a temperature of 100° C. for 6 hours in a nitrogen environment. After the reaction was completed, the reaction solution was cooled, then the solvent was removed by rotary evaporation. Subsequently, the solution was extracted and washed with water to obtain a crude product. The organic phase in the crude product was purified by column chromatography to obtain intermediate 22-5 with yield of 76%. MS (ASAP)=1169.5.

(6) Synthesis of Compound 22: according to the synthesis method of compound 1, intermediate 22-5 (58.4 g, 50 mmol) was substituted for intermediate 1-4 (43.5 g, 50 mmol) to obtain the compound 22 with yield of 23%. MS (ASAP)=1143.5.

### Comparative Example 1

The present disclosure further provides a comparative example 1, the organic compound in the comparative example 1 is called “comparative compound 1” represented by the following structure:

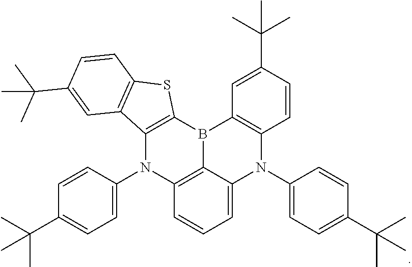 [SMILES: CC(C)(C)c1ccc(N2c3ccc(C(C)(C)C)cc3B3c4sc5ccc(C(C)(C)C)cc5c4N(c4ccc(C(C)(C)C)cc4)c4cccc2c43)cc1]

### Comparative Example 2

The present disclosure further provides a comparative example 2, the organic compound in the comparative example 2 is called “comparative compound 2” represented by the following structure:

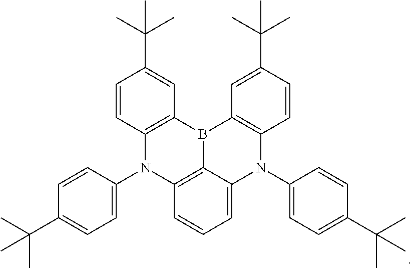 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1]

In the present disclosure, the HOMO energy level, the LUMO energy level, the first excited triplet state (T1) energy level, and the first excited singlet state (S1) energy level of each of compounds 1-22 in examples 1-22 and comparative compounds 1-2 in comparative example 2 were tested through quantum calculations. Specifically, Gaussian 09W (Gaussian Inc.) is used by time-dependent density functional theory (TD-DFT), specific simulation methods can refer to application WO201141110, which is incorporated hereby as a reference. First, a semi-empirical method “Ground State/Semi-empirical/Default Spin/AM1” (Charge0/Spin Singlet) was used to optimize molecular geometry, and then energy structures of organic molecules were calculated by the TD-DFT method to obtain “TD-SCF/DFT/Default Spin/B3PW91” and the base group “6-31G (d)” (Charge0/Spin Singlet). HOMO and LUMO energy levels were calculated according to the following calibration equations, and S1 and T1 energy levels were used directly.

$$HOMO ( eV ) = ( HOMO ( G ) \times 27.212 ) - 0.9899 ) / 1.1206 ;$$

$$LUMO ( eV ) = ( LUMO ( G ) \times 27.212 ) - 2.0041 ) / 1.385 ;$$

In the equations above, HOMO, LUMO, T1, and S1 energy levels were the calculation results of Gaussian 09W, in Hartree, and the results were shown in the following table 1.

TABLE 1

| | | HOMO | LUMO | T1 | S1 |
|---|---|---|---|---|---|
| Example | Compound | (eV) | (eV) | (eV) | (eV) |
| Example 1 | Compound 1 | −4.98 | −2.31 | 2.45 | 3.01 |
| Example 2 | Compound 2 | −5.01 | −2.23 | 2.44 | 3.00 |
| Example 3 | Compound 3 | −5.01 | −2.24 | 2.45 | 3.02 |
| Example 4 | Compound 4 | −5.02 | −2.24 | 2.49 | 3.00 |
| Example 5 | Compound 5 | −5.03 | −2.27 | 2.41 | 3.02 |
| Example 6 | Compound 6 | −5.04 | −2.33 | 2.43 | 3.04 |
| Example 7 | Compound 7 | −4.98 | −2.31 | 2.34 | 3.00 |
| Example 8 | Compound 8 | −5.04 | −2.24 | 2.32 | 2.98 |
| Example 9 | Compound 9 | −5.02 | −2.34 | 2.38 | 3.02 |
| Example 10 | Compound 10 | −5.04 | −2.25 | 2.43 | 3.02 |
| Example 11 | Compound 11 | −5.02 | −2.26 | 2.41 | 3.04 |
| Example 12 | Compound 12 | −5.01 | −2.25 | 2.40 | 3.03 |
| Example 13 | Compound 13 | −5.03 | −2.31 | 2.41 | 3.02 |
| Example 14 | Compound 14 | −5.01 | −2.27 | 2.41 | 3.01 |
| Example 15 | Compound 15 | −5.03 | −2.30 | 2.35 | 3.01 |
| Example 16 | Compound 16 | −5.03 | −2.26 | 2.42 | 3.01 |
| Example 17 | Compound 17 | −5.01 | −2.25 | 2.43 | 3.02 |
| Example 18 | Compound 18 | −5.02 | −2.25 | 2.41 | 3.02 |
| Example 19 | Compound 19 | −5.03 | −2.24 | 2.42 | 3.01 |
| Example 20 | Compound 20 | −5.02 | −2.25 | 2.41 | 3.02 |
| Example 21 | Compound 21 | −5.02 | −2.26 | 2.37 | 3.03 |
| Example 22 | Compound 22 | −5.04 | −2.30 | 2.35 | 3.01 |
| Comparative | Comparative | −5.10 | −2.35 | 2.33 | 2.91 |
| Example 1 | Compound 1 | | | | |
| Comparative | Comparative | −5.11 | −2.34 | 2.35 | 2.95 |
| Example 2 | Compound 2 | | | | |

It can be seen from table 1 that the T1 and S1 energy levels of the compounds 1-22 provided by examples 1-22 of the present disclosure are significantly higher than those of comparative compounds 1-22, indicating that the T1 and S1 energy levels of the boron-nitrogen compounds provided by the present disclosure can be enhanced. Therefore, when the boron-nitrogen compounds are used as blue light-emitting guest materials in OLED devices, blue light emitted by the OLED devices can tend to dark blue. Moreover, when the compounds 1-22 of the present disclosure are used as guest materials in light-emitting layers to prepare blue light-emitting devices, the blue light-emitting devices with better color coordinates can be obtained.

### Preparation and Characterization of OLED Devices

Taking the preparation for blue light OLED devices as examples, the following is a detailed description of preparation methods for preparing OLED devices using the compounds 1-22 of the present disclosure through specific examples of devices.

In the following preparation methods for OLED devices, indium tin oxide (ITO) is used as the anode material, poly(3,4-ethylenedioxythiophene) (PEDOT, Clevios™ AI4083) is used as the hole injection material, polyvinyl carbazole (PVK, Sigma Aldrich, average molecular weight of 25000-50000) is used as the hole transport material, BH is used as the host material of the light-emitting layer, ET and 8-hydroxyquinoline lithium (Liq) are used as electron transport materials, and Al is used as the cathode material. Moreover, the compounds 1-22 prepared from the aforementioned examples 1-22 are used as guest materials of the light-emitting layers to prepare corresponding OLED devices. The structures of BH, ET, and Liq are shown as follows:

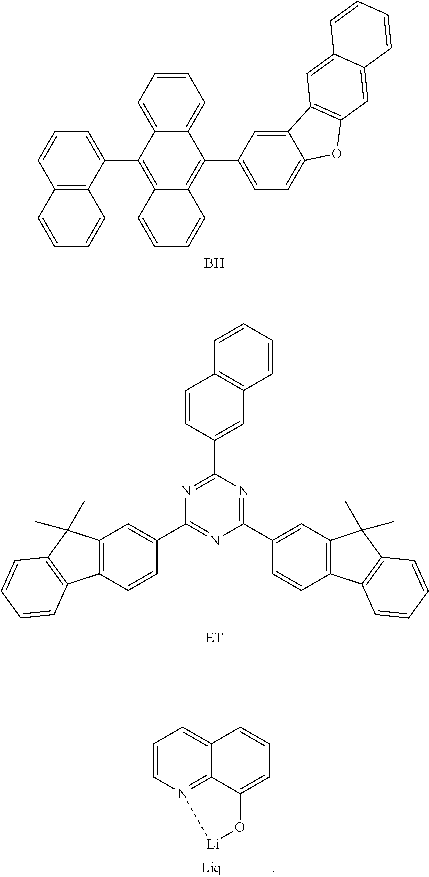

The following is a detailed description of the preparation processes for the OLED devices using the aforementioned materials through specific examples.

### Preparation of OLED-1 Device

Taking the preparation method for the OLED device using compound 1 as the guest material as an example, the prepared OLED device is called “an OLED-1 device”. The preparation method for the OLED-1 device includes the following steps:

Step a, cleaning an ITO conductive glass substrate. Providing the ITO conductive glass substrate and cleaning with one or more cleaning agents such as deionized water, acetone, isopropanol, chloroform, acetone, and isopropanol, and then treating by a UV ozone process.

Step b, forming a hole injection layer. Coating PEDOT on the ITO conductive glass substrate in a spin way, then treating on a hot plate at a temperature of 180° C. for 10 minutes to obtain the hole injection layer with a thickness of 40 nm.

Step c, forming a hole transport layer. Preparing a PVK solution with a concentration of 5 mg/mL using toluene as the solvent and PVK as the hole transport material, coating the PVK solution on the hole injection layer in a spin way, and treating on a hot plate at a temperature of 180° C. for 10 minutes to obtain the hole transport layer with a thickness of 20 nm.

Step d, forming a light-emitting layer. Preparing a methyl benzoate solution with a concentration of 15 mg/mL using methyl benzoate as the solvent, BH as the host material of the light-emitting layer, and the compound 1 as the guest material of the light-emitting layer. The weight ratio of BH to the compound 1 was 95:5 by mass. Then, coating the methyl benzoate solution on the hole transport layer in a spin way, and treating on a hot plate at a temperature of 180° C. for 10 minutes to obtain the light-emitting layer with a thickness of 40 nm.

Step e, forming an electron transport layer. Placing ET and Liq in different evaporation units of vacuum chamber above the light-emitting layer, and co-depositing at a weight ratio of 50:50 in high vacuum (1×10⁻⁶ millibar), to obtain the electron transport layer with a thickness of 20 nm.

Step f, depositing Al on the electron transport layer to obtain a cathode with a thickness of 100 nm.

Step g, encapsulating the device prepared above in a nitrogen glove box using UV cured resin.

### Preparation of OLED-2 Device to OLED-22 Device

According to the preparation method for the OLED-1 device, compounds 2-22 were used as guest materials for the light-emitting layers of OLED devices, respectively, to prepare corresponding OLED-2 to OLED-22 devices. It can be understood that, in the preparation methods for the OLED-2 to OLED-22 devices mentioned above, except for different guest materials for the light-emitting layers, all other experimental conditions are the same.

Further, according to the preparation method for the OLED-1 device, comparative compounds 1-2 were used as guest materials for the light-emitting layers of OLED devices, respectively, to prepare corresponding OLED-Ref1 and OLED-Ref2 devices. Compared to the preparation methods for the OLED-1 device, in the preparation methods for the OLED-Ref1 and OLED-Ref2 devices, except for different guest materials for the light-emitting layers, all other experimental conditions are the same.

In the present disclosure, the current voltage (J-V) characteristics of the above-mentioned OLED-1 to OLED-22, OLED-Ref1, and OLED-Ref2 devices were characterized, while important parameters such as color coordinate (CIE, (x, y)), voltage@1knits (V), luminous efficiency (CE@1knits), and life (LT90@1knits) were tested, the results are shown in table 2. The voltage is tested at an initial brightness of 1knits, the luminous efficiency is the relative value obtained at the current density of 10 mA/cm², and the life refers to a time when the brightness of the device delays from initial brightness of 1knits to 90% of the initial brightness under a constant current.

TABLE 2

| | | | Voltage | CE@ | LT90@ |
|---|---|---|---|---|---|
| OLED | Guest | CIE | @1 knits | 1 knits | 1 knits |
| Device | material | (x, y) | (V) | (cd/A) | (h) |
| OLED-1 | Compound 1 | 0.141, 0.082 | 5.5 | 6.2 | 138 |
| OLED-2 | Compound 2 | 0.142, 0.082 | 5.3 | 6.0 | 144 |
| OLED-3 | Compound 3 | 0.141, 0.083 | 5.4 | 6.1 | 148 |
| OLED-4 | Compound 4 | 0.143, 0.082 | 5.5 | 6.0 | 158 |
| OLED-5 | Compound 5 | 0.142, 0.081 | 5.3 | 6.2 | 157 |
| OLED-6 | Compound 6 | 0.142, 0.083 | 5.3 | 5.6 | 154 |
| OLED-7 | Compound 7 | 0.144, 0.084 | 5.4 | 5.8 | 158 |
| OLED-8 | Compound 8 | 0.145, 0.085 | 5.3 | 5.4 | 168 |
| OLED-9 | Compound 9 | 0.141, 0.086 | 5.3 | 5.8 | 156 |
| OLED-10 | Compound 10 | 0.142, 0.082 | 5.4 | 6.7 | 161 |
| OLED-11 | Compound 11 | 0.143, 0.082 | 5.3 | 5.8 | 158 |
| OLED-12 | Compound 12 | 0.142, 0.084 | 5.4 | 5.9 | 158 |
| OLED-13 | Compound 13 | 0.142, 0.083 | 5.3 | 5.5 | 157 |
| OLED-14 | Compound 14 | 0.142, 0.082 | 5.3 | 6.8 | 161 |
| OLED-15 | Compound 15 | 0.143, 0.081 | 5.4 | 5.9 | 149 |
| OLED-16 | Compound 16 | 0.142, 0.083 | 5.3 | 5.5 | 141 |
| OLED-17 | Compound 17 | 0.141, 0.082 | 5.2 | 5.6 | 153 |
| OLED-18 | Compound 18 | 0.142, 0.083 | 5.3 | 5.3 | 154 |
| OLED-19 | Compound 19 | 0.141, 0.083 | 5.3 | 5.4 | 151 |
| OLED-20 | Compound 20 | 0.142, 0.082 | 5.2 | 5.5 | 147 |
| OLED-21 | Compound 21 | 0.141, 0.082 | 5.4 | 5.8 | 149 |
| OLED-22 | Compound 22 | 0.142, 0.082 | 5.2 | 5.4 | 142 |
| OLED- | Comparative | 0.141, 0.131 | 5.7 | 3.2 | 97 |
| Ref1 | compound 1 | | | | |
| OLED- | Comparative | 0.141, 0.112 | 5.6 | 3.3 | 95 |
| Ref2 | compound 2 | | | | |

It can be seen from table 2 that, compared to the blue light-emitting devices prepared using the comparative compounds 1-2 as the guest materials for the light-emitting layers, the blue light-emitting devices prepared using the compounds 1-22 in examples 1-22 of the present disclosure as the guest materials for the light-emitting layers have better color coordinates, higher luminous efficiency, and longer life.

Specifically, luminous efficiency of OLED-Ref1 and OLED-Ref2 devices prepared using the comparative compounds 1-2 as the guest materials for the light-emitting layers is less than 3.2 cd/A, and life is less than 97 hours. But luminous efficiency of the OLED-1 to OLED-22 devices prepared using compounds 1-22 as the guest materials for the light-emitting layers in the present disclosure ranges from 5.4 cd/A to 6.7 cd/A, and life ranges from 138 hours to 168 hours. That is, compared to the blue light-emitting devices prepared using the comparative compounds 1-2 in the comparative examples 1-2 as the guest materials for the light-emitting layers, the life of the blue light-emitting devices prepared using the boron-nitrogen compounds 1-22 prepared by the examples 1-22 of the present disclosure as the guest materials for the light-emitting layers is significantly improved. Thus, the present disclosure, by introducing the pyrene group that enhances the overall conjugation of the boron-nitrogen compound, makes the boron-nitrogen compound have a large molecular weight, planarity, and conjugation, due to the multi-benzene ring structure of the pyrene group. When the boron-nitrogen compound is used as a blue guest material in blue light-emitting devices, it not only causes blue light emitted by the blue light-emitting devices to lean towards dark blue, but also improves luminous efficiency and life of the blue light-emitting devices.

The boron-nitrogen compound and the organic electronic device containing the boron-nitrogen compound provided by the embodiments of the present disclosure are described in detail. In this context, specific embodiments are adopted to illustrate a principle and implementation modes of the present disclosure. The description of the above-mentioned embodiments is only used to help understand methods and a core idea of the present disclosure. At the same time, for those skilled in the art, according to the idea of the present disclosure, there might be changes in specific implementation modes and a scope of the present disclosure, which falls within the scope of the protection of the present disclosure. In conclusion, contents of the specification should not be interpreted as a limitation of the present disclosure.

What is claimed is:

1. A boron-nitrogen compound having a structure represented by formula (1) or formula (2): 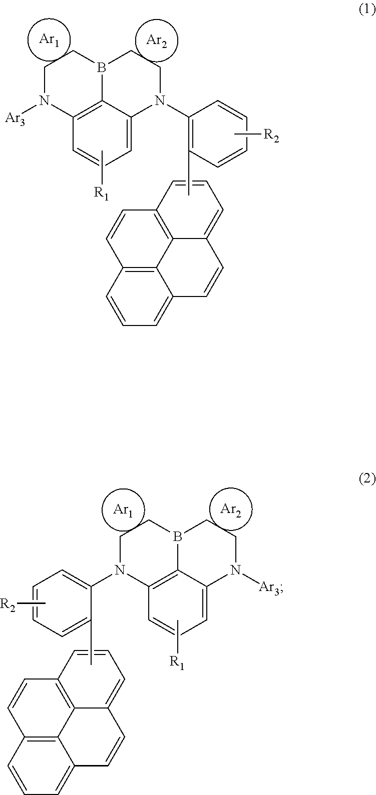
wherein Ar₁ is independently selected from any one of structures represented by formula (X-1) to formula (X-3): 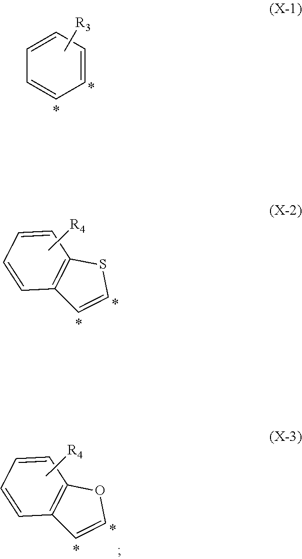
Ar₂ is independently selected from any one of structures represented by formula (A-1) to formula (A-7): 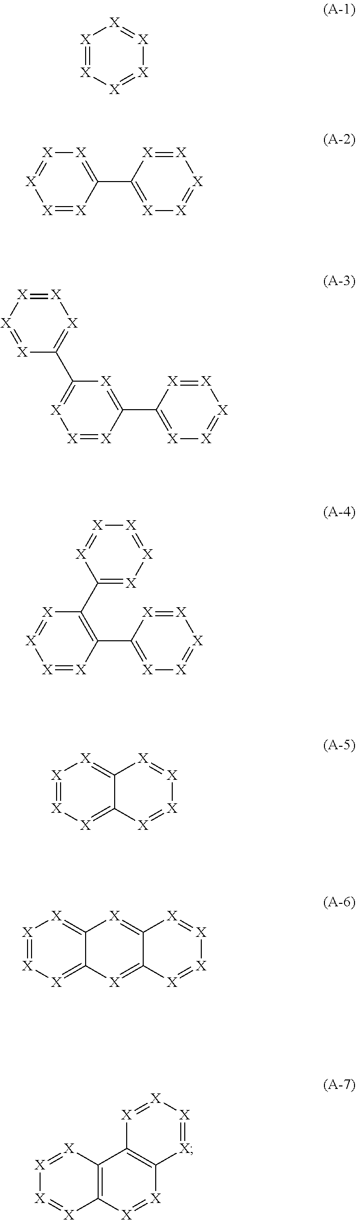
and
Ar₃ is independently selected from any one of the following structures: 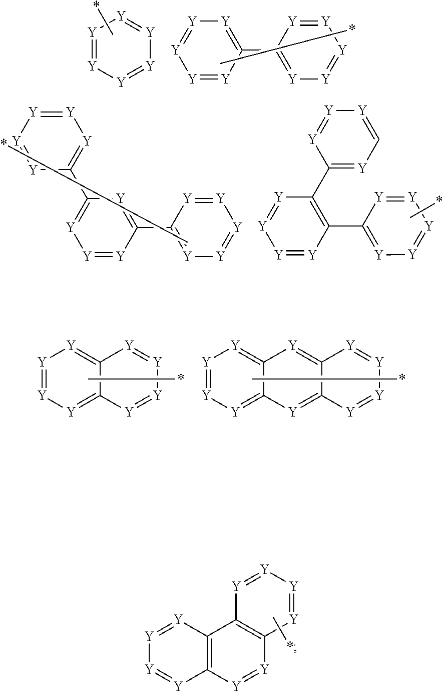
wherein X and Y are each independently selected from CR₅;
R₁-R₅ are each independently selected from H, D, a C₁-C₂₀ linear alkyl group, a C₃-C₂₀ branched alkyl group, a C₃-C₂₀ cyclic alkyl group, a substituted or unsubstituted aromatic group containing 5 to 30 ring atoms, a substituted or unsubstituted heteroaromatic group containing 5 to 30 ring atoms, or combinations thereof at each occurrence; and
* indicates a linking site.

2. The boron-nitrogen compound of claim 1, wherein Ar₁ is independently selected from any one of structures represented by formula (Y-1) to formula (Y-3): 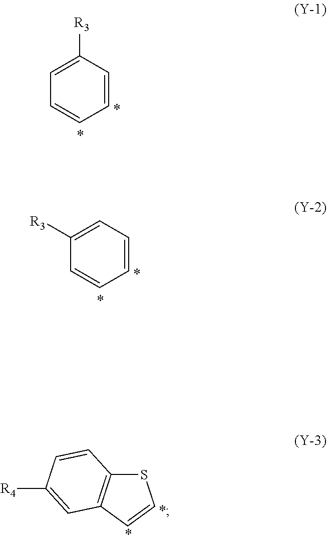
wherein R₃ and R₄ are each independently selected from H, a C₁-C₁₀ linear alkyl group, a C₃-C₁₀ branched alkyl group, a substituted or unsubstituted aromatic group containing 5 to 20 ring atoms, or a substituted or unsubstituted heteroaromatic group containing 5 to 20 ring atoms.

3. The boron-nitrogen compound of claim 1, wherein R₃ is independently selected from H, a C₁-C₅ linear alkyl group, a C₃-C₅ branched alkyl group, a substituted or unsubstituted aromatic group containing 6 to 20 ring atoms, or a substituted or unsubstituted heteroaromatic group containing 5 to 15 ring atoms.

4. The boron-nitrogen compound of claim 1, wherein R₃ is independently selected from a C₃-C₅ branched alkyl group or any one of structures represented by formula (B-1) to formula (B-5): 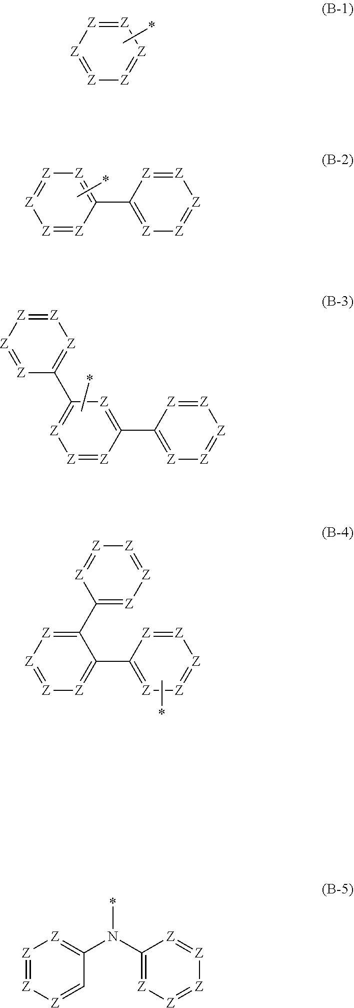
and
wherein Z is independently selected from CR₆, and R₆ is independently selected from H, a C₁-C₅ linear alkyl group, or a C₃-C₅ branched alkyl group.

5. The boron-nitrogen compound of claim 4, wherein at least one R₆ in any one of the formula (B-1) to formula (B-5) is not H, and R₆ is independently selected from H or a C₃-C₅ branched alkyl group.

6. The boron-nitrogen compound of claim 1, wherein R₃ is independently selected from any one of structures represented by formula (C-1) to formula (C-6):

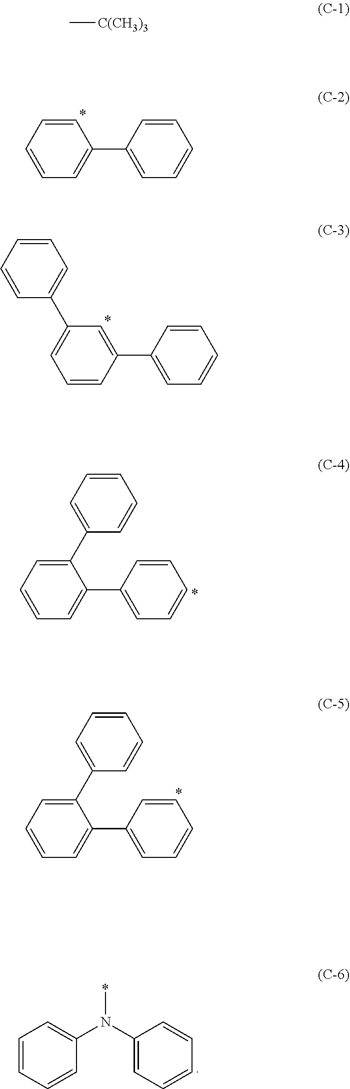

7. The boron-nitrogen compound of claim 1, wherein R₄ is selected from a C₁-C₅ linear alkyl group, a C₃-C₅ branched alkyl group, or a substituted or unsubstituted aromatic group containing 6 to 20 ring atoms.

8. The boron-nitrogen compound of claim 1, wherein R₄ is selected from a C₃-C₅ branched alkyl group, or a substituted or unsubstituted aromatic group containing 6 to 15 ring atoms.

9. The boron-nitrogen compound of claim 1, wherein R₄ is selected from a tert-butyl group or a phenyl group.

10. The boron-nitrogen compound of claim 1, wherein Ar₂ is independently selected from any one of structures represented by formula (D-1) to formula (D-4): 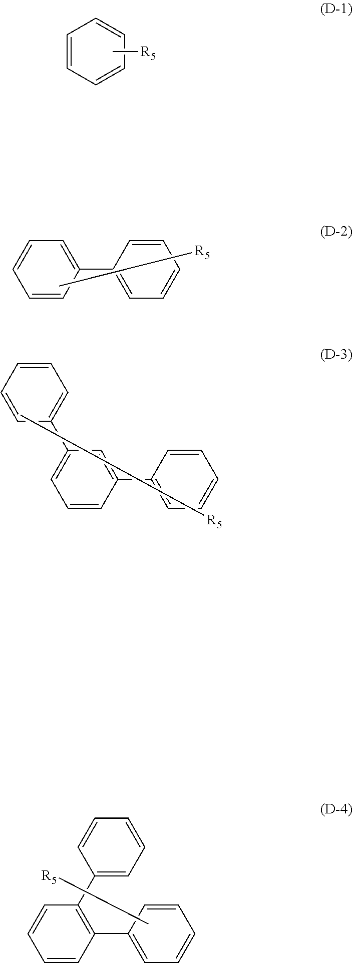
Ar₃ is independently selected from any one of the following structures: 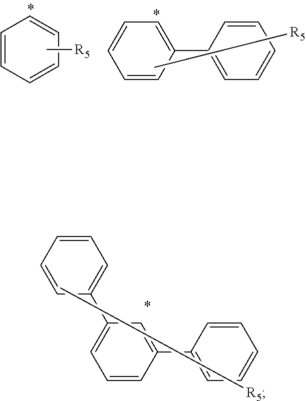
wherein R₅ is independently selected from H, a C₁-C₁₀ linear alkyl group, or a C₃-C₁₀ branched alkyl group.

11. The boron-nitrogen compound of claim 10, wherein R₅ is independently selected from H, a C₁-C₅ linear alkyl group, or a C₃-C₅ branched alkyl group.

12. The boron-nitrogen compound of claim 1, wherein R₁ is independently selected from any one of structures represented by formula (E-1) to formula (E-9): 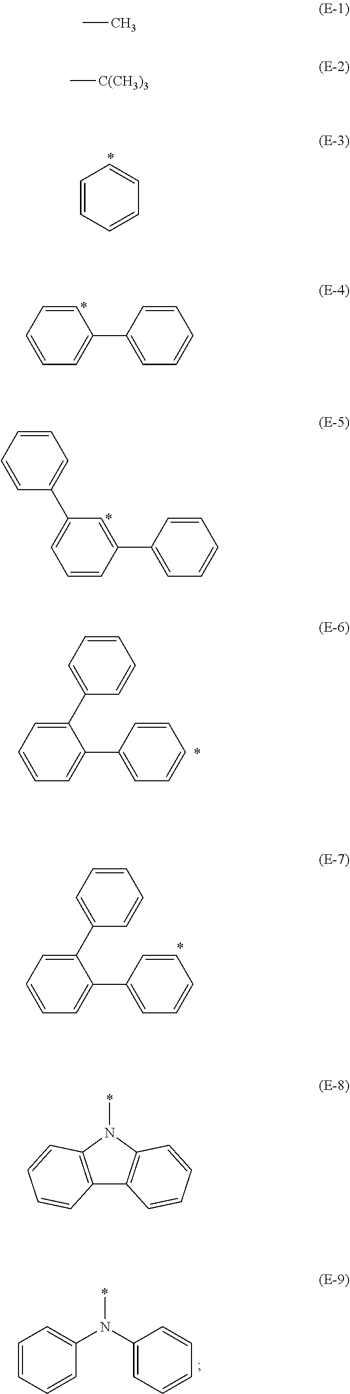
wherein R₂ is independently selected from H, a C₁-C₁₀ linear alkyl group, or a C₃-C₁₀ branched alkyl group.

13. The boron-nitrogen compound of claim 12, wherein R₁ is independently selected from any one of structures represented by formula (E-2), formula (E-3), formula (E-4), formula (E-8), and formula (E-9).

14. The boron-nitrogen compound of claim 1, wherein R₂ is independently selected from H, a C₁-C₁₀ linear alkyl group, or a C₃-C₁₀ branched alkyl group.

15. The boron-nitrogen compound of claim 1, wherein R₂ is independently selected from H, a C₁-C₅ linear alkyl group, or a C₃-C₅ branched alkyl group.

16. The boron-nitrogen compound of claim 1, wherein the boron-nitrogen compound has a structure represented by formula (2-1) or formula (2-5):

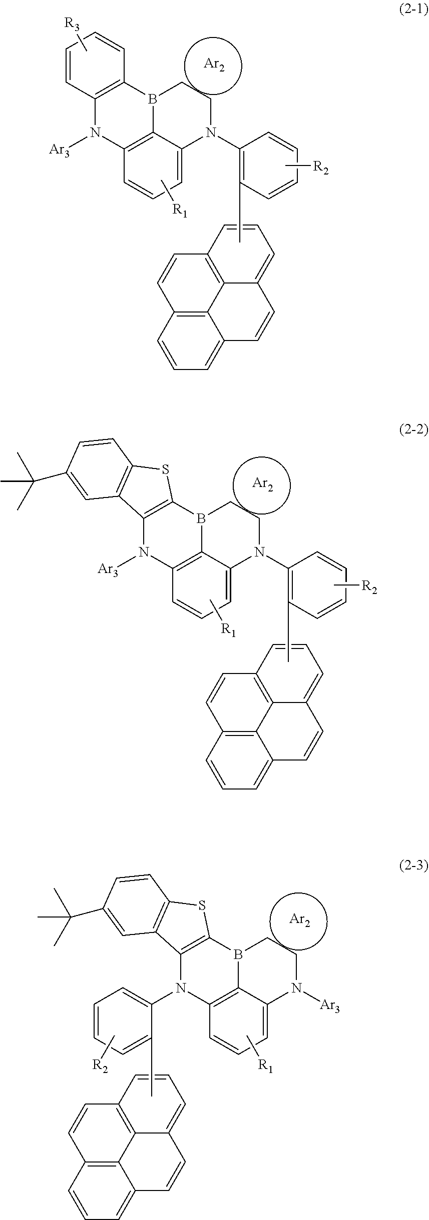

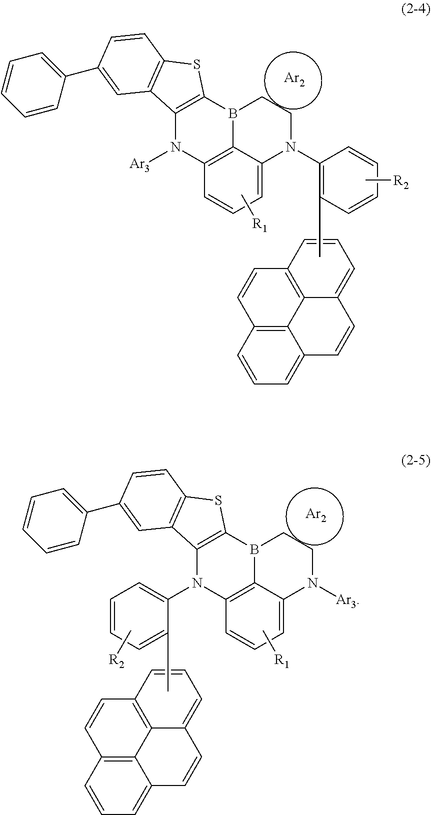

17. The boron-nitrogen compound of claim 1, wherein the boron-nitrogen compound has a structure represented by formula (3-1) or formula (3-7): 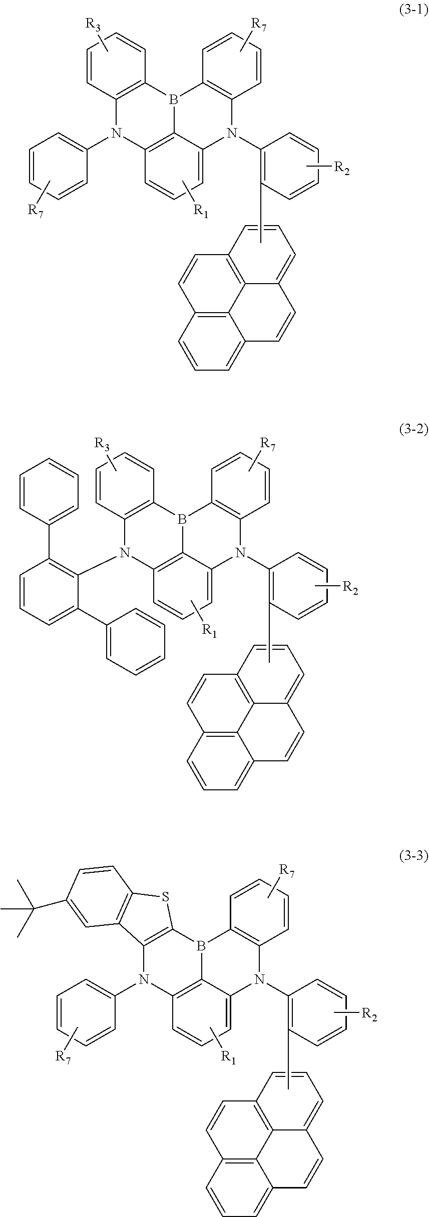 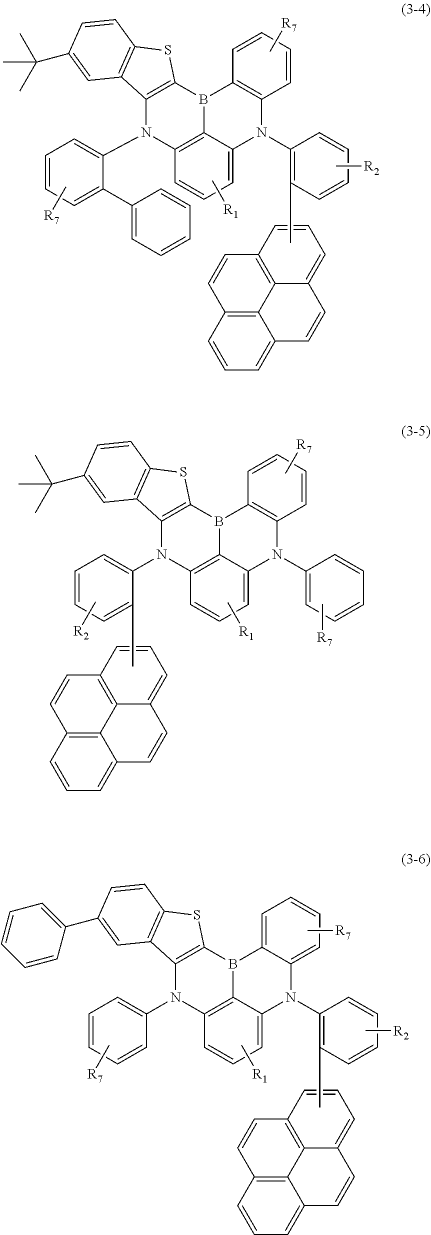 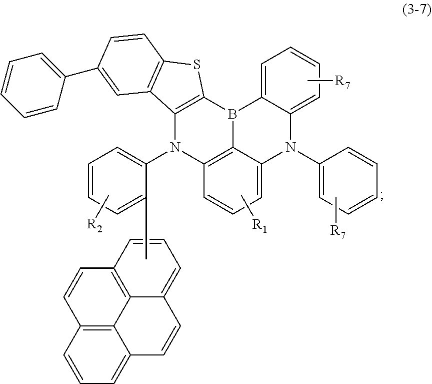
and
wherein R₇ is independently selected from H, a C₁-C₁₀ linear alkyl group, a C₃-C₁₀ branched alkyl group, a substituted or unsubstituted aromatic group containing 5 to 20 ring atoms, or a substituted or unsubstituted heteroaromatic group containing 5 to 20 ring atoms.

18. The boron-nitrogen compound of claim 17, wherein R₁-R₅ are each independently selected from H, a C₁-C₁₀ linear alkyl group, a C₃-C₁₀ branched alkyl group, a substituted or unsubstituted aromatic group containing 5 to 20 ring atoms, or a substituted or unsubstituted heteroaromatic group containing 5 to 20 ring atoms; and wherein R₇ is independently selected from any one of the following structures:

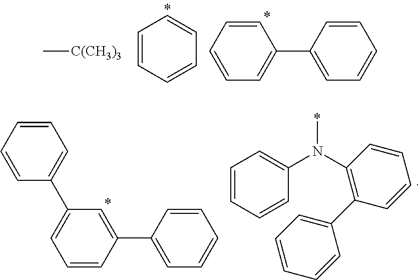

19. The boron-nitrogen compound of claim 1, wherein the boron-nitrogen compound is selected from any one of the following structures:

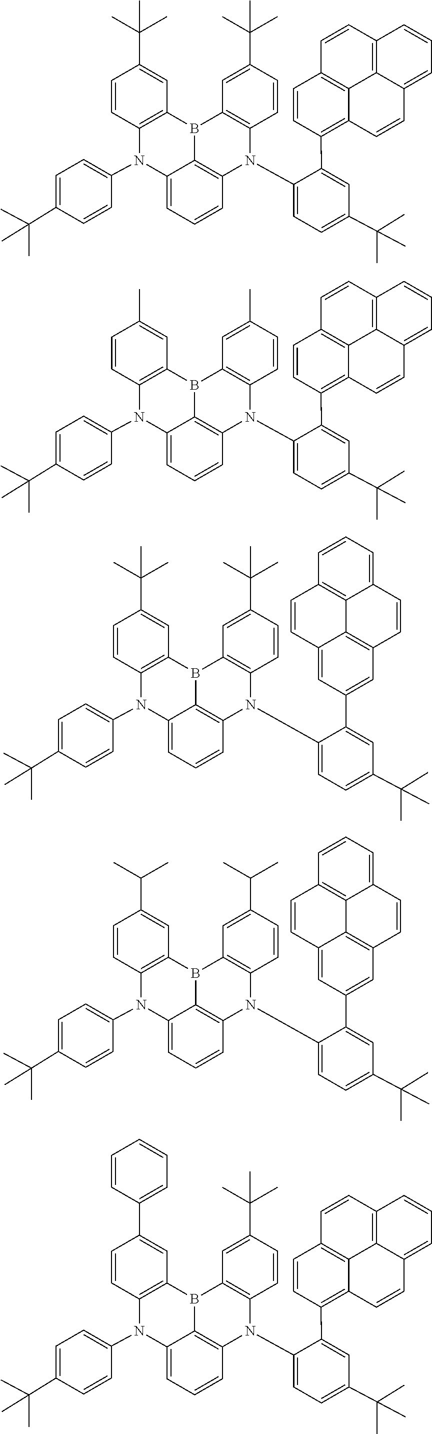

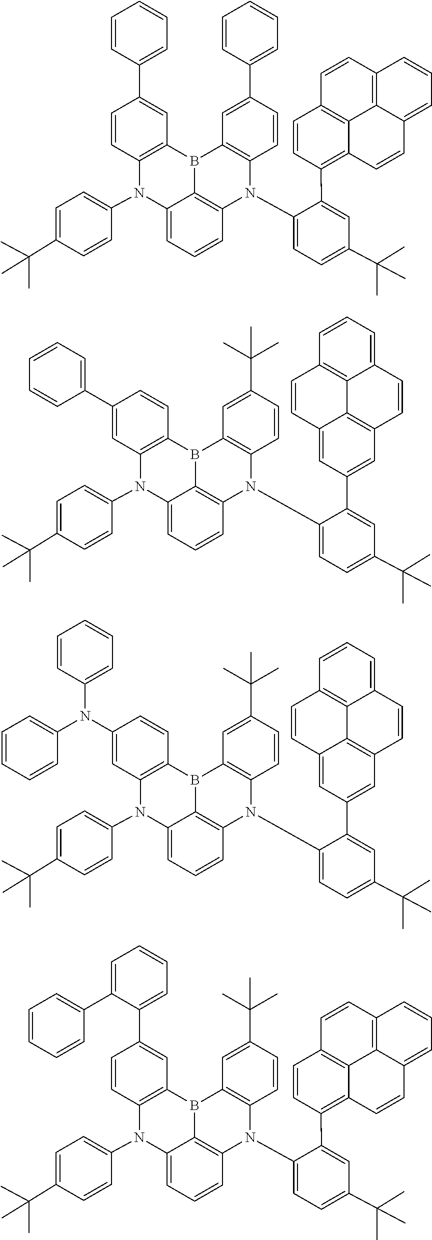

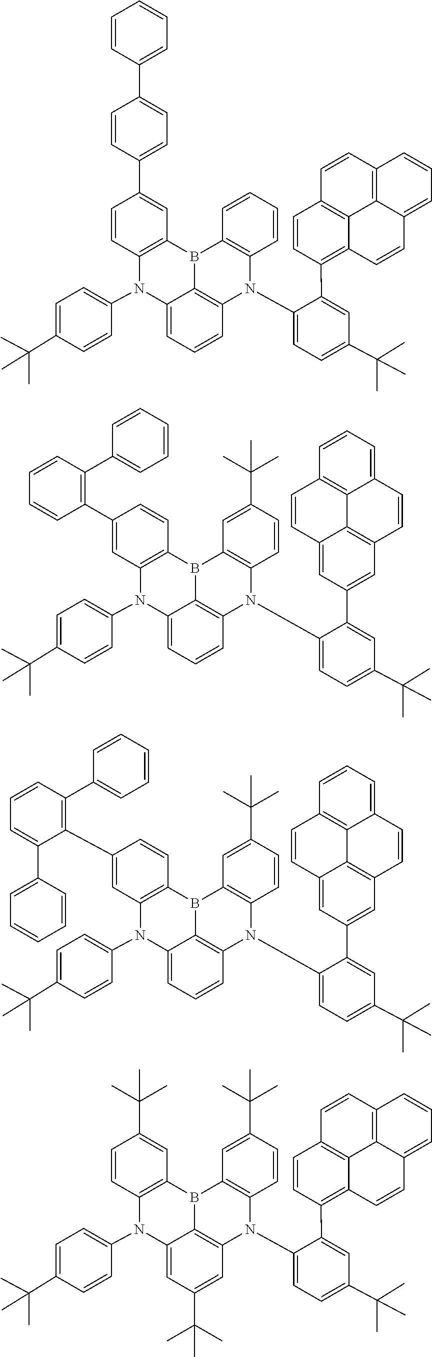

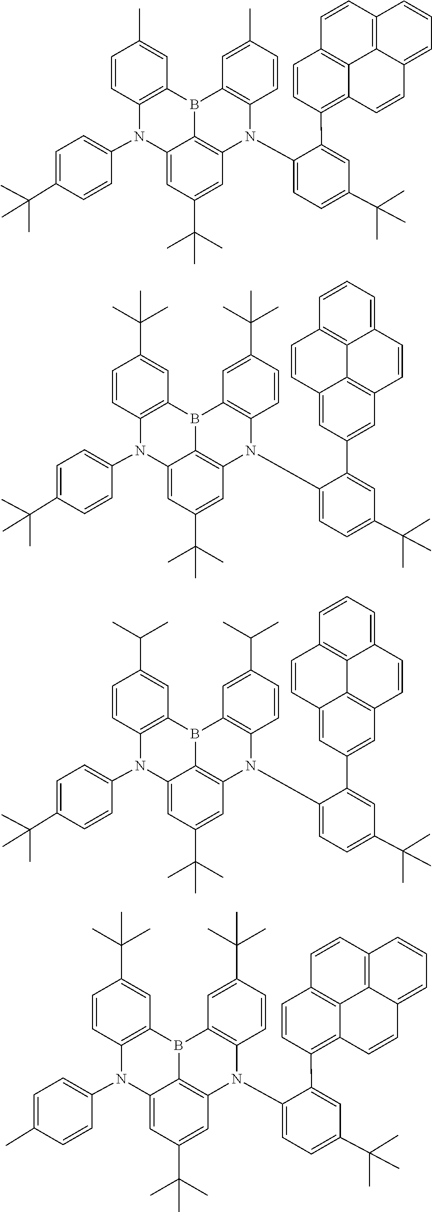

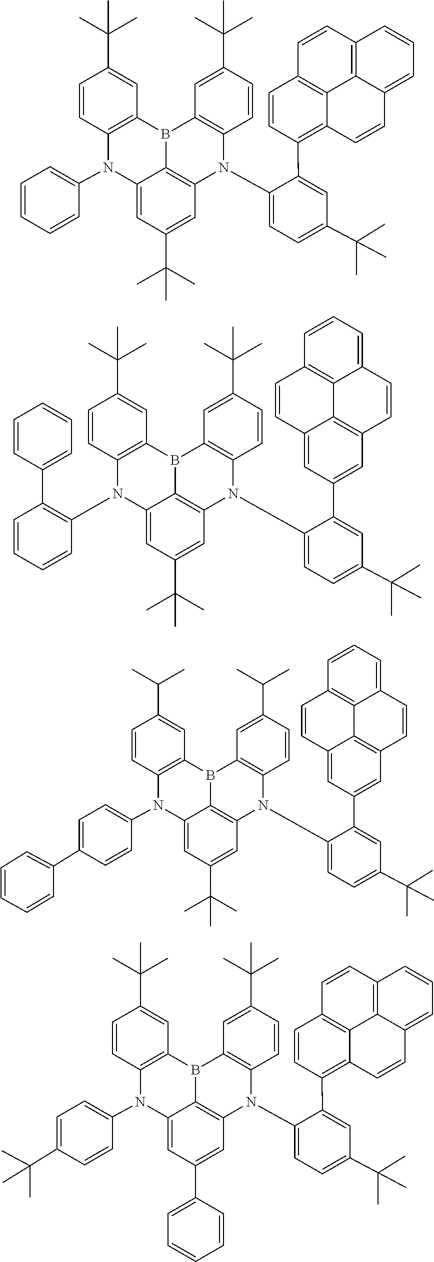

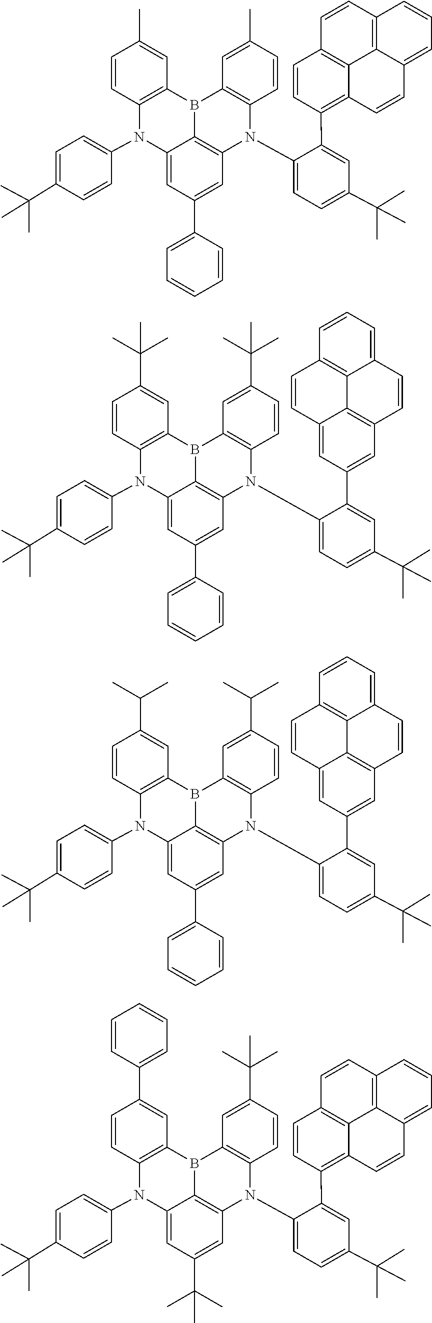

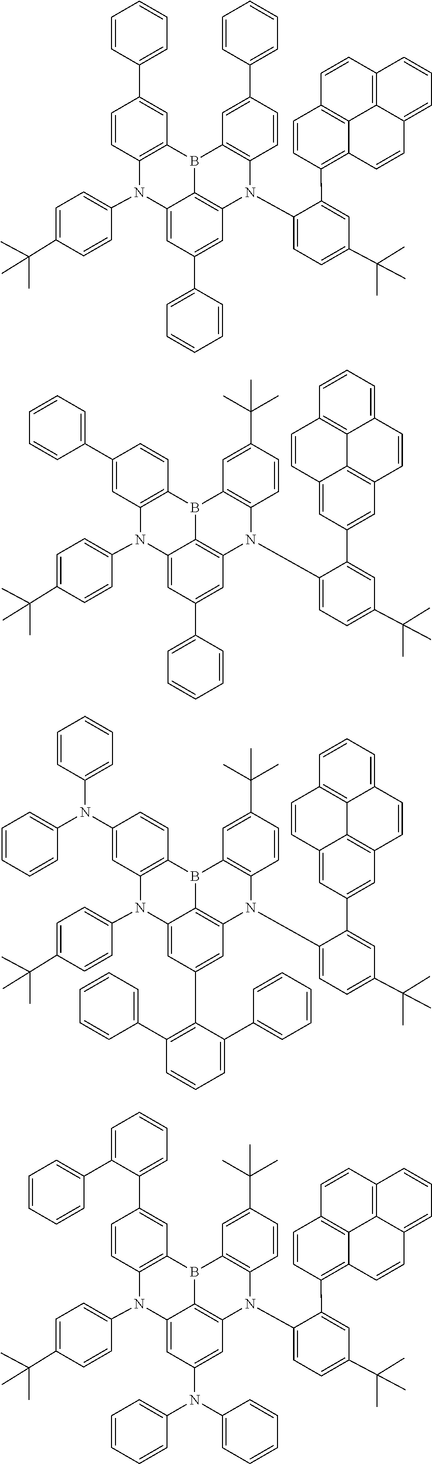

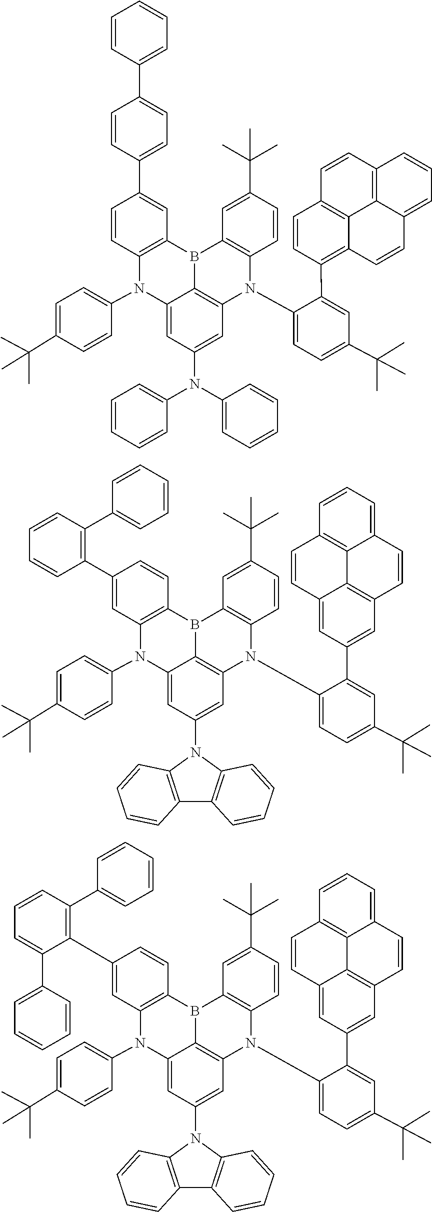

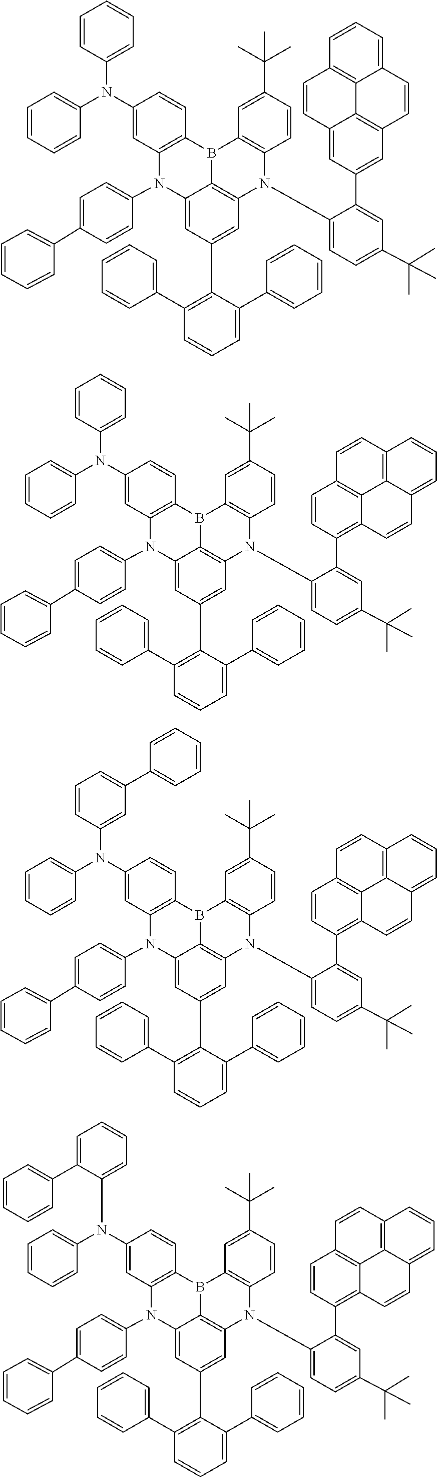

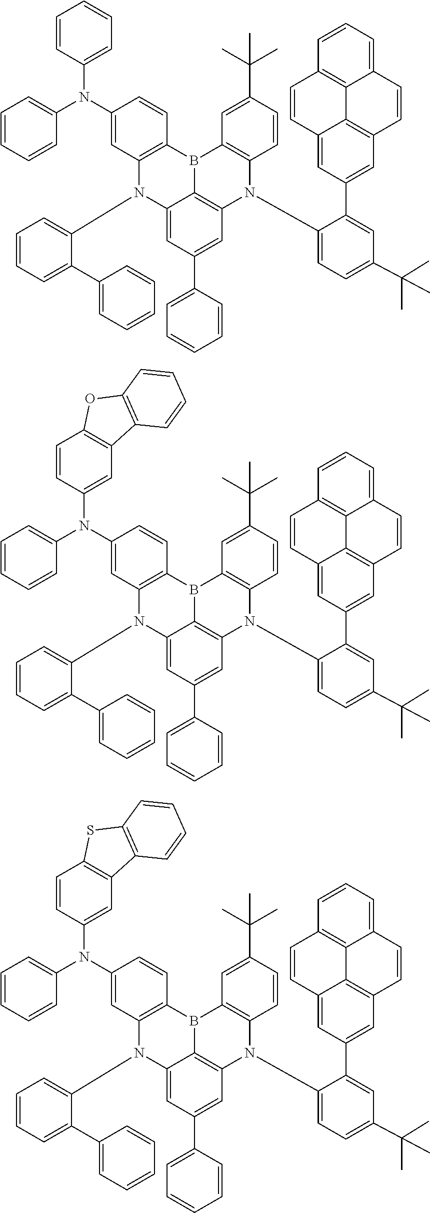

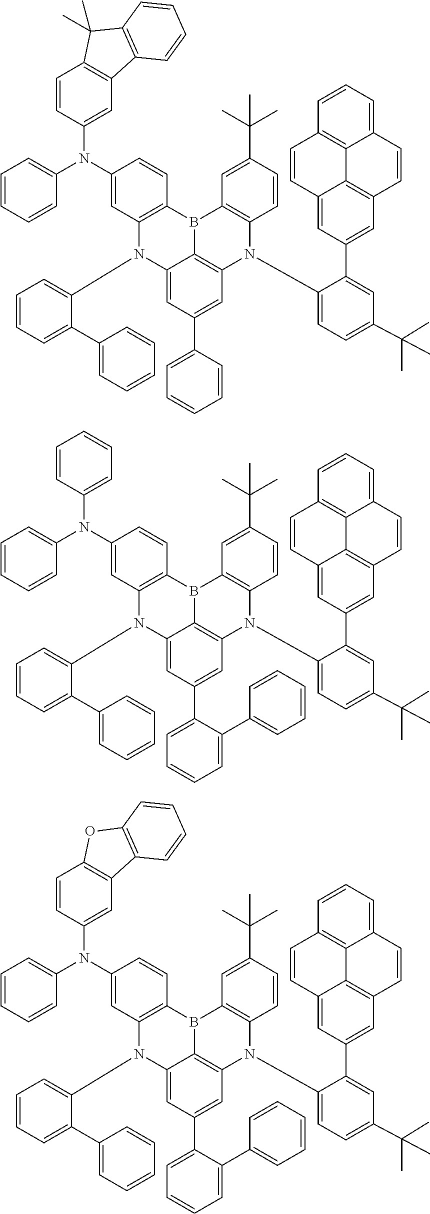

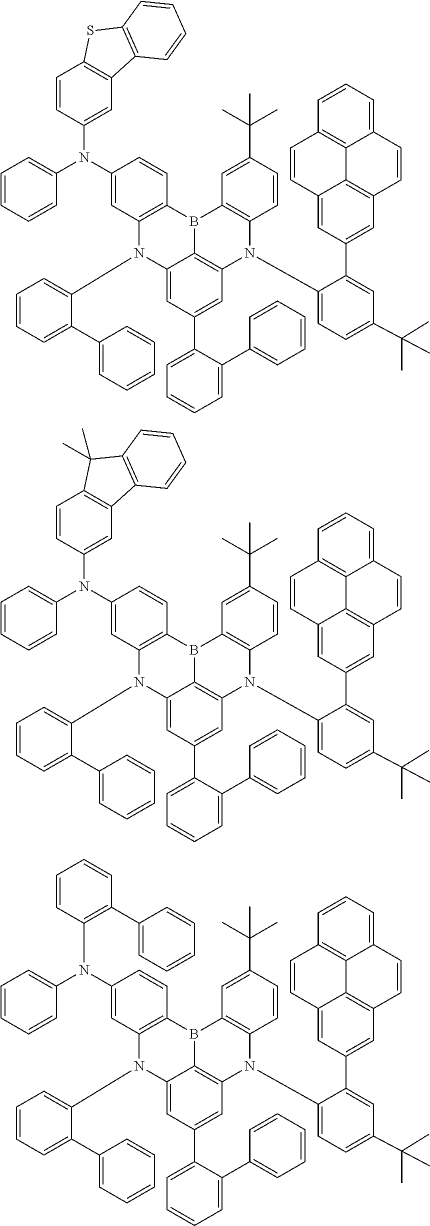

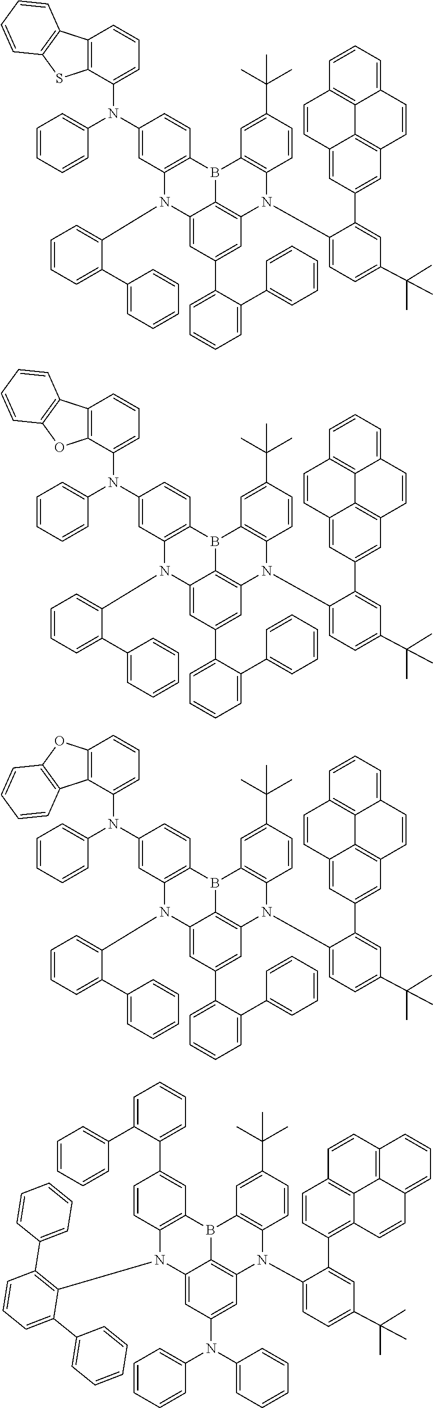

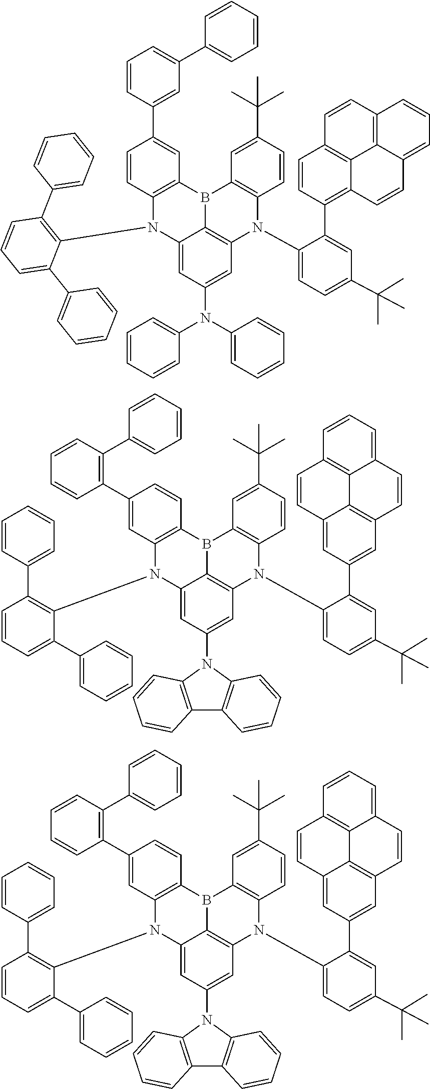

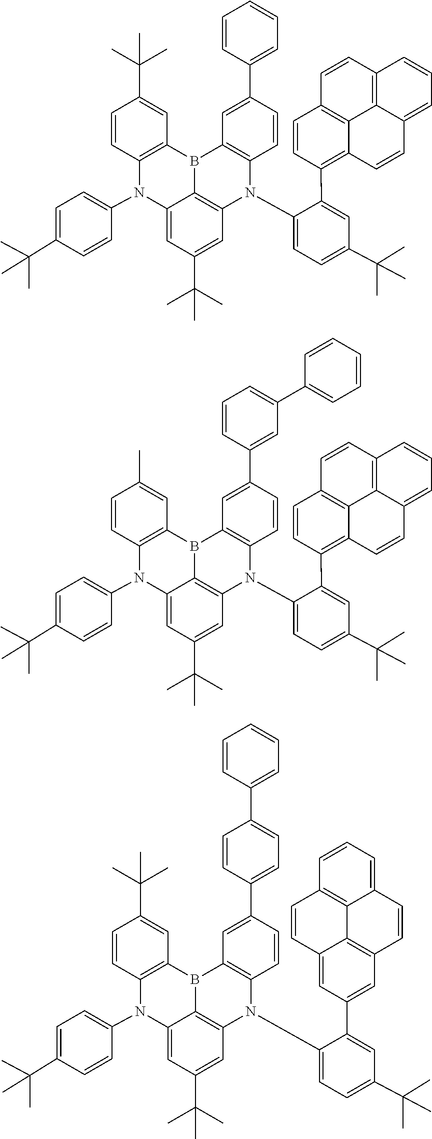 [SMILES: CC(C)(C)c1ccc(N2c3ccc(C(C)(C)C)cc3B3c4cc(-c5ccccc5)ccc4N(c4ccc(C(C)(C)C)cc4-c4ccc5ccc6cccc7ccc4c5c67)c4cc(C(C)(C)C)cc2c43)cc1 ; Cc1ccc2c(c1)B1c3cc(-c4cccc(-c5ccccc5)c4)ccc3N(c3ccc(C(C)(C)C)cc3-c3ccc4ccc5cccc6ccc3c4c56)c3cc(C(C)(C)C)cc(c31)N2c1ccc(C(C)(C)C)cc1 ; CC(C)(C)c1ccc(N2c3ccc(C(C)(C)C)cc3B3c4cc(-c5ccc(-c6ccccc6)cc5)ccc4N(c4ccc(C(C)(C)C)cc4-c4cc5ccc6cccc7ccc(c4)c5c67)c4cc(C(C)(C)C)cc2c43)cc1]

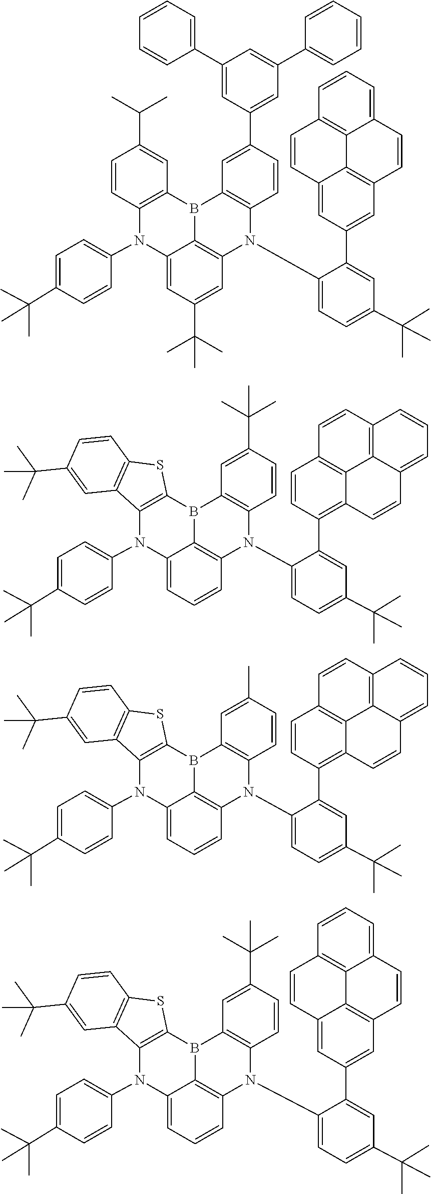

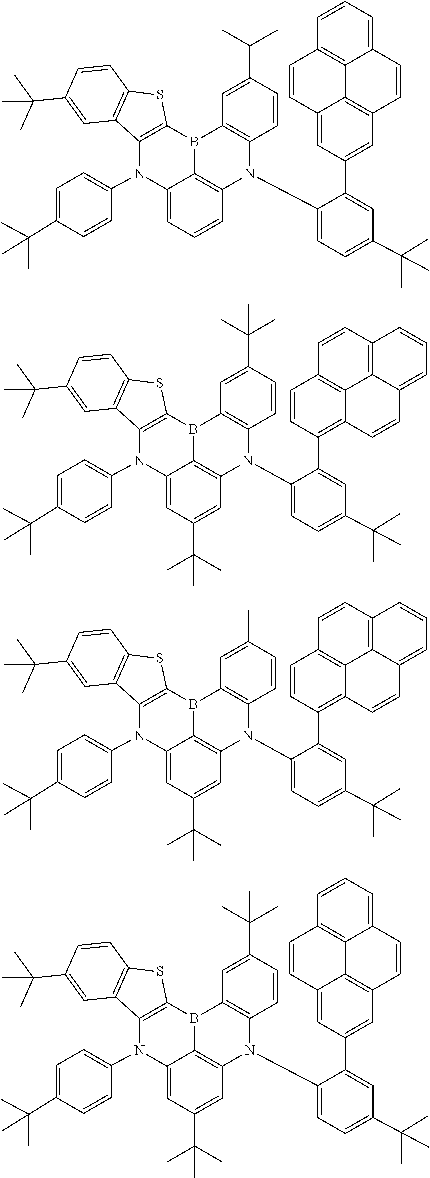

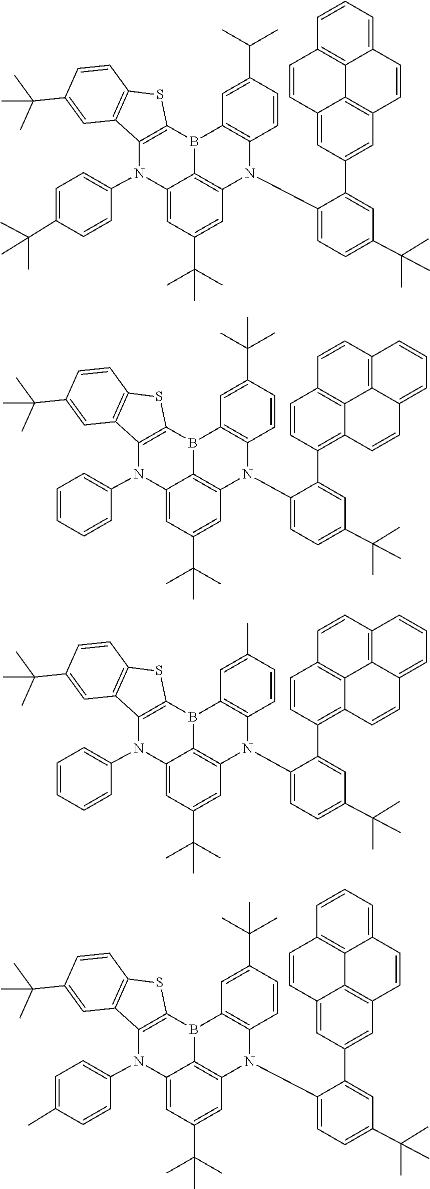

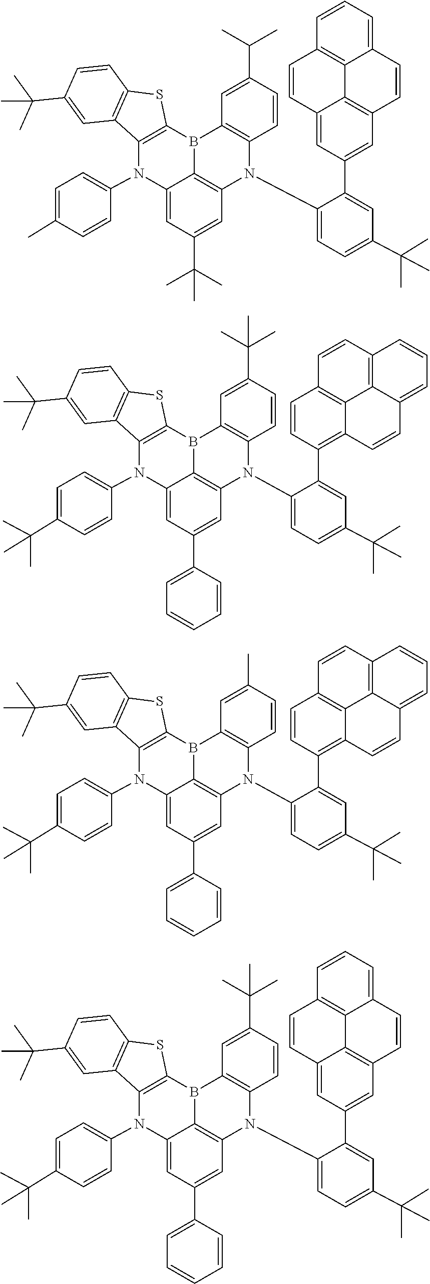

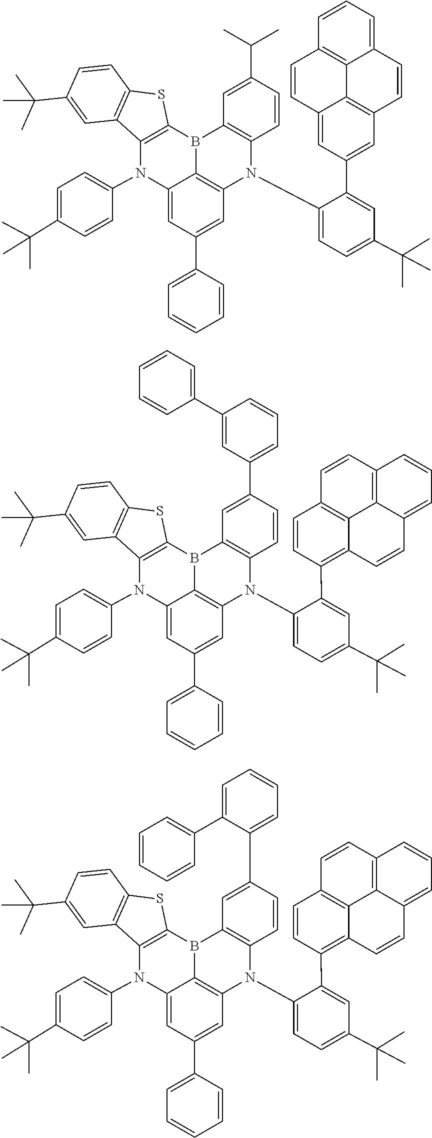

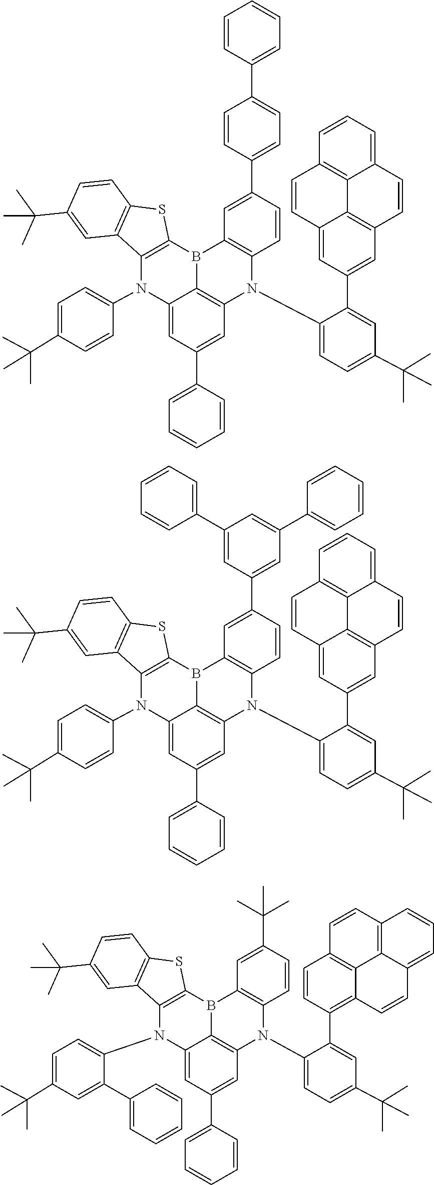

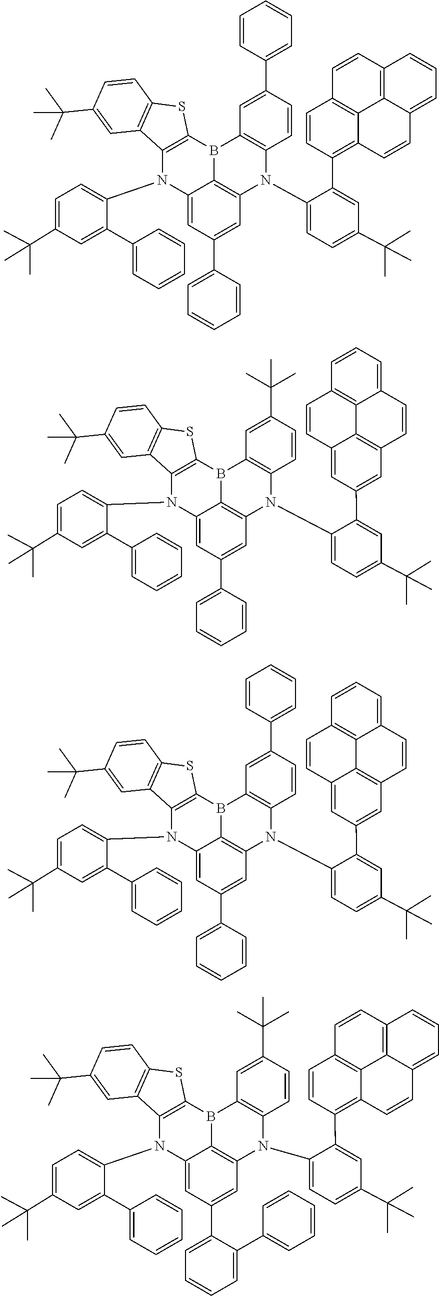

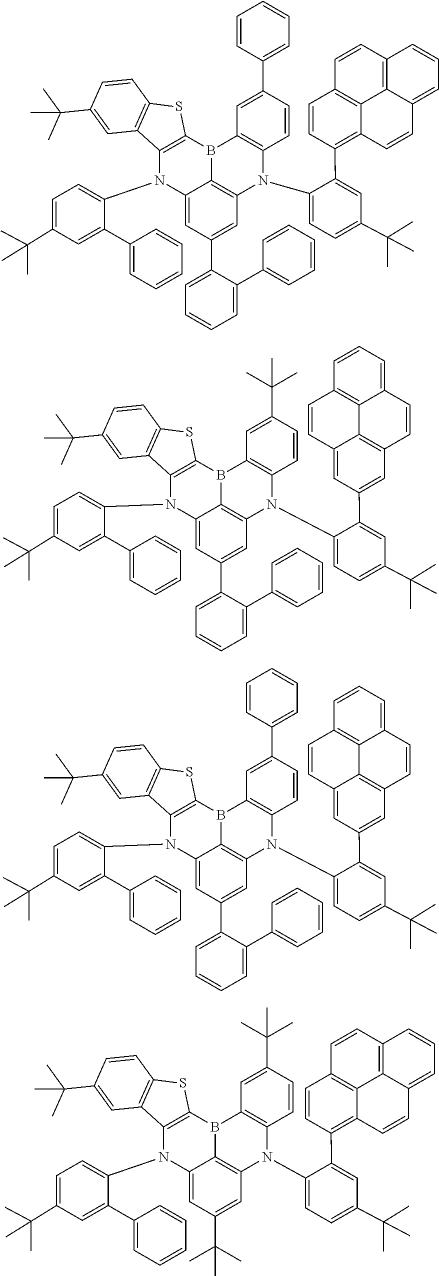

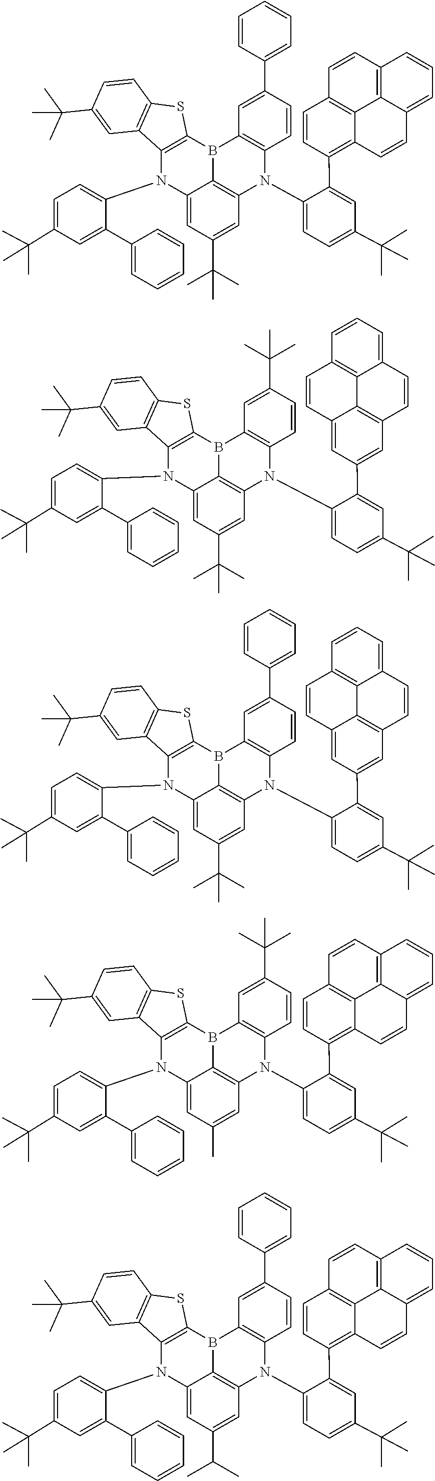

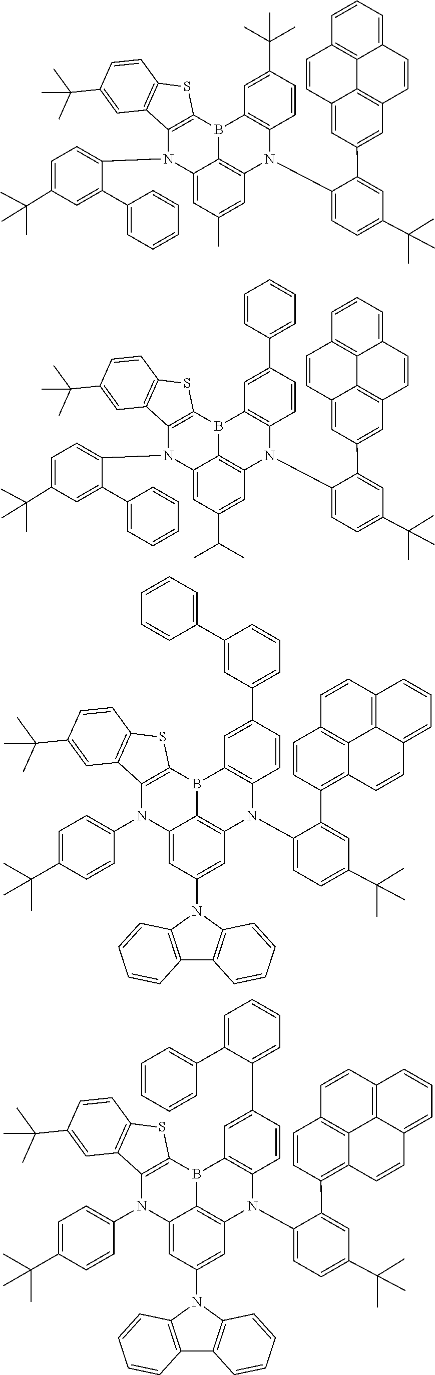

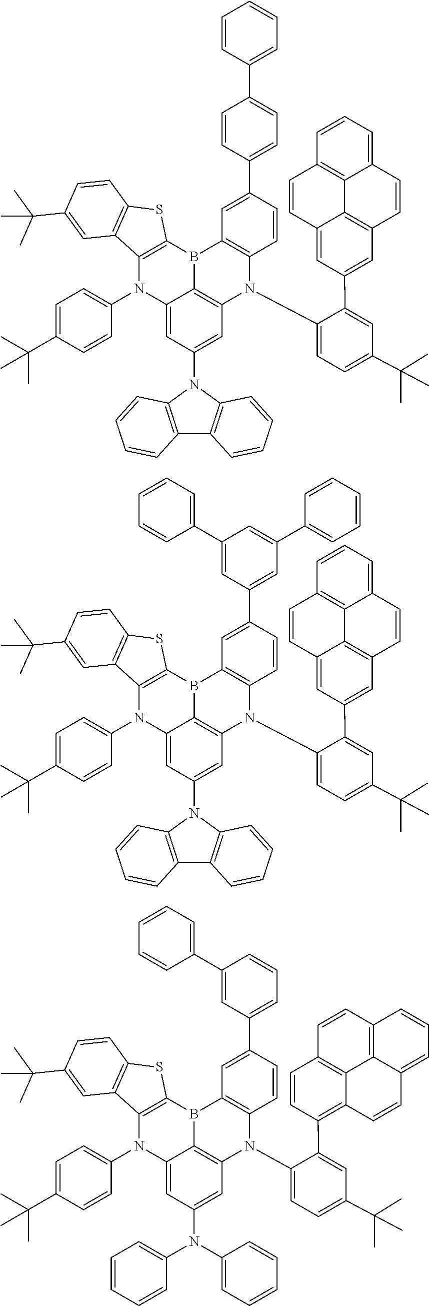

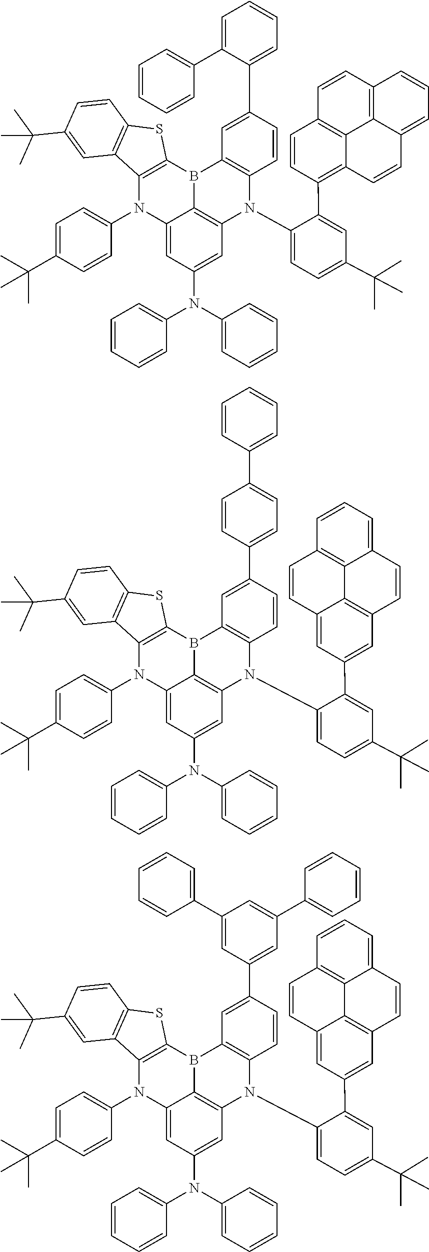

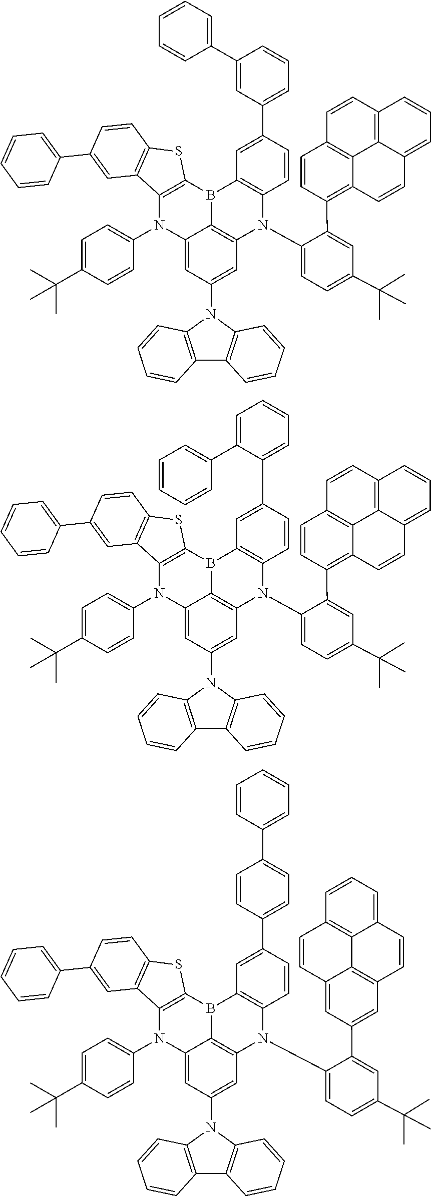

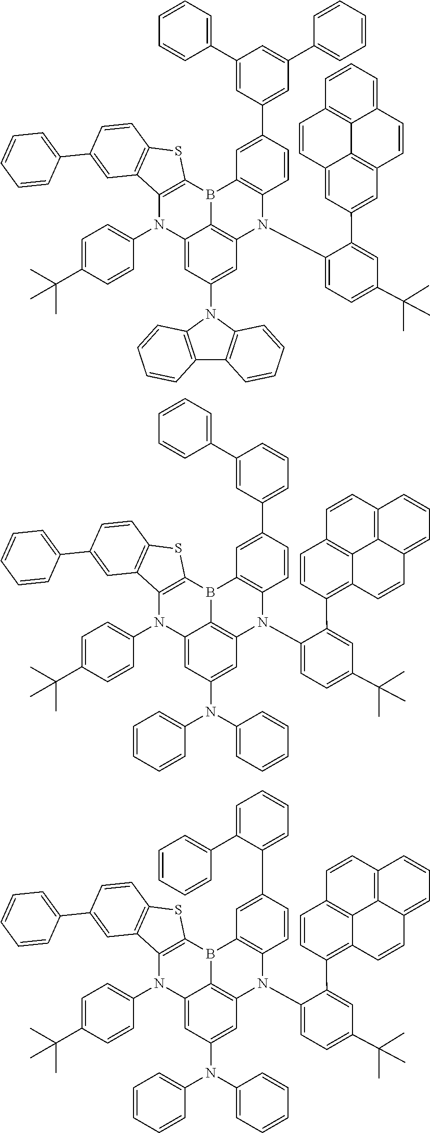

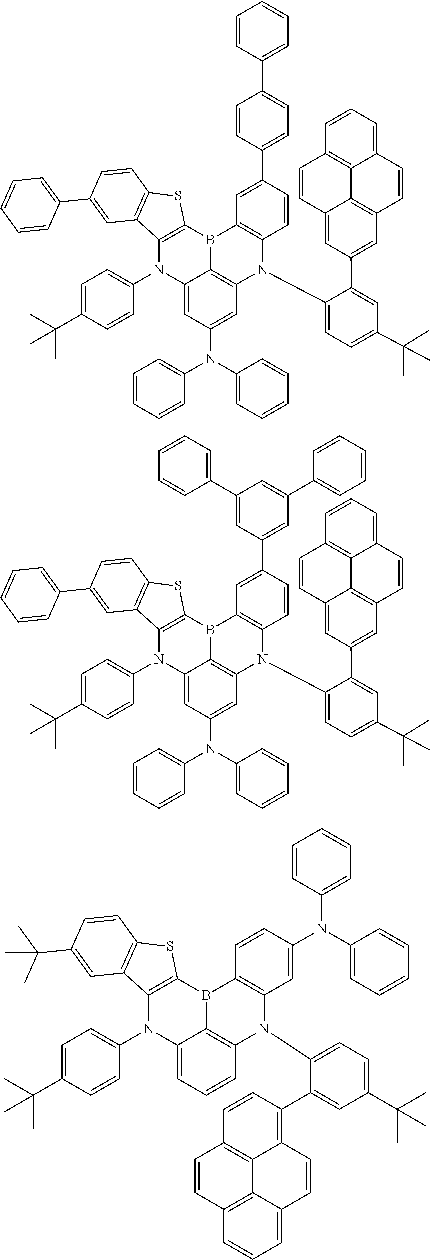

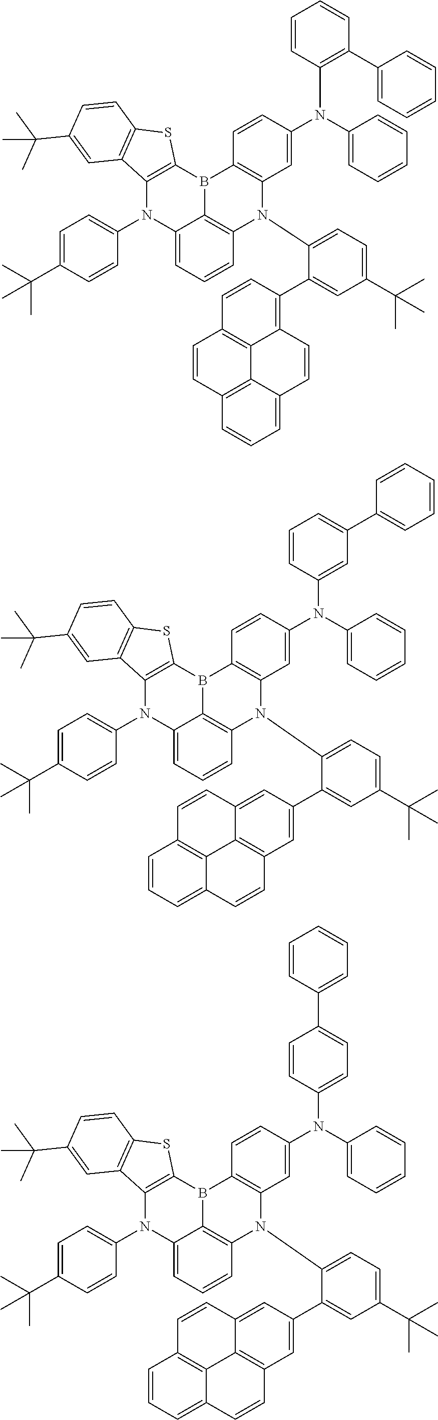

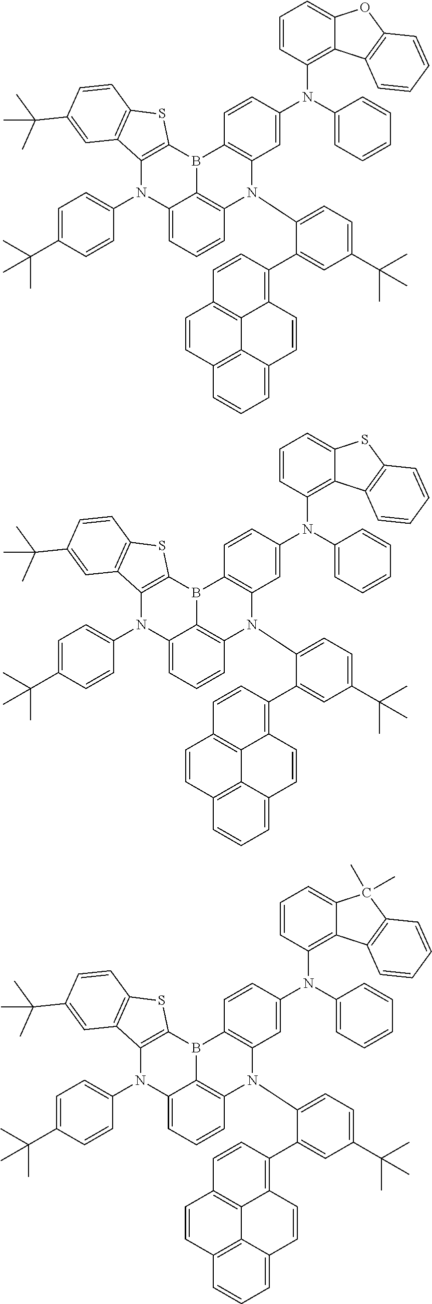 [SMILES: CC(C)(C)c1ccc(N2c3cccc4c3B(c3ccc(N(c5ccccc5)c5cccc6oc7ccccc7c56)cc3N4c3ccc(C(C)(C)C)cc3-c3ccc4ccc5cccc6ccc3c4c56)c3sc4ccc(C(C)(C)C)cc4c32)cc1 ; CC(C)(C)c1ccc(N2c3cccc4c3B(c3ccc(N(c5ccccc5)c5cccc6sc7ccccc7c56)cc3N4c3ccc(C(C)(C)C)cc3-c3ccc4ccc5cccc6ccc3c4c56)c3sc4ccc(C(C)(C)C)cc4c32)cc1 ; CC(C)(C)c1ccc(N2c3cccc4c3B(c3ccc(N(c5ccccc5)c5cccc6c5-c5ccccc5C6(C)C)cc3N4c3ccc(C(C)(C)C)cc3-c3ccc4ccc5cccc6ccc3c4c56)c3sc4ccc(C(C)(C)C)cc4c32)cc1]

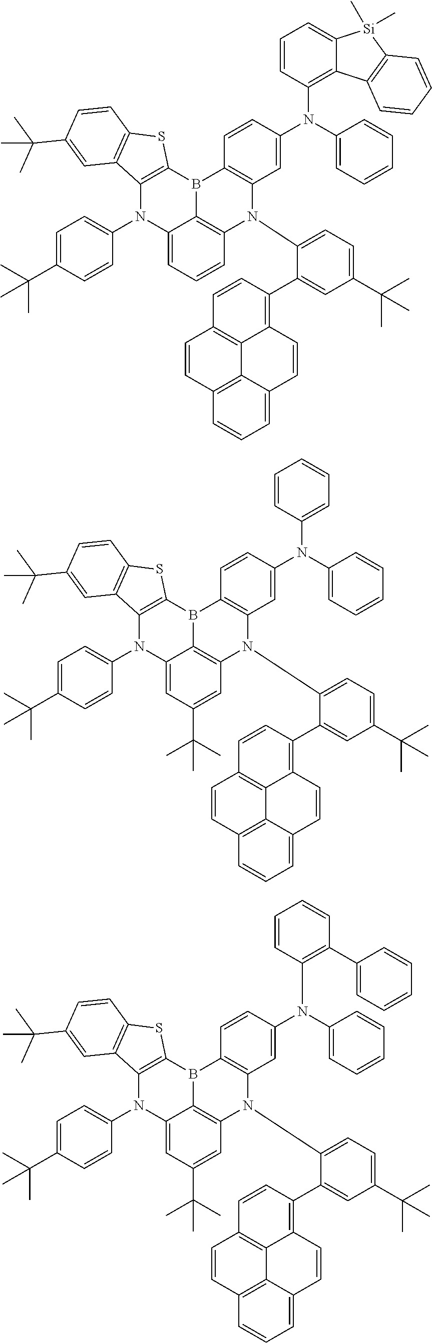

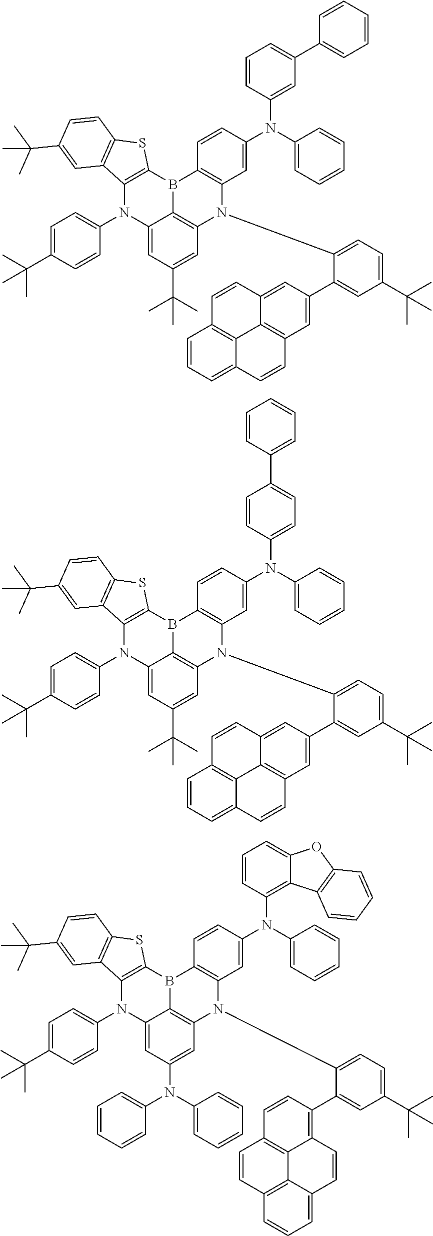

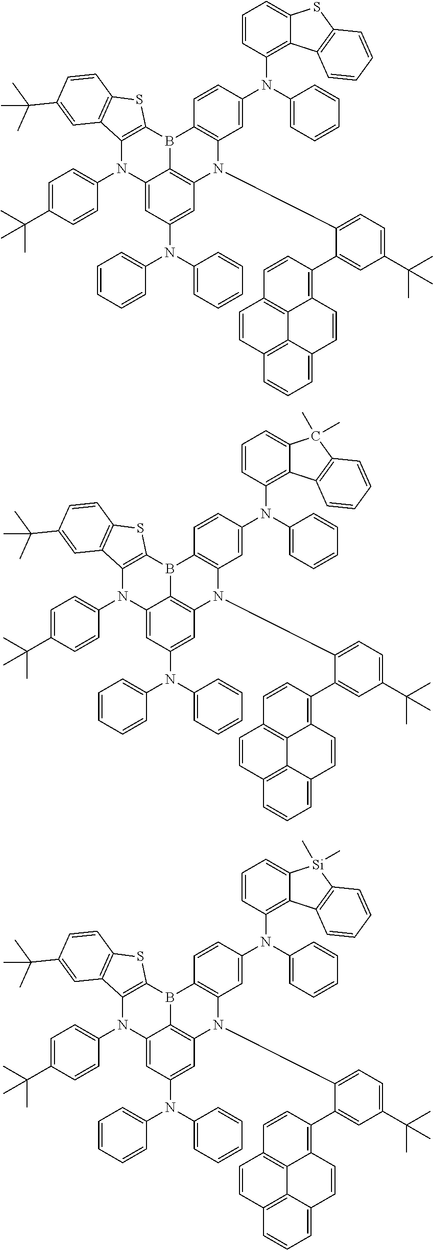

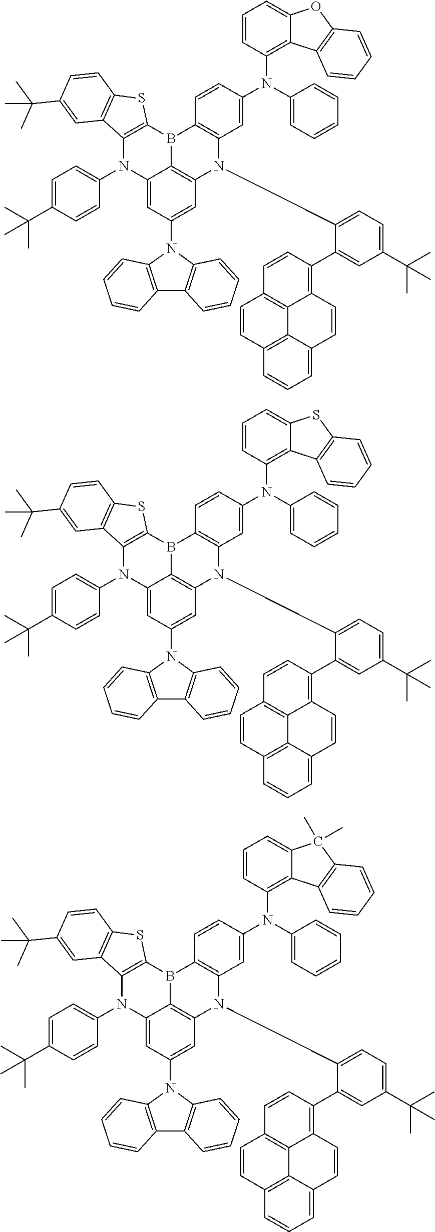

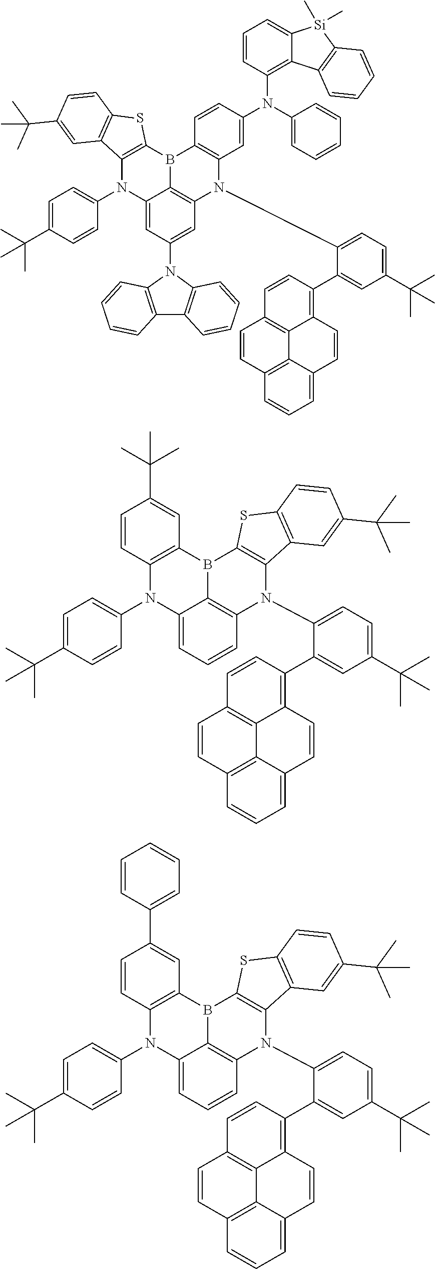

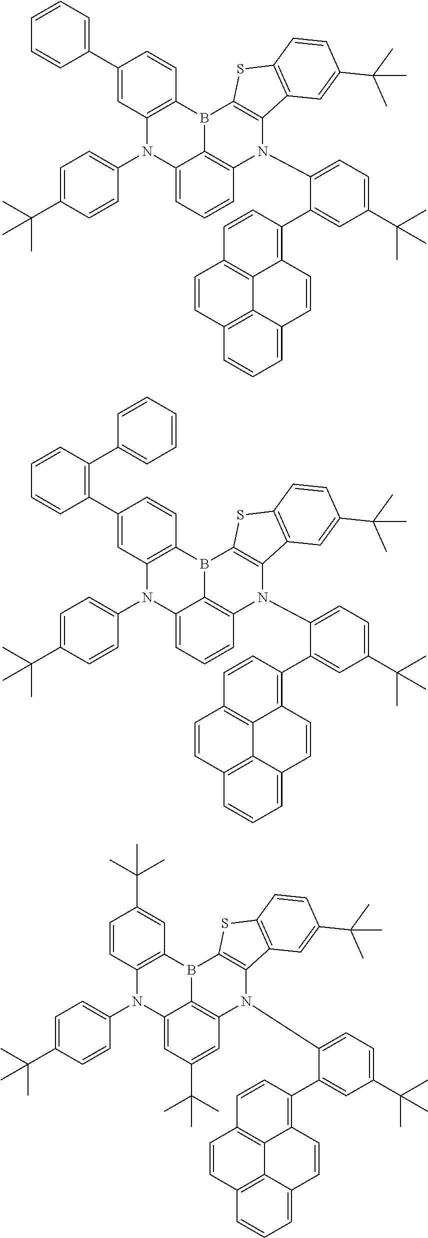

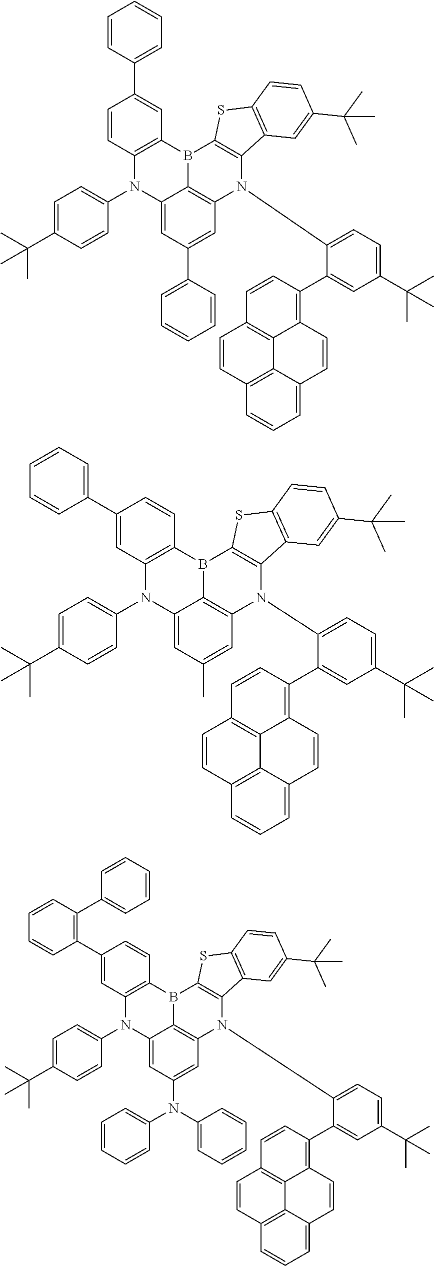

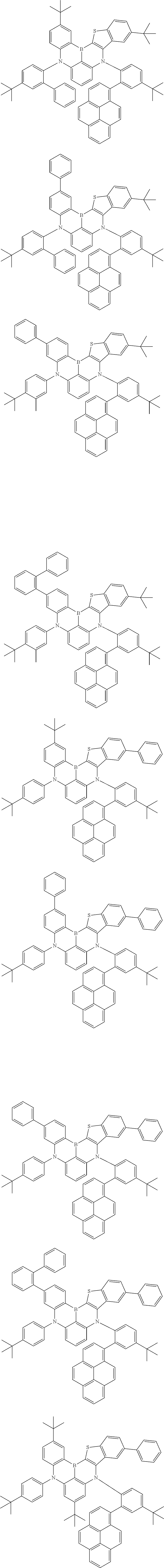

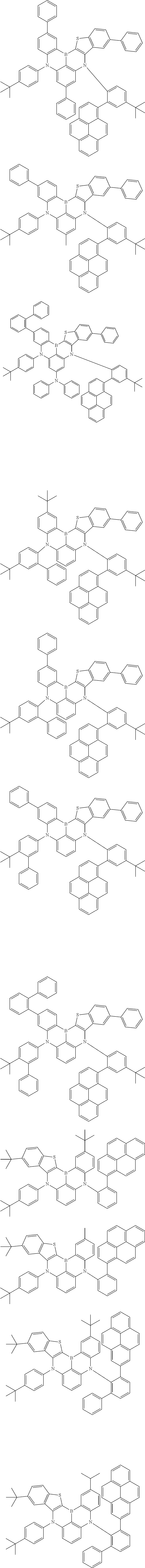

20. An organic electronic device comprising a first electrode, a second electrode, and one or more organic functional layers disposed between the first electrode and the second electrode, wherein at least one of the one or more organic functional layers comprises a boron-nitrogen compound having a structure represented by formula (1) or formula (2): 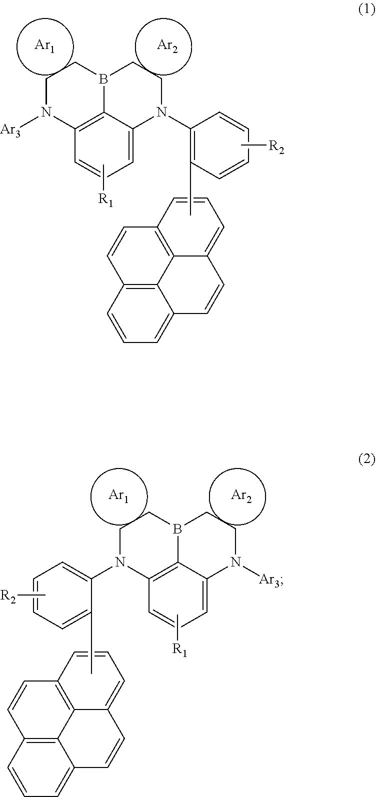
wherein Ar₁ is independently selected from any one of structures represented by formula (X-1) to formula (X-3): 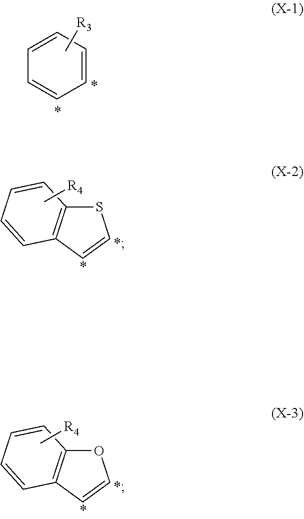
Ar₂ is independently selected from any one of structures represented by formula (A-1) to formula (A-7): 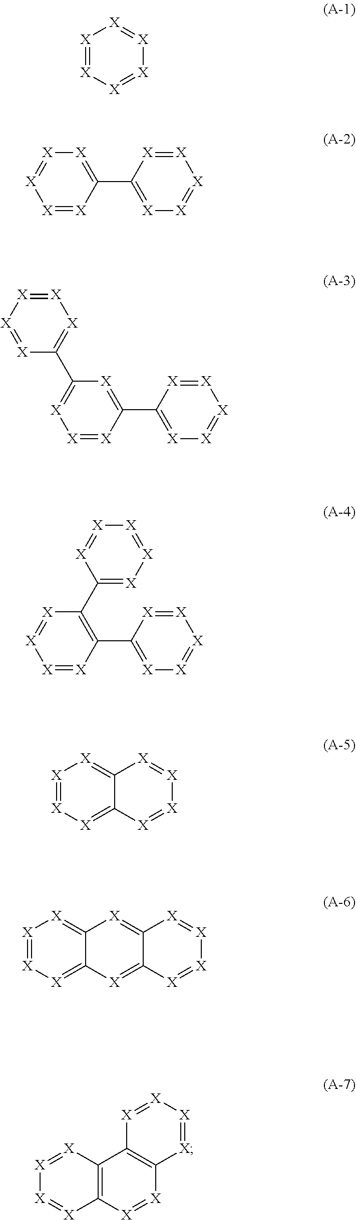
and
Ar₃ is independently selected from any one of the following structures: 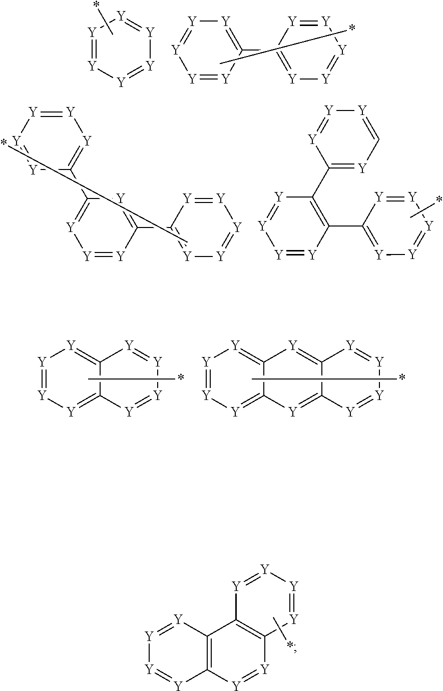
wherein X and Y are each independently selected from CR₅;
R₁-R₅ are each independently selected from H, D, a C₁-C₂₀ linear alkyl group, a C₃-C₂₀ branched alkyl group, a C₃-C₂₀ cyclic alkyl group, a substituted or unsubstituted C₅-C₃₀ aromatic group, a substituted or unsubstituted C₅-C₃₀ heteroaromatic group, or combinations thereof at each occurrence; and
* indicates a linking site.
